(19) United States
(12) Patent Application Publication
(10) Pub. No.: US 2026/0032950 A1
(43) Pub. Date: Jan. 29, 2026

(54) SEMICONDUCTOR DEVICE AND MANUFACTURING METHOD FOR SAME

(71) Applicant: ROHM CO., LTD., Kyoto-shi (JP)

(72) Inventors: Rogosu WAGURI, Kyoto-shi (JP); Yuki NAKANO, Kyoto-shi (JP); Seigo MORI, Kyoto-shi (JP)

(73) Assignee: ROHM CO., LTD., Kyoto-shi (JP)

(21) Appl. No.: 19/342,707

(22) Filed: Sep. 29, 2025

Related U.S. Application Data
(63) Continuation of application No. PCT/JP2024/012559, filed on Mar. 28, 2024.

(30) Foreign Application Priority Data
Mar. 30, 2023 (JP) 2023-056619

(51) Int. Cl. H10D 30/66; H10D 30/01; H10D 62/10; H10D 62/40; H10D 62/60; H10D 62/832

(52) U.S. Cl. CPC H10D 30/665; H10D 30/0291; H10D 62/107; H10D 62/126; H10D 62/40; H10D 62/60; H10D 62/8325

(57) ABSTRACT

A semiconductor device includes a chip that has a main surface, a drift region of a first conductivity type that is formed in a surface layer portion of the main surface, and a body region of a second conductivity type that is formed in a tapered shape in a surface layer portion of the drift region such that a width in a horizontal direction decreases in a thickness direction, and includes a peripheral edge portion inclined in an oblique direction with respect to the main surface.

### CROSS-REFERENCE TO RELATED APPLICATIONS

The present application is a bypass continuation of International Patent Application No. PCT/JP2024/012559 filed on Mar. 28, 2024, which claims priority to Japanese Patent Application No. 2023-056619 filed on Mar. 30, 2023 in the Japan Patent Office, and the entire contents of these applications are hereby incorporated herein by reference.

### BACKGROUND

### 1. Field of the Disclosure

The present disclosure relates to a semiconductor device and a manufacturing method for a semiconductor device.

### 2. Description of the Related Art

US2013/0193447A1 discloses a semiconductor device including body regions.

### BRIEF DESCRIPTION OF DRAWINGS

FIG. 1 is a plan view illustrating a semiconductor device according to a first embodiment.

FIG. 2 is a cross-sectional view taken along line II-II illustrated in FIG. 1.

FIG. 3 is a plan view illustrating a layout example of a first main surface.

FIG. 4 is an enlarged plan view showing a main portion of the first main surface.

FIG. 5 is an enlarged plan view illustrating another main portion of the first main surface.

FIG. 6 is a cross-sectional view taken along line VI-VI illustrated in FIG. 5.

FIG. 7 is an enlarged cross-sectional view illustrating a main portion of a region illustrated in FIG. 6.

FIG. 8 is a cross-sectional view taken along line VIII-VIII illustrated in FIG. 5.

FIG. 9 is an enlarged cross-sectional view illustrating a main portion of a region illustrated in FIG. 8.

FIG. 10A is an enlarged cross-sectional view illustrating a body structure according to the first configuration example.

FIG. 10B is an enlarged cross-sectional view illustrating a body structure according to a second configuration example.

FIG. 10C is an enlarged cross-sectional view illustrating a body structure according to a third configuration example.

FIG. 10D is an enlarged cross-sectional view illustrating a body structure according to a fourth configuration example.

FIG. 10E is an enlarged cross-sectional view illustrating a body structure according to a fifth configuration example.

FIG. 10F is an enlarged cross-sectional view illustrating a body structure according to a sixth configuration example.

FIG. 11A is a graph showing a concentration gradient in a first region of the body structure.

FIG. 11B is a graph showing a concentration gradient in a second region of the body structure.

FIG. 12 is a schematic view illustrating a wafer used in a manufacturing of the semiconductor device.

FIGS. 13A to 13H are cross-sectional views illustrating a manufacturing method for the semiconductor device.

FIG. 14 is an enlarged cross-sectional view illustrating a body structure according to a reference example.

FIG. 15A is a graph illustrating a concentration gradient in a first region of the body structure according to the reference example.

FIG. 15B is a graph illustrating a concentration gradient in a second region of the body structure according to the reference example.

FIG. 16 is a cross-sectional view illustrating a semiconductor device according to a second embodiment.

FIG. 17 is a cross-sectional view illustrating a modification example of a field region.

FIG. 18 is a cross-sectional view illustrating a first modification example of a source pad electrode.

FIG. 19 is a cross-sectional view illustrating a second modification example of a source pad electrode.

### DETAILED DESCRIPTION OF THE PREFERRED EMBODIMENTS

Hereinafter, specific embodiments will be described in detail with reference to attached drawings. The attached drawings are all schematic views and are not strictly illustrated, and relative positional relationships, scales, proportions, angles, etc., thereof do not always match. Identical reference signs are given to corresponding structures among the attached drawings, and duplicate descriptions thereof shall be omitted or simplified. For the structures, whose description has been omitted or simplified, the description given before the omission or simplification shall apply.

When the wording “substantially” is used in the present specification, the wording includes a numerical value (shape) equal to a numerical value (shape) of a comparison target and also includes numerical errors (shape errors) in a range of +10% with the numerical value (shape) of the comparison target as a reference. Although the wordings “first,” “second,” “third,” etc., are used in the following description, these are indicators added to names of respective structures in order to clarify the order of description and are not added with an intention of restricting the names of the respective structures.

In the following description, a “p-type” or an “n-type” is used to indicate a conductivity type of a semiconductor (impurity). However, the “p-type” may be referred to as a “first conductivity type,” and the “n-type” may be referred to as a “second conductivity type.” As a matter of course, the “n-type” may be referred to as a “first conductivity type,” and the “p-type” may be referred to as a “second conductivity type.” The “p-type” is a conductivity type caused by a trivalent element, and the “n-type” is a conductivity type caused by a pentavalent element. The trivalent element is at least one of boron, aluminum, gallium, and indium. The pentavalent element is at least one of nitrogen, phosphorus, arsenic, antimony, and bismuth.

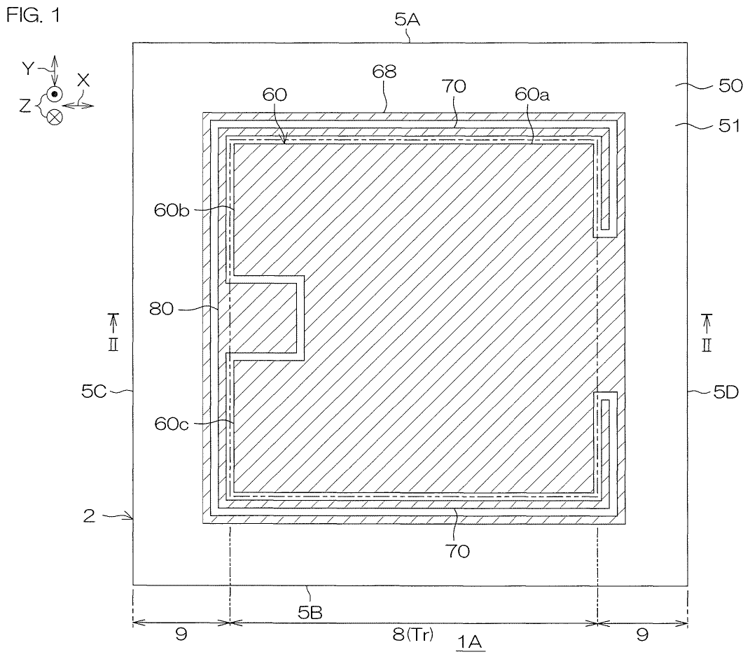

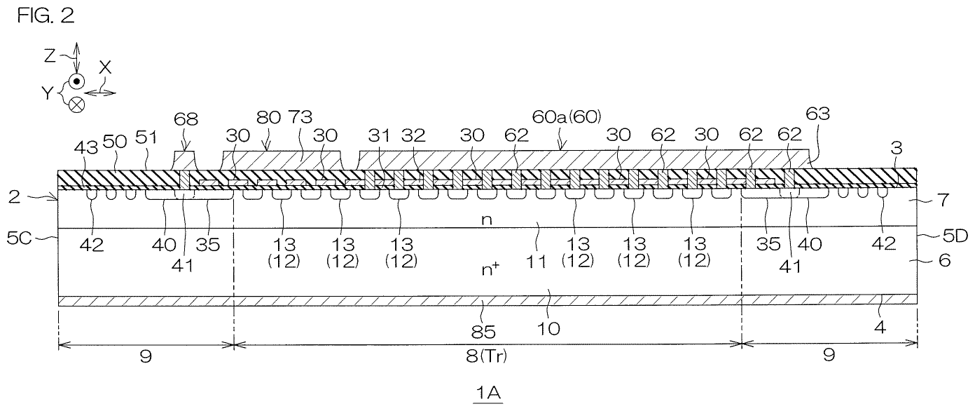

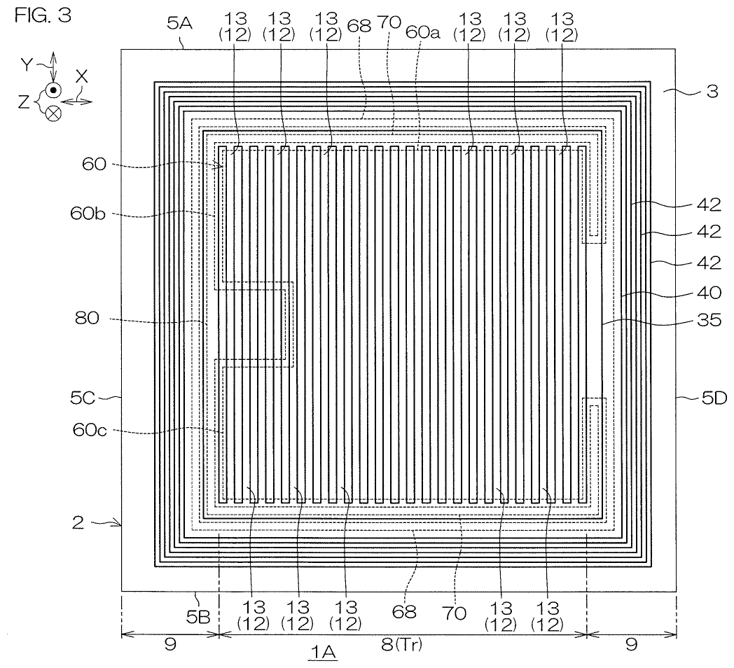

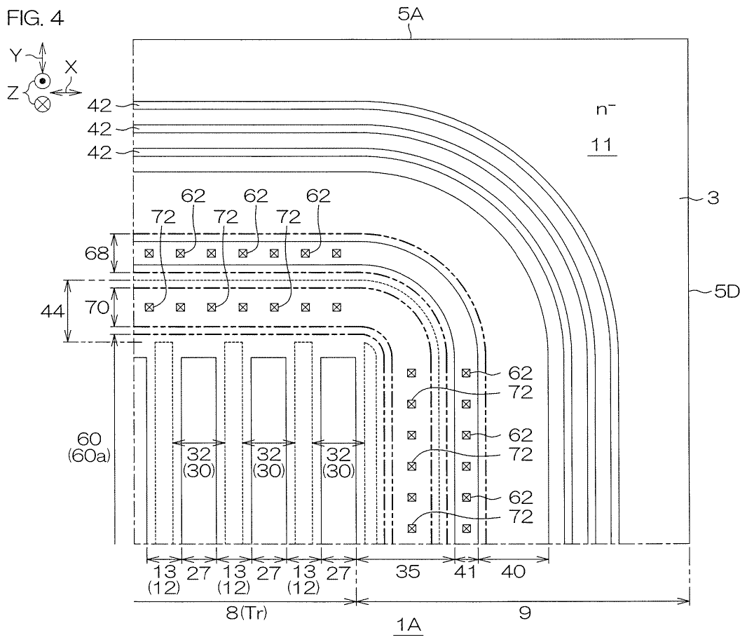

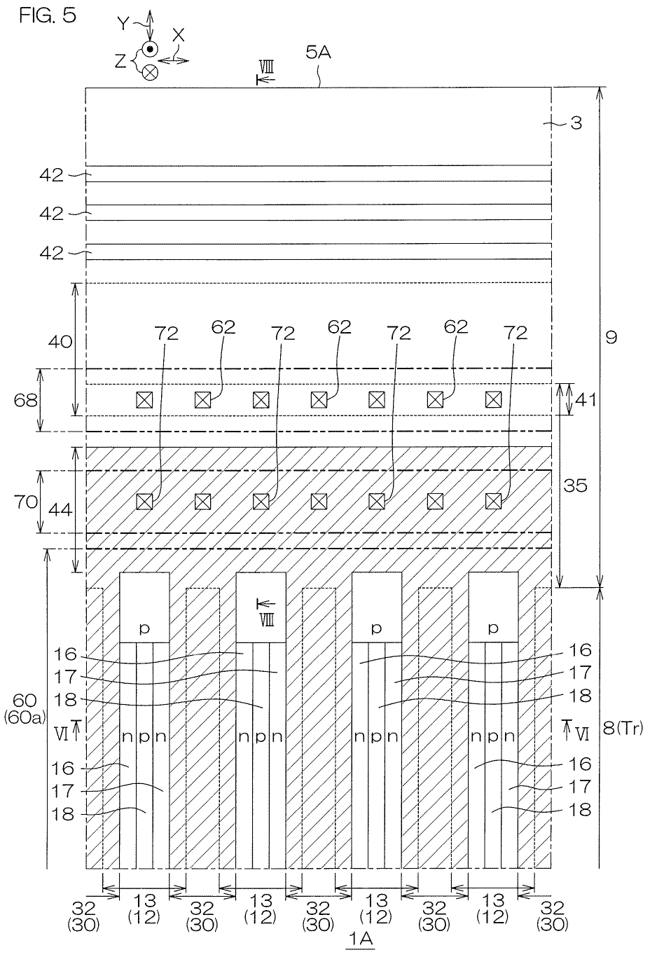

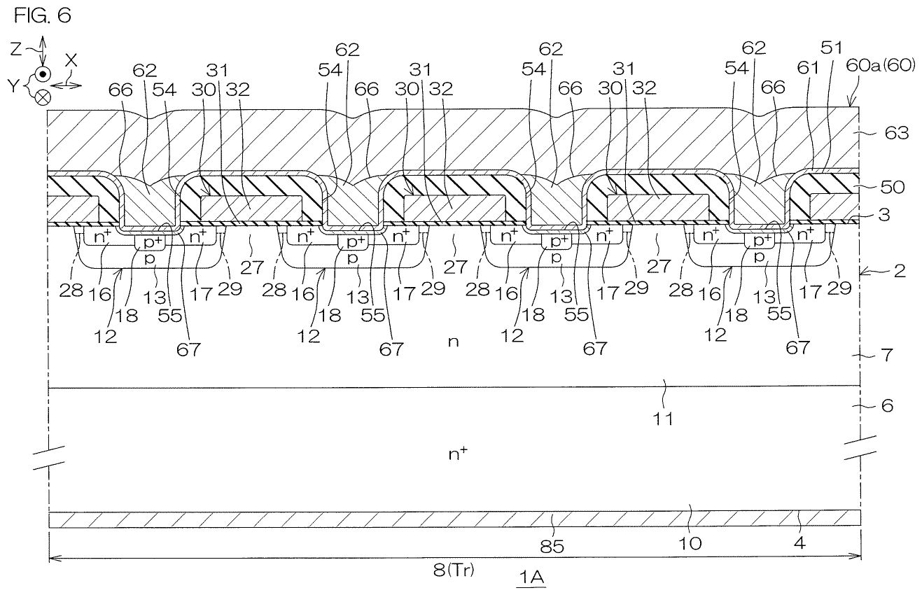

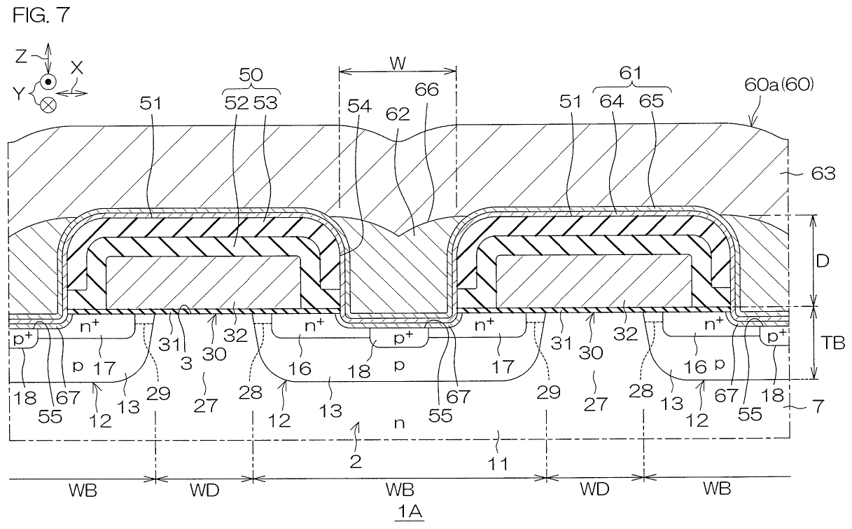

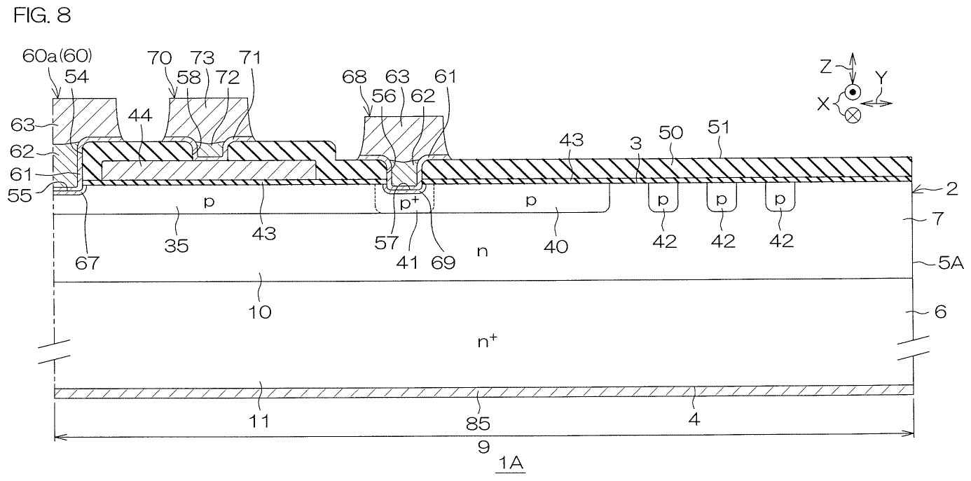

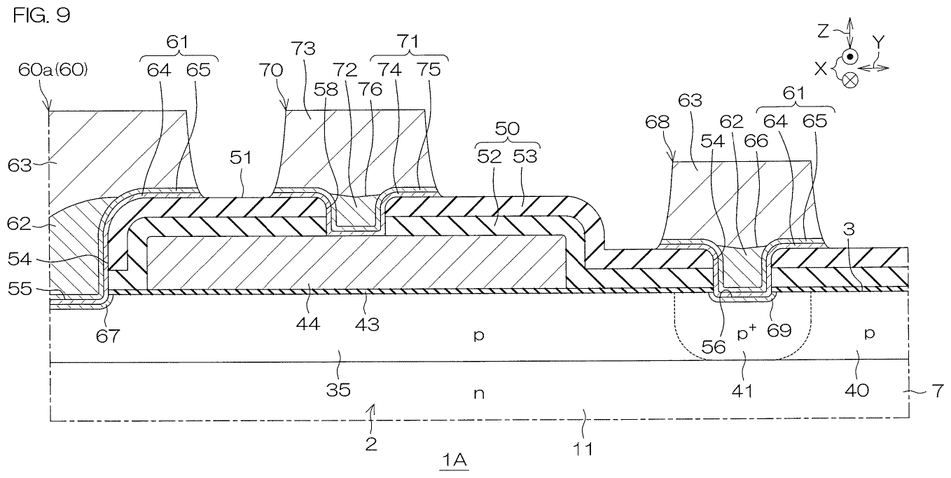

FIG. 1 is a plan view illustrating a semiconductor device 1A according to a first embodiment. FIG. 2 is a cross-sectional view taken along line II-II illustrated in FIG. 1. FIG. 3 is a plan view illustrating a layout example of a first main surface 3. FIG. 4 is an enlarged plan view illustrating a main portion of the first main surface 3. FIG. 5 is an enlarged plan view illustrating another main portion of the first main surface 3. FIG. 6 is a cross-sectional view taken along line VI-VI illustrated in FIG. 5. FIG. 7 is an enlarged cross-sectional view illustrating a main portion of a region illustrated in FIG. 6. FIG. 8 is a cross-sectional view taken along line VIII-VIII illustrated in FIG. 5. FIG. 9 is an enlarged cross-sectional view illustrating a main portion of a region illustrated in FIG. 8.

Referring to FIG. 1 to FIG. 9, the semiconductor device 1A is a semiconductor switching device having a transistor structure Tr of an insulated-gate-type as an example of a device structure. The transistor structure Tr has a vertical structure. The semiconductor device 1A is an SiC semiconductor device including a chip 2 made of an SiC single crystal. The chip 2 may be referred to as an “SiC chip” or as a “semiconductor chip.”

In this embodiment, the chip 2 is made of an SiC single crystal, which is a hexagonal crystal, and is formed in a rectangular parallelepiped shape. The hexagonal SiC single crystal includes a plurality of types of polytypes including 2 hexagonal(H)-SiC single crystal, 4H-SiC single crystal, 6H-SiC single crystal, etc. In this embodiment, an example in which the chip 2 is made of 4H-SiC single crystal is described, but the chip 2 may be made of another polytype.

The chip 2 has a first main surface 3 on one side, a second main surface 4 on the other side, and first to fourth side surfaces 5A to 5D connecting the first main surface 3 and the second main surface 4. In a plan view when viewed from a vertical direction Z (hereinafter, referred to simply as “plan view”), the first main surface 3 and the second main surface 4 are formed in quadrangle shapes. The vertical direction Z is also a thickness direction of the chip 2 and a normal direction to the first main surface 3 (the second main surface 4). The first main surface 3 and the second main surface 4 may be formed in a square shape or a rectangular shape in a plan view.

Preferably, the first main surface 3 and the second main surface 4 are formed by c-planes of the SiC single crystal. In this case, preferably, the first main surface 3 is formed by a silicon plane ((0001) plane) of the SiC single crystal, and the second main surface 4 is formed by a carbon plane ((000-1) plane) of the SiC single crystal.

The first side surface 5A and the second side surface 5B extend in a first direction X along the first main surface 3, and oppose each other in a second direction Y intersecting the first direction X along the first main surface 3. Specifically, the second direction Y is orthogonal to the first direction X. The third side surface 5C and the fourth side surface 5D extend in the second direction Y, and oppose each other in the first direction X.

In this embodiment, the first direction X is an m-axis direction ([1-100] direction) of the SiC single crystal, and the second direction Y is an a-axis direction ([11-20] direction) of the SiC single crystal. As a matter of course, the first direction X may be the a-axis direction of the SiC single crystal, and the second direction Y may be the m-axis direction of the SiC single crystal. In the following, a direction extending along the first main surface 3 may be referred to as a “horizontal direction.” The horizontal direction is also an XY plane (horizontal plane) formed by the first direction X and the second direction Y, and is orthogonal to the vertical direction Z.

The chip 2 (the first main surface 3 and the second main surface 4) has an off angle by being inclined at a predetermined angle in a predetermined off direction with respect to the c-plane of the SiC single crystal. That is, a c-axis ((0001) axis) of the SiC single crystal is inclined by the off angle toward the off direction from the vertical axis. Also, the c-plane of the SiC single crystal is inclined by the off angle with respect to the horizontal plane.

Preferably, the off direction is the a-axis direction (that is, the second direction Y) of the SiC single crystal. The off angle may be larger than 0° and equal to or smaller than 10°. The off angle may have a value in at least one range among a range larger than 0° and equal to or smaller 1°, a range of 1° or larger and 2.5° or smaller, a range of 2.5° or larger and 5° or smaller, a range of 5° or larger and 7.5° or smaller, and a range of 7.5° or larger and 10° or smaller.

Preferably, the off angle is equal to or smaller than 5°. It is particularly preferable that the off angle is in a range of 2° or larger and 4.5° or smaller. The off angle is typically set in a range of 4°±0.1°. This description does not exclude an embodiment in which the off angle is 0° (that is, an embodiment in which the first main surface 3 is a just surface with respect to the c-plane).

In this embodiment, the chip 2 has a laminated structure including a first semiconductor layer 6 and a second semiconductor layer 7. The first semiconductor layer 6 is made of a substrate (SiC substrate) including an SiC single crystal (semiconductor single crystal), and has the off direction and the off angle described above. The first semiconductor layer 6 forms the second main surface 4, and forms a portion of the first to fourth side surfaces 5A to 5D.

The first semiconductor layer 6 may have a thickness in a range of 10 μm or thicker and 500 μm or thinner. The thickness of the first semiconductor layer 6 may have a value in at least one range among a range of 10 μm or thicker and 50 μm or thinner, a range of 50 μm or thicker and 100 μm or thinner, a range of 100 μm or thicker and 150 μm or thinner, a range of 150 μm or thicker and 200 μm or thinner, a range of 200 μm or thicker and 300 μm or thinner, a range of 300 μm or thicker and 400 μm or thinner, and a range of 400 μm or thicker and 500 μm or thinner.

The second semiconductor layer 7 is made of an epitaxial layer (SiC epitaxial layer) including an SiC single crystal (semiconductor single crystal), and is laminated on the first semiconductor layer 6. The second semiconductor layer 7 has the off direction and the off angle described above. The second semiconductor layer 7 forms the first main surface 3, and forms a portion of the first to fourth side surfaces 5A to 5D. Preferably, the second semiconductor layer 7 has a thickness thinner than the thickness of the first semiconductor layer 6. As a matter of course, the thickness of the second semiconductor layer 7 may be thicker than the thickness of the first semiconductor layer 6.

The thickness of the second semiconductor layer 7 may be in a range of 5 μm or thicker and 50 μm or thinner. The thickness of the second semiconductor layer 7 may have a value in at least one range among a range of 5 μm or thicker and 10 μm or thinner, a range of 10 μm or thicker and 15 μm or thinner, a range of 15 μm or thicker and 20 μm or thinner, a range of 20 μm or thicker and 25 μm or thinner, a range of 25 μm or thicker and 30 μm or thinner, a range of 30 μm or thicker and 35 μm or thinner, a range of 35 μm or thicker and 40 μm or thinner, a range of 40 μm or thicker and 45 μm or thinner, and a range of 45 μm or thicker and 50 μm or thinner.

The semiconductor device 1A includes an active region 8 that is set in the chip 2 (first main surface 3). The active region 8 is set in an inner portion of the chip 2 (first main surface 3). The active region 8 is a region that has a device structure (transistor structure Tr) and in which an output current (drain current) is generated.

The active region 8 is set in an inner portion of the chip 2 at an interval from a peripheral edge (the first to fourth side surfaces 5A to 5D) of the chip 2 in a plan view. The active region 8 is set in a polygonal shape (in this embodiment, a quadrangle shape) having four sides parallel to the peripheral edge of the chip 2 in a plan view. Preferably, a planar area of the active region 8 is equal to or larger than 50% and equal to or smaller than 90% of a planar area of the first main surface 3.

The semiconductor device 1A includes an outer peripheral region 9 that is included in the chip 2 and is set outside the active region 8. The outer peripheral region 9 is a region that does not include a device structure (transistor structure Tr). The outer peripheral region 9 is set in a peripheral edge portion of the chip 2 (first main surface 3). That is, the outer peripheral region 9 is provided in a region between the peripheral edge of the chip 2 and the active region 8 in a plan view. The outer peripheral region 9 extends in a band shape along the active region 8 in a plan view, and is set in a polygonal round shape (in this embodiment, a quadrangular round shape) that surrounds the active region 8.

The semiconductor device 1A includes an n-type drain region 10 that is formed in a surface layer portion of the second main surface 4 in the active region 8. The drain region 10 may be referred to as a “first region,” a “first semiconductor region,” etc. A drain potential as a high potential (first potential) is to be applied to the drain region 10. The drain region 10 may be referred to as a “first region,” a “first semiconductor region,” etc. The drain region 10 may have an impurity concentration of 5×10¹⁷ cm⁻³ or higher and 3×10¹⁹ cm⁻³ or lower.

The drain region 10 extends in a layer shape along the second main surface 4. The drain region 10 is formed in the entire active region 8. The drain region 10 is drawn from the active region 8 to the outer peripheral region 9, and includes a portion that is located on a surface layer portion of the second main surface 4 in the outer peripheral region 9. The drain region 10 is led out from the active region 8 to the outer peripheral region 9 over the entire periphery. The drain region 10 is exposed from at least one of the first to fourth side surfaces 5A to 5D. In this embodiment, the drain region 10 is exposed from the entire periphery of the first to fourth side surfaces 5A to 5D.

The drain region 10 is formed in the first semiconductor layer 6. The drain region 10 is formed in the entire thickness range between a lower end (the second main surface 4) of the first semiconductor layer 6 and an upper end (the second semiconductor layer 7) of the first semiconductor layer 6, and is connected to the second semiconductor layer 7. The drain region 10 is formed using the n-type first semiconductor layer 6, and has a thickness corresponding to the thickness of the first semiconductor layer 6. As a matter of course, the drain region 10 may be formed by introducing n-type impurities into the surface layer portion of the second main surface 4 of the chip 2.

The semiconductor device 1A includes an n-type drift region 11 that is formed in a surface layer portion of the first main surface 3 in the active region 8. The drift region 11 may be referred to as a “second region,” a “second semiconductor region,” etc. The drift region 11 has an impurity concentration lower than the impurity concentration of the drain region 10.

The drift region 11 extends in a layer shape along the first main surface 3, and is electrically connected to the drain region 10 in the inner portion of the chip 2. The drift region 11 is formed in the entire active region 8. In this embodiment, the drift region 11 is led out from the active region 8 to the outer peripheral region 9, and includes a portion that is located on a surface layer portion of the first main surface 3 in the outer peripheral region 9.

The drift region 11 is led out from the active region 8 to the outer peripheral region 9 over the entire periphery. Preferably, the drift region 11 is exposed from at least one of the first to fourth side surfaces 5A to 5D. In this embodiment, the drift region 11 is exposed from the entire periphery of the first to fourth side surfaces 5A to 5D.

The drift region 11 is formed in the second semiconductor layer 7. The drift region 11 is formed in the entire thickness range between the upper end (drain region 10) of the first semiconductor layer 6 and an upper end (first main surface 3) of the second semiconductor layer 7, and is connected to the first semiconductor layer 6 (drain region 10). In this embodiment, the drift region 11 is formed using the n-type second semiconductor layer 7, and has a thickness corresponding to the thickness of the second semiconductor layer 7. As a matter of course, the drift region 11 may be formed by introducing n-type impurities into the surface layer portion of the first main surface 3 of the chip 2 (second semiconductor layer 7).

The semiconductor device 1A includes a plurality of body structures 12 that are formed in the surface layer portion of the first main surface 3 in the active region 8. The body structures 12 are arranged at intervals in the first direction X, and are respectively formed in a band shape extending in the second direction Y. That is, the body structures 12 are arranged in a stripe shape extending in the second direction Y. Also, the extension direction of the body structures 12 coincides with the off direction of the SiC single crystal.

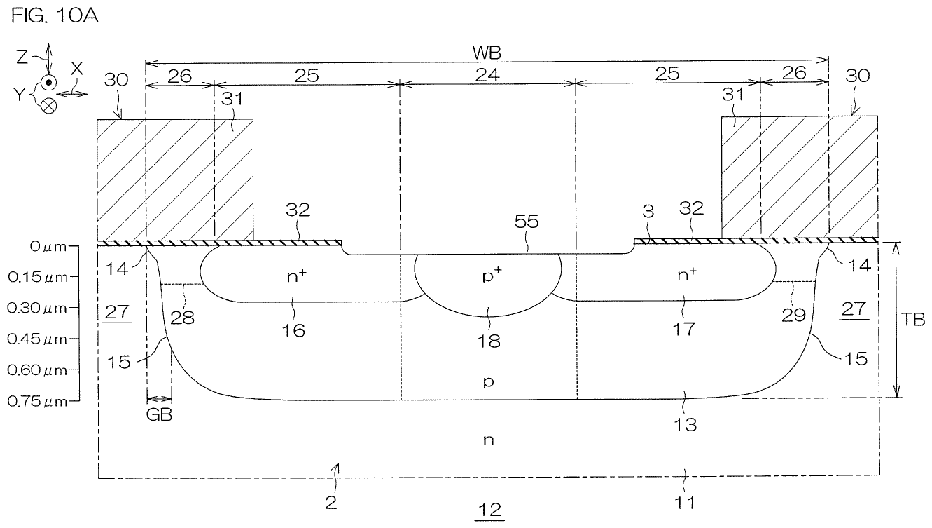

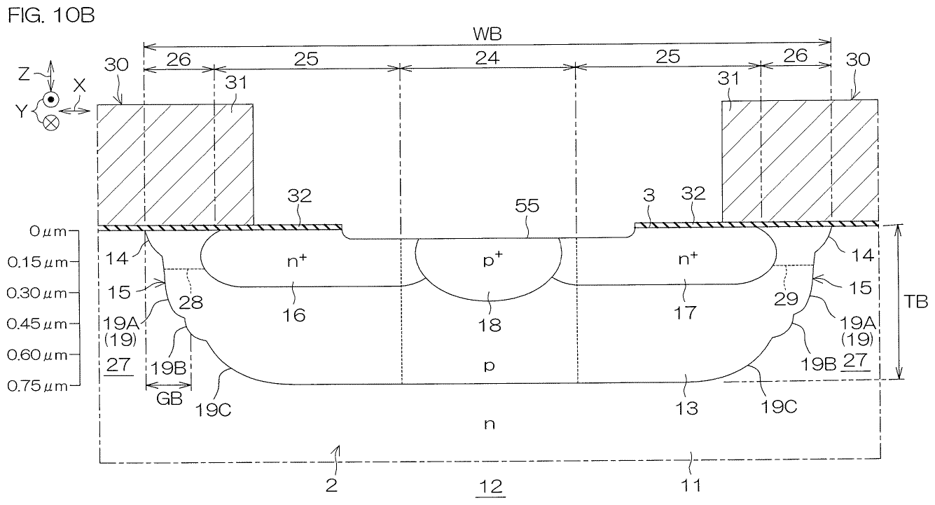

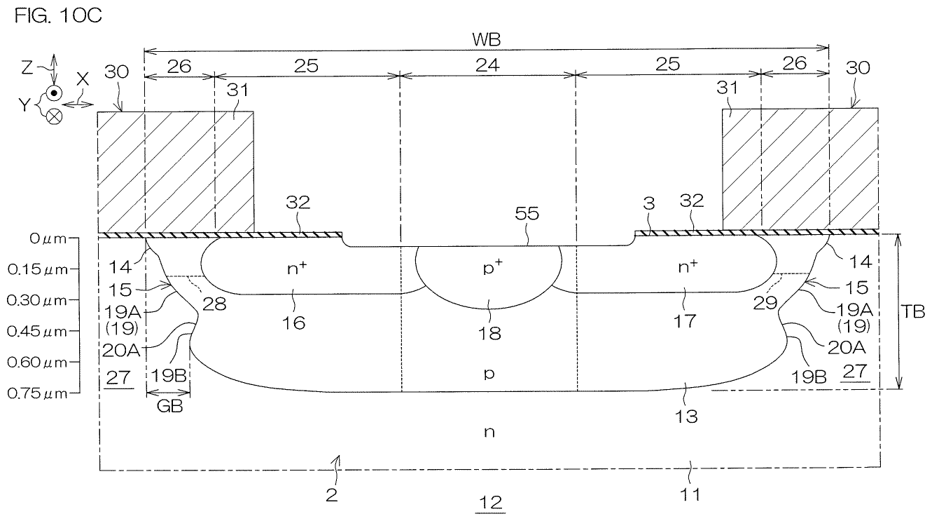

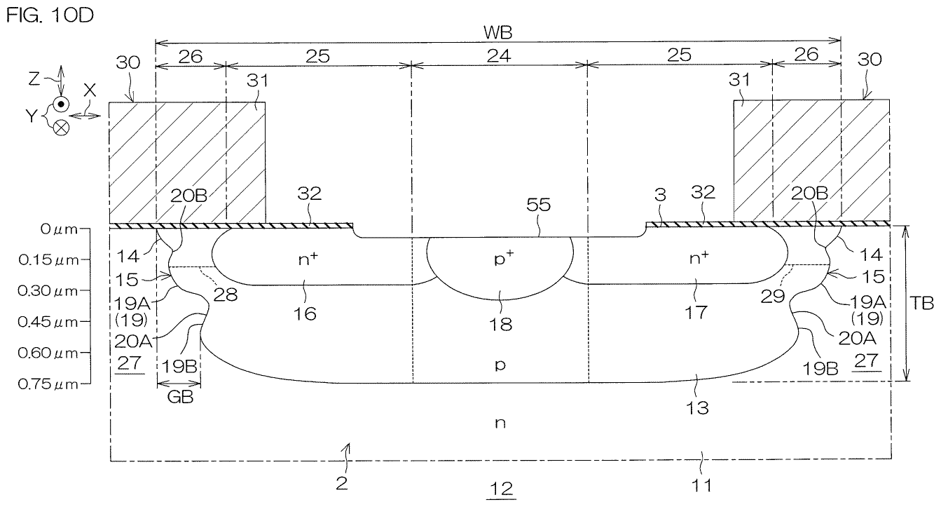

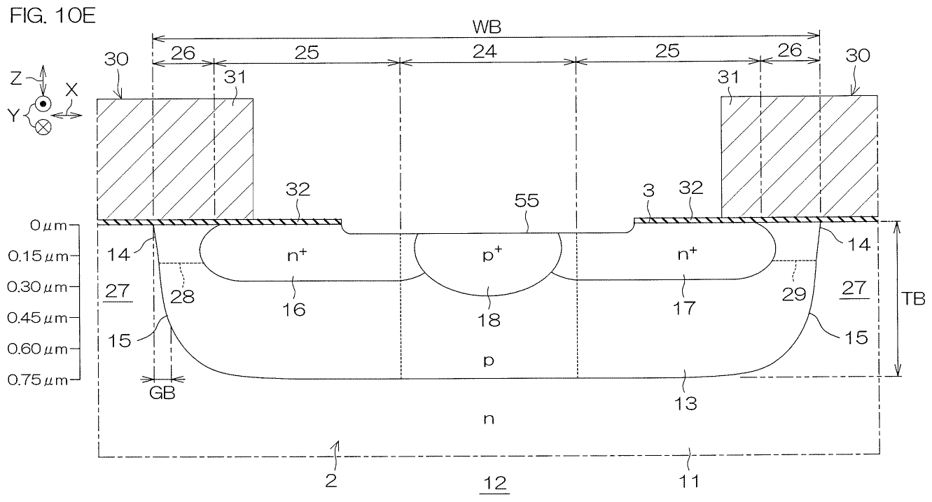

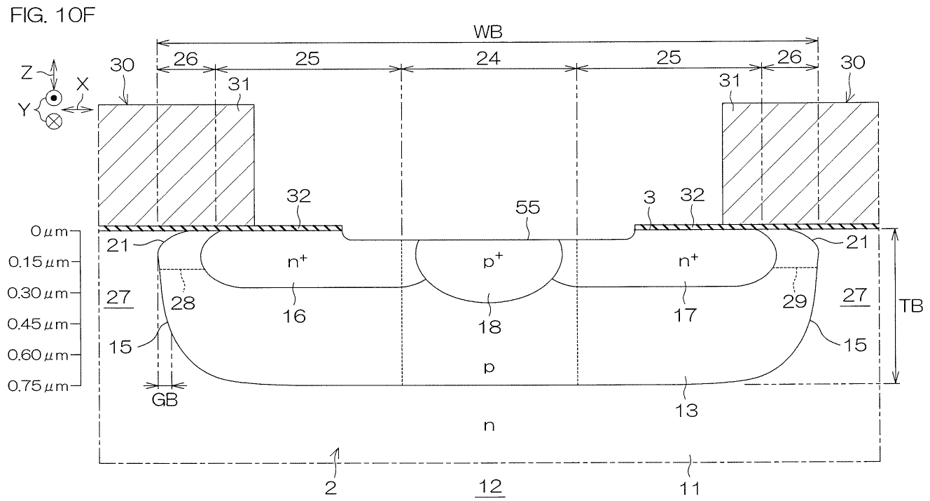

Hereinafter, a specific configuration of one body structure 12 will be described with reference to FIG. 10A. FIG. 10A is an enlarged cross-sectional view illustrating the body structure 12 according to a first configuration example. Referring to FIG. 10A, the body structure 12 includes a p-type body region 13 formed in the surface layer portion of the first main surface 3.

The body region 13 is formed in a surface layer portion of the drift region 11 as a main body portion of the body structure 12. That is, a plurality of the body regions 13 are arranged at intervals in the first direction X, and are respectively formed in a band shape extending in the second direction Y. A source potential as a low potential (second potential) different from the high potential (first potential) is to be applied to the body regions 13. Each of the body regions 13 forms a pn-junction portion with the drift region 11, and expands a depletion layer to the drift region 11 when a reverse bias voltage is applied.

The body region 13 includes an upper end portion on the first main surface 3 side and a lower end portion on a bottom portion side of the drift region 11. The lower end portion of the body region 13 is a bottom portion of the body region 13. The upper end portion of the body region 13 is exposed from the first main surface 3. The lower end portion of the body region 13 is formed at an interval from the bottom portion of the drift region 11 toward the first main surface 3 side, and opposes the drain region 10 across a portion of the drift region 11. Preferably, the lower end portion of the body region 13 is formed at an interval from an intermediate portion of the drift region 11 toward the first main surface 3 side. As a matter of course, the body region 13 may traverse a depth position of the intermediate portion of the drift region 11 in the thickness direction.

The body region 13 has a body width WB in the horizontal direction (in this embodiment, the first direction X). A maximum value of the body width WB may be in a range of 1 μm or wider and 10 μm or narrower. The maximum value of the body width WB may have a value in at least one range among a range of 1 μm or wider and 2 μm or narrower, a range of 2 μm or wider and 3 μm or narrower, a range of 3 μm or wider and 4 μm or narrower, a range of 4 μm or wider and 5 μm or narrower, a range of 5 μm or wider and 6 μm or narrower, a range of 6 μm or wider and 7 μm or narrower, a range of 7 μm or wider and 8 μm or narrower, a range of 8 μm or wider and 9 μm or narrower, and a range of 9 μm or wider and 10 μm or narrower. Preferably, the maximum value of the body width WB is in a range of 2 μm or wider and 5 μm or narrower.

The body region 13 may have a body thickness TB of 0.1 μm or thicker and 2.5 μm or thinner in the vertical direction Z. The body thickness TB is also a depth of the body region 13. The body thickness TB may have a value in at least one range among a range of 0.1 μm or thicker and 0.25 μm or thinner, a range of 0.25 μm or thicker and 0.5 μm or thinner, a range of 0.5 μm or thicker and 0.75 μm or thinner, a range of 0.75 μm or thicker and 1 μm or thinner, a range of 1 μm or thicker and 1.25 μm or thinner, a range of 1.25 μm or thicker and 1.5 μm or thinner, a range of 1.5 μm or thicker and 1.75 μm or thinner, a range of 1.75 μm or thicker and 2 μm or thinner, a range of 2 μm or thicker and 2.25 μm or thinner, and a range of 2.25 μm or thicker and 2.5 μm or thinner. Preferably, the body thickness TB is in a range of 0.5 μm or thicker and 1.5 μm or thinner. FIG. 10A illustrates an example in which the body thickness TB is in a range of 0.7 μm or thicker and 0.8 μm or thinner.

The body region 13 is formed in a tapered shape in the surface layer portion of the drift region 11 such that the body width WB decreases in the thickness direction, and includes a peripheral edge portion inclined in an oblique direction with respect to the first main surface 3. That is, the peripheral edge portion of the body region 13 is inclined in the oblique direction toward a central portion side of the lower end portion of the body region 13. The body width WB does not necessarily have to monotonously decrease in the thickness direction as long as an inclination tendency of the peripheral edge portion is maintained, and may gradually decrease.

Therefore, the phrase “inclined in an oblique direction” includes a form in which a straight line (oblique line) connecting two points of the peripheral edge portion in a predetermined thickness range is inclined with respect to the first main surface 3 in a cross-sectional view. For example, the predetermined thickness range may be a thickness range of ¼ or thicker, ⅓ or thicker, or ½ or thicker of the body thickness TB. As a matter of course, the predetermined thickness range may be the body thickness TB. In this case, the phrase “inclined in an oblique direction” includes a form in which a straight line connecting an upper end portion of the peripheral edge portion and a lower end portion of the peripheral edge portion is inclined with respect to the first main surface 3 in a cross-sectional view.

A distance in the horizontal direction between two points of the peripheral edge portion in the predetermined thickness range is defined as a body gradient GB. The body gradient GB in the predetermined thickness range may be in a range of 0.05 μm or longer and 0.5 μm or shorter. The body gradient GB may have a value in at least one range among a range of 0.05 μm or longer and 0.1 μm or shorter, a range of 0.1 μm or longer and 0.2 μm or shorter, a range of 0.2 μm or longer and 0.3 μm or shorter, a range of 0.3 μm or longer and 0.4 μm or shorter, and a range of 0.4 μm or longer and 0.5 μm or shorter.

An inclination angle formed by a straight line (oblique line) connecting two points of the peripheral edge portion and a vertical line may be in a range of 5° or larger and 45° or smaller. The inclination angle may have a value in at least one range among a range of 5° or larger and 10° or smaller, a range of 10° or larger and 15° or smaller, a range of 15° or larger and 20° or smaller, a range of 20° or larger and 25° or smaller, a range of 25° or larger and 30° or smaller, a range of 30° or larger and 35° or smaller, a range of 35° or larger and 40° or smaller, and a range of 40° or larger and 45° or smaller. Preferably, the inclination angle is in a range of 10° or larger and 30° or smaller. It is particularly preferable that the inclination angle is in a range of 15° or larger and 25° or smaller.

In this embodiment, the body region 13 is formed such that the body width WB decreases in the thickness direction with the upper end portion as a starting point. That is, the peripheral edge portion of the body region 13 is inclined in the oblique direction toward the lower end portion side with the upper end portion as the starting point. Preferably, the body width WB decreases from at least the upper end portion to an intermediate portion. That is, preferably, the peripheral edge portion of the body region 13 is inclined in the oblique direction at least from the upper end portion to the intermediate portion.

It is particularly preferable that the body width WB decreases from the upper end portion side toward the lower end portion side over the entire thickness range between the upper end portion and the lower end portion. That is, it is particularly preferable that the peripheral edge portion of the body region 13 is inclined in the oblique direction from the upper end portion side toward the lower end portion side over the entire thickness range between the upper end portion and the lower end portion.

The body region 13 may have a maximum value of the body width WB in the upper end portion or a region on the upper end portion side (for example, a region in a thickness range of 10% from the upper end portion). The body region 13 may have a minimum value of the body width WB in the lower end portion or a region on the lower end portion side (for example, a region in a thickness range of 10% from the lower end portion). Preferably, the peripheral edge portion is connected to the lower end portion in an arc shape (circular arc shape) in a cross-sectional view. That is, preferably, the body region 13 includes an edge portion connecting the peripheral edge portion and the lower end portion in an arc shape (circular arc shape).

In a case where the upper end portion of the peripheral edge portion of the body region 13 is set as a reference position (a point at 0 μm), the peripheral edge portion of the body region 13 is inclined in the oblique direction with respect to the first main surface 3 in a thickness range of 0.5 μm from the first main surface 3. That is, the body region 13 does not extend in a direction perpendicular to the first main surface 3 in the thickness range of 0.5 μm. In other words, a portion of the peripheral edge portion of the body region 13 that is located at a point of 0.5 μm is located on the inner side of the body region 13 from the upper end portion of the peripheral edge portion, and does not overlap the upper end portion in the vertical direction Z.

The peripheral edge portion of the body region 13 has a body gradient GB of 0.05 μm or longer and 0.25 μm or shorter in the thickness range of 0.5 μm. The body gradient GB in the thickness range of 0.5 μm is an amount of a change of the peripheral edge portion in the horizontal direction at a thickness point of 0.5 μm when the upper end portion of the peripheral edge portion is set as a reference position. In FIG. 10A, the body gradient GB in the thickness range of 0.5 μm is illustrated.

The body gradient GB in the thickness range of 0.5 μm may have a value in at least one range among a range of 0.05 μm or longer and 0.1 μm or shorter, a range of 0.1 μm or longer and 0.15 μm or shorter, a range of 0.15 μm or longer and 0.2 μm or shorter, and a range of 0.2 μm or longer and 0.25 μm or shorter. Preferably, the body gradient GB is in a range of 0.1 μm or longer and 0.2 μm or shorter. It is preferable that the body gradient GB in the thickness range of 0.5 μm is in a range of 0.1 μm or longer and 0.15 μm or shorter.

In this embodiment, the peripheral edge portion of the body region 13 includes a sub inclined portion 14 on the upper end portion side and a main inclined portion 15 on the lower end portion side. The sub inclined portion 14 may be referred to as a “first inclined portion” or an “upper inclined portion,” and the main inclined portion 15 may be referred to as a “second inclined portion” or a “lower inclined portion.” The sub inclined portion 14 is formed in a region on the first main surface 3 side with respect to the intermediate portion of the body region 13. The sub inclined portion 14 forms a surface portion of the body region 13, and is exposed from the first main surface 3.

The sub inclined portion 14 is formed of a protruding portion that protrudes in the horizontal direction from the peripheral edge portion along the first main surface 3 in the upper end portion of the body region 13. The sub inclined portion 14 is formed by a portion of the body region 13 in which the body width WB monotonously decreases, and is inclined in the oblique direction with respect to the first main surface 3. In this embodiment, the sub inclined portion 14 protrudes in an arc shape (circular arc shape). The sub inclined portion 14 has a first inclination angle which is relatively gentle with respect to the first main surface 3.

The sub inclined portion 14 suppresses the body width WB that is relatively narrow from being formed in the upper end portion of the body region 13, and suppresses the upper end portion of the peripheral edge portion from being recessed toward the inner portion side of the body region 13. That is, the sub inclined portion 14 suppresses a short channel portion from being formed in the upper end portion of the body region 13.

The sub inclined portion 14 may have a width (protruding width) of 0.01 μm or wider and 0.25 μm or narrower in the horizontal direction. The width of the sub inclined portion 14 is a width in the horizontal direction when a vertical line passing through the lower end portion of the sub inclined portion 14 in the vertical direction Z is set as a reference. The width of the sub inclined portion 14 monotonously decreases in the thickness direction.

The width of the sub inclined portion 14 may have a value in at least one range among a range of 0.01 μm or wider and 0.05 μm or narrower, a range of 0.05 μm or wider and 0.1 μm or narrower, a range of 0.1 μm or wider and 0.15 μm or narrower, a range of 0.15 μm or wider and 0.2 μm or narrower, and a range of 0.2 μm or wider and 0.25 μm or narrower. In this embodiment, the width of the sub inclined portion 14 is in a range of 0.15 μm or narrower.

The sub inclined portion 14 may have a thickness of 0.01 μm or thicker and 0.25 μm or thinner in the vertical direction Z. The thickness of the protruding portion may have a value in at least one range among a range of 0.01 μm or thicker and 0.05 μm or thinner, a range of 0.05 μm or thicker and 0.1 μm or thinner, a range of 0.1 μm or thicker and 0.15 μm or thinner, a range of 0.15 μm or thicker and 0.2 μm or thinner, and a range of 0.2 μm or thicker and 0.25 μm or thinner. In this embodiment, the thickness of the sub inclined portion 14 is in a range of 0.15 μm or thinner.

The main inclined portion 15 is formed in a region on the lower end portion side with respect to the sub inclined portion 14. The main inclined portion 15 has a thickness thicker than the thickness of the sub inclined portion 14, and forms a main portion of the body region 13. The main inclined portion 15 forms the body gradient GB with the sub inclined portion 14. For example, the main inclined portion 15 forms the body gradient GB with the sub inclined portion 14 in the thickness range of 0.5 μm.

In this embodiment, the main inclined portion 15 is formed by a portion of the body region 13 in which the body width WB substantially monotonously decreases, and is inclined in the oblique direction with respect to the first main surface 3. The main inclined portion 15 is located on the inner side of the body region 13 with respect to the sub inclined portion 14, and has a second inclination angle that is steeper than the first inclination angle of the sub inclined portion 14 with respect to the first main surface 3. For example, when a horizontal line (X-axis line) along the horizontal direction (first direction X) is set as a reference, the second inclination angle has a value larger than that of the first inclination angle. In other words, when a vertical line along the vertical direction Z is set as a reference, the second inclination angle has a value smaller than that of the first inclination angle.

The body structure 12 includes a plurality of n-type source regions 16 and 17 that are formed in a surface layer portion of the body region 13. The source potential is to be applied to the source regions 16 and 17. The source regions 16 and 17 include a first source region 16 located on one side (the third side surface 5C side) in the first direction X and a second source region 17 located on the other side (the fourth side surface 5D side) in the first direction X. In this embodiment, one first source region 16 is formed on one end side of the body region 13, and one second source region 17 is formed on the other end side of the body region 13.

The first source region 16 is formed at an interval from one end of the body region 13 toward the other end side of the body region 13. The second source region 17 is formed at an interval from the first source region 16 toward the other end side of the body region 13. The second source region 17 is formed at an interval from the other end of the body region 13 toward one end side of the body region 13.

Hereinafter, configurations of one source region 16, 17 will be specifically described. The source region 16, 17 extends in a band shape along the extension direction of the body region 13. The source region 16, 17 is formed at intervals inwardly from both end portions of the body region 13 in the second direction Y. That is, the source region 16, 17 exposes both end portions of the body region 13 from the first main surface 3 (see FIG. 5).

The source region 16, 17 is formed at an interval from a lower end portion of the body region 13 toward the first main surface 3 side, and opposes the drift region 11 across a portion of the body region 13. Specifically, the source region 16, 17 has a thickness that traverses a depth position of the sub inclined portion 14 in the thickness direction.

The source region 16, 17 is formed at an interval inwardly from the sub inclined portion 14, and includes a portion that opposes the sub inclined portion 14 in the horizontal direction. The source region 16, 17 is formed at an interval inwardly from the main inclined portion 15, and includes a portion that opposes the main inclined portion 15 in the horizontal direction.

An intermediate portion of the source region 16, 17 is located on the main inclined portion 15 side with respect to the depth position of the sub inclined portion 14, and oppose the main inclined portion 15 in the horizontal direction. In the horizontal direction, a distance between the source region 16, 17 and the main inclined portion 15 is shorter than a distance between the source region 16, 17 and the sub inclined portion 14.

The source region 16, 17 includes a peripheral edge portion protruding in an arc shape (circular arc shape) toward the peripheral edge portion side of the body region 13. An end portion of the source region 16, 17 may oppose the first main surface 3 across a portion of the body region 13 in the thickness direction. As a matter of course, the peripheral edge portion of the source region 16, 17 may include an end portion exposed from the first main surface 3 without interposing the body region 13 in the thickness direction. In this case, the peripheral edge portion of the source region 16, 17 may be inclined obliquely downward in a linear shape or a curved shape from the first main surface 3 toward the inner side of the lower end portion of the body region 13. As a matter of course, the peripheral edge portion of the source region 16, 17 may extend to be substantially perpendicular to the first main surface 3.

In a case where a plurality of first source regions 16 are formed in the body region 13, the first source regions 16 may be formed at intervals in the extension direction of the body region 13. In this case, each of the first source regions 16 may be formed in a band shape extending in the second direction Y. In a case where a plurality of second source regions 17 are formed in the body region 13, the second source regions 17 may be formed at intervals in the extension direction of the body region 13. In this case, each of the second source regions 17 may be formed in a band shape extending in the second direction Y.

The body structures 12 include a plurality of p-type contact regions 18 that are formed in regions different from the source regions 16 and 17 in the surface layer portions of the body regions 13. The contact region 18 may be referred to as a “back gate region.” The source potential is to be applied to the contact regions 18. In this embodiment, a single contact region 18 is interposed in a region between the first source region 16 and the second source region 17 in the surface layer portion of the body region 13, and is electrically connected to the body region 13.

The contact region 18 extends in a band shape along the extension direction of the body region 13 (the source regions 16 and 17). The contact region 18 is formed at intervals inwardly from both end portions of the body region 13 in the second direction Y. That is, the contact region 18 exposes both end portions of the body region 13 from the first main surface 3 (refer to FIG. 5).

In this embodiment, the contact region 18 has a width narrower than the widths of the source regions 16 and 17. As a matter of course, the width of the contact region 18 may be wider than the widths of the source regions 16 and 17. The contact region 18 is formed at an interval from the lower end portion of the body region 13 toward the first main surface 3 side, and opposes the drift region 11 across a portion of the body region 13. Specifically, the contact region 18 has a thickness that traverses a depth position of the sub inclined portion 14 in the thickness direction.

The contact region 18 includes a portion that opposes the sub inclined portion 14 across the source region 16, 17 in the horizontal direction and a portion that opposes the main inclined portion 15 across the source region 16, 17 in the horizontal direction. An intermediate portion of the contact region 18 is located on the main inclined portion 15 side with respect to the depth position of the sub inclined portion 14, and opposes the main inclined portion 15 in the horizontal direction.

In this embodiment, the contact region 18 has a thickness thicker than the thicknesses of the source regions 16 and 17, and includes a bottom portion located on the lower end portion side of the body region 13 with respect to bottom portions of the source regions 16 and 17. That is, the bottom portion of the contact region 18 opposes the main inclined portion 15 without interposing the source regions 16 and 17 in the horizontal direction. The contact region 18 includes a peripheral edge portion protruding in an arc shape (circular arc shape) toward the peripheral edge portion side of the body region 13.

An end portion of the contact region 18 may oppose the first main surface 3 across portions of the source regions 16 and 17 in the thickness direction. As a matter of course, a peripheral edge portion of the contact region 18 may include an end portion exposed from the first main surface 3 without interposing the source regions 16 and 17 in the thickness direction. In this case, the peripheral edge portion of the contact region 18 may be inclined obliquely downward in a linear shape or a curved shape from the first main surface 3 toward the inner side of the lower end portion of the body region 13. As a matter of course, the peripheral edge portion of the contact region 18 may extend to be substantially perpendicular to the first main surface 3.

In a case where a plurality of contact regions 18 are formed in the body region 13, the contact regions 18 may be formed at intervals in the extension direction of the body region 13. In this case, each of the contact regions 18 may be formed in a band shape extending in the second direction Y.

The body structure 12 may have a configuration illustrated in FIG. 10B to FIG. 10F. FIG. 10B is an enlarged cross-sectional view illustrating the body structure 12 according to a second configuration example. FIG. 10C is an enlarged cross-sectional view illustrating the body structure 12 according to a third configuration example. FIG. 10D is an enlarged cross-sectional view illustrating the body structure 12 according to a fourth configuration example. FIG. 10E is an enlarged cross-sectional view illustrating the body structure 12 according to a fifth configuration example. FIG. 10F is an enlarged cross-sectional view illustrating the body structure 12 according to a sixth configuration example.

Referring to FIG. 10B, the body structure 12 according to the second configuration example has a configuration in which the configuration of the body region 13 according to the first configuration example is changed. In this embodiment, the body region 13 includes the main inclined portion 15 having undulations.

Specifically, the main inclined portion 15 includes a plurality of (at least two) bulging portions 19 that protrude in the horizontal direction and are arranged in multiple stages in the thickness direction. The bulging portions 19 are regions in which a change rate (decrease amount) of the body width WB changes in the thickness direction. The bulging portions 19 may protrude in arc shapes (circular arc shapes). The bulging portion 19 may be referred to as a “protruding portion,” a “projecting portion,” a “curved portion,” an “extension portion,” etc.

The body region 13 (main inclined portion 15) may include at least one or a plurality of bulging portions 19 formed by portions of the body region 13 in which the body width WB decreases substantially monotonously. The body region 13 (main inclined portion 15) may include at least one or a plurality of bulging portions 19 formed by portions of the body region 13 in which the body width WB gradually increases and decreases.

The bulging portions 19 are formed to be sequentially set back toward the inner side of the body region 13 from the upper end portion side of the body region 13 toward the lower end portion side of the body region 13, with the lower end portion of the sub inclined portion 14 as a starting point, and form undulations in which protrusions and recesses are repeated along the inclination direction. That is, in regard to a lower bulging portion 19 and an upper bulging portion 19, an end portion of the lower bulging portion 19 is located on the inner side of the body region 13 with respect to an end portion of the upper bulging portion 19.

The bulging portions 19 may have different thicknesses. That is, the main inclined portion 15 may include one bulging portion 19 having a relatively thinner thickness (depth) and the other bulging portion 19 having a thickness (depth) thicker than the thickness of the one bulging portion 19. The other bulging portion 19 may be located on the upper end portion side with respect to the one bulging portion 19, or may be located on the lower end portion side with respect to the one bulging portion 19.

The thickness of each of the bulging portions 19 may be in a range of 0.05 μm or thicker and 0.5 μm or thinner. The thickness of each of the bulging portions 19 may have a value in at least one range among a range of 0.05 μm or thicker and 0.1 μm or thinner, a range of 0.1 μm or thicker and 0.2 μm or thinner, a range of 0.2 μm or thicker and 0.3 μm or thinner, a range of 0.3 μm or thicker and 0.4 μm or thinner, and a range of 0.4 μm or thicker and 0.5 μm or thinner.

As an example, in this embodiment, the bulging portions 19 include a first bulging portion 19A, a second bulging portion 19B, and a third bulging portion 19C that are formed in this order from the upper end portion side toward the lower end portion side. The first bulging portion 19A is formed immediately below the sub inclined portion 14. The first bulging portion 19A is formed by a portion of the body region 13 in which the body width WB decreases substantially monotonously, and includes an end portion that is set back toward the inner side of the body region 13 with respect to the end portion of the sub inclined portion 14.

In this embodiment, the end portion of the first bulging portion 19A does not oppose the sub inclined portion 14 in the thickness direction. As a matter of course, the first bulging portion 19A may be formed by a portion in which the body width WB gradually increases and decreases, and may oppose the sub inclined portion 14 in the thickness direction. The first bulging portion 19A has a first thickness thicker than the thickness of the sub inclined portion 14. As a matter of course, the first thickness may be thinner than the thickness of the sub inclined portion 14.

The second bulging portion 19B is formed immediately below the first bulging portion 19A. The second bulging portion 19B is formed by a portion of the body region 13 in which the body width WB decreases substantially monotonously, and includes an end portion that is set back toward the inner side of the body region 13 with respect to the end portion of the first bulging portion 19A. In this embodiment, the second bulging portion 19B does not oppose the first bulging portion 19A in the thickness direction.

As a matter of course, the second bulging portion 19B may be formed by a portion in which the body width WB gradually increases and decreases, and may oppose the first bulging portion 19A in the thickness direction. The second bulging portion 19B has a second thickness thinner than the first thickness of the first bulging portion 19A. As a matter of course, the second thickness may be thicker than the first thickness.

The third bulging portion 19C is formed immediately below the second bulging portion 19B. The third bulging portion 19C is formed by a portion of the body region 13 in which the body width WB decreases substantially monotonously, and includes an end portion that is set back toward the inner side of the body region 13 with respect to the end portion of the second bulging portion 19B. In this embodiment, the third bulging portion 19C does not oppose the second bulging portion 19B in the thickness direction.

As a matter of course, the third bulging portion 19C may be formed by a portion in which the body width WB gradually increases and decreases, and may oppose the second bulging portion 19B in the thickness direction. The third bulging portion 19C forms an edge portion of the body region 13, and is connected to the lower end portion of the body region 13 in an arc shape (circular arc shape). The third bulging portion 19C has a third thickness thicker than the second thickness of the second bulging portion 19B. As a matter of course, the third thickness may be thinner than the second thickness. The third thickness may be thicker than the first thickness, or may be thinner than the first thickness.

The source region 16, 17 is formed at an interval from at least a depth position of the lowermost bulging portion 19 (that is, the third bulging portion 19C) toward the first main surface 3 side, and opposes at least one bulging portion 19 in the horizontal direction. In this embodiment, the source region 16, 17 is formed at an interval from a depth position of the second bulging portion 19B toward the first main surface 3 side.

The source region 16, 17 includes a portion that opposes the sub inclined portion 14 in the horizontal direction and a portion that opposes the first bulging portion 19A in the horizontal direction. As a matter of course, the source region 16, 17 may have a thickness that traverses the depth position of the second bulging portion 19B, and may include a portion that opposes the second bulging portion 19B in the horizontal direction.

The contact region 18 is formed at an interval from at least the depth position of the lowermost bulging portion 19 (that is, the third bulging portion 19C) toward the first main surface 3 side, and opposes at least one bulging portion 19 in the horizontal direction. In this embodiment, the contact region 18 is formed at an interval from the depth position of the second bulging portion 19B toward the first main surface 3 side.

The contact region 18 includes a portion that opposes the sub inclined portion 14 across the source region 16, 17 in the horizontal direction and a portion that opposes the first bulging portion 19A across the source region 16, 17 in the horizontal direction. As a matter of course, the contact region 18 may have a thickness that traverses the depth position of the second bulging portion 19B, and may include a portion that opposes the second bulging portion 19B in the horizontal direction.

Referring to FIG. 10C, the body structure 12 according to the third configuration example includes a plurality of bulging portions 19 similarly to the body region 13 according to the second configuration example. In this embodiment, the bulging portions 19 include a first bulging portion 19A and a second bulging portion 19B that are formed in this order from the upper end portion side toward the lower end portion side.

The first bulging portion 19A is formed immediately below the sub inclined portion 14. The first bulging portion 19A is formed by a portion of the body region 13 in which the body width WB decreases substantially monotonously, and includes an end portion that is set back toward the inner side of the body region 13 with respect to the end portion of the sub inclined portion 14. The first bulging portion 19A has a first thickness thicker than the thickness of the sub inclined portion 14. As a matter of course, the first thickness may be thinner than the thickness of the sub inclined portion 14.

The second bulging portion 19B is formed immediately below the first bulging portion 19A. The second bulging portion 19B is formed by a portion of the body region 13 in which the body width WB gradually increases and decreases, and includes an end portion that is set back toward the inner side of the body region 13 with respect to the end portion of the first bulging portion 19A. The second bulging portion 19B forms an edge portion of the body region 13, and is connected to the lower end portion of the body region 13 in an arc shape (circular arc shape). The second bulging portion 19B has a second thickness thicker than the thickness of the sub inclined portion 14. The second thickness may be thicker than the first thickness, or may be thinner than the first thickness.

The second bulging portion 19B forms a recessed portion 20A that is recessed in the horizontal direction toward the inner side of the body region 13 at a boundary portion (connection portion) with the first bulging portion 19A, and opposes the first bulging portion 19A in the thickness direction across the recessed portion 20A. In a case where a vertical line passing through the end portion of the second bulging portion 19B in the vertical direction Z in a cross-sectional view is set, the recessed portion 20A includes an end portion that is recessed toward the inner side of the body region 13 from the vertical line. A configuration without the recessed portion 20A corresponds to the body region 13 according to the second configuration example.

Preferably, the source region 16, 17 is formed at an interval from at least a depth position of the recessed portion 20A toward the first main surface 3 side, and opposes at least one bulging portion 19 in the horizontal direction. In this embodiment, the source region 16, 17 is formed at an interval from a depth position of the end portion of the recessed portion 20A toward the first main surface 3 side. The source region 16, 17 includes a portion that opposes the sub inclined portion 14 in the horizontal direction and a portion that opposes the first bulging portion 19A in the horizontal direction. The source region 16, 17 does not include a portion that opposes the recessed portion 20A (second bulging portion 19B) in the horizontal direction.

Preferably, the contact region 18 is formed at an interval from at least a depth position of the recessed portion 20A toward the first main surface 3 side, and opposes at least one bulging portion 19 across the source region 16, 17 in the horizontal direction. In this embodiment, the contact region 18 is formed at an interval from a depth position of the end portion of the recessed portion 20A toward the first main surface 3 side.

The contact region 18 includes a portion that opposes the sub inclined portion 14 across the source region 16, 17 in the horizontal direction and a portion that opposes the first bulging portion 19A across the source region 16, 17 in the horizontal direction. The contact region 18 does not include a portion that opposes the recessed portion 20A (second bulging portion 19B) in the horizontal direction.

Referring to FIG. 10D, the body structure 12 according to the fourth configuration example has a form in which the first bulging portion 19A is changed in the body region 13 according to the third configuration example. In this embodiment, the first bulging portion 19A is formed by a portion of the body region 13 in which the body width WB gradually increases and decreases, and includes an end portion that is set back toward the inner side of the body region 13 with respect to the end portion of the sub inclined portion 14. In this embodiment, the end portion of the first bulging portion 19A opposes the sub inclined portion 14 in the thickness direction. The first bulging portion 19A has a first thickness thicker than the thickness of the sub inclined portion 14. As a matter of course, the first thickness may be thinner than the thickness of the sub inclined portion 14.

The first bulging portion 19A forms a recessed portion 20B that is recessed in the horizontal direction toward the inner side of the body region 13 at a boundary portion (connection portion) with the sub inclined portion 14, and opposes the sub inclined portion 14 across the recessed portion 20B. In a case where a vertical line passing through the end portion of the first bulging portion 19A in the vertical direction Z in a cross-sectional view is set, the recessed portion 20B includes an end portion that is recessed toward the inner side of the body region 13 from the vertical line. The end portion of the recessed portion 20B is located on the sub inclined portion 14 side with respect to the end portion of the recessed portion 20A in the horizontal direction. A configuration without the recessed portion 20A and the recessed portion 20B corresponds to the body region 13 according to the second configuration example.

The source region 16, 17 includes a portion that opposes the sub inclined portion 14 in the horizontal direction and a portion that opposes the first bulging portion 19A in the horizontal direction. In this embodiment, the source region 16, 17 opposes the recessed portion 20B in the horizontal direction. The contact region 18 includes a portion that opposes the sub inclined portion 14 across the source region 16, 17 in the horizontal direction and a portion that opposes the first bulging portion 19A across the source region 16, 17 in the horizontal direction. In this embodiment, the contact region 18 opposes the recessed portion 20B across the source region 16, 17 in the horizontal direction.

Referring to FIG. 10E, the body structure 12 according to the fifth configuration example has a form in which the sub inclined portion 14 of the body region 13 according to the first configuration example is changed. In this embodiment, the sub inclined portion 14 is formed by a portion of the body region 13 in which the body width WB substantially monotonously decreases, does not protrude in the horizontal direction, and is inclined in the oblique direction with respect to the first main surface 3 at a first inclination angle. Also in this embodiment, the sub inclined portion 14 suppresses a short channel portion from being formed in the upper end portion of the body region 13.

On the other hand, the main inclined portion 15 has a second inclination angle substantially equal to the first inclination angle, and includes a portion that is continuously inclined in the oblique direction from the sub inclined portion 14 along the inclination direction of the sub inclined portion 14. The sub inclined portion 14 according to the fifth configuration example can also be applied to the body structures 12 according to the first to fourth configuration examples.

Referring to FIG. 10F, the body structure 12 according to the sixth configuration example includes a narrowed portion 21 that forms a short channel portion instead of the sub inclined portion 14. Specifically, the narrowed portion 21 is formed by a portion of the body region 13 in which the body width WB increases (gradually increases) in the thickness direction in the upper end portion of the body region 13. The narrowed portion 21 includes a portion that is obliquely inclined with respect to the first main surface 3 in the surface layer portion of the drift region 11, and opposes the first main surface 3 across a portion of the drift region 11.

On the other hand, the main inclined portion 15 is formed by a portion in which the body width WB decreases from a end portion of the narrowed portion 21, and is inclined in the oblique direction with respect to the first main surface 3. In this embodiment, the body gradient GB described above is applied to the main inclined portion 15 when the end portion of the narrowed portion 21 is set as a reference position (a point of 0 μm).

The source region 16, 17 is formed at an interval from a base end portion of the narrowed portion 21 in the surface layer portion of the body region 13. The source region 16, 17 form a relatively-narrow short channel portion between the narrowed portion 21 and the source region 16, 17, and form a relatively-wide channel portion between the main inclined portion 15 and the source region 16, 17.

In a case where the short channel portion does not cause a problem, the body structure 12 according to the sixth configuration example may be adopted. The narrowed portion 21 according to the sixth configuration example can also be applied to the body structures 12 according to the first to fifth configuration examples. Hereinafter, a configuration including the sub inclined portion 14 will be described as a premise, but the sub inclined portion 14 can be replaced with the narrowed portion 21. A specific configuration in this case is obtained by replacing the “sub inclined portion 14” with the “narrowed portion 21” as necessary in the following description.

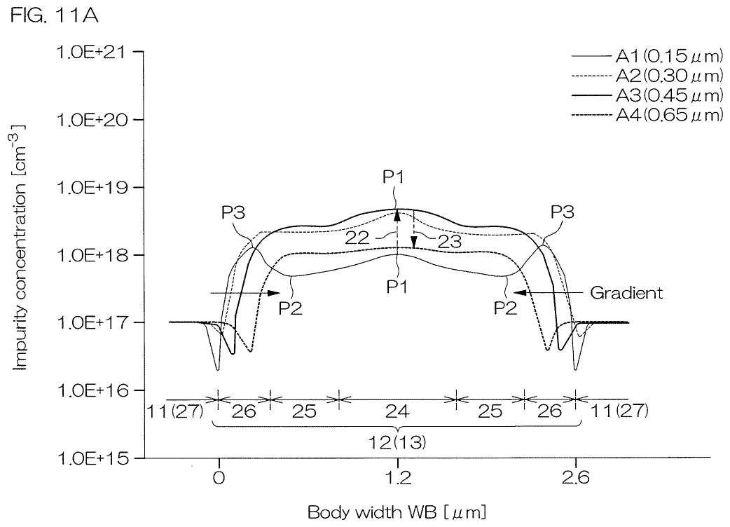

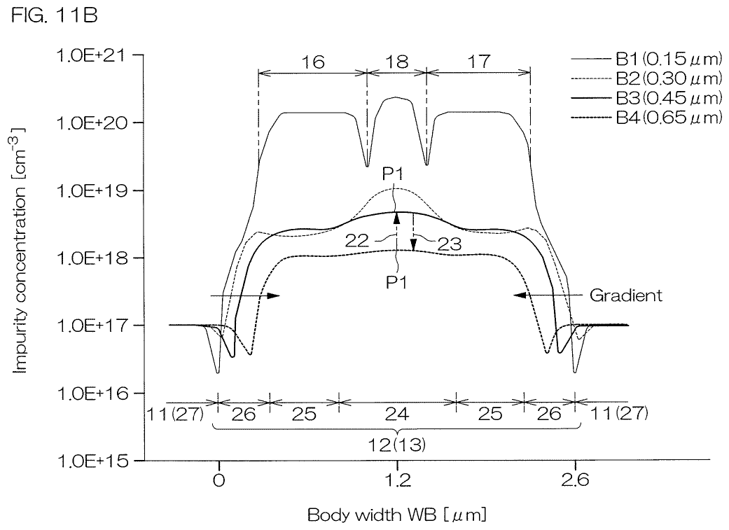

FIG. 11A is a graph showing a concentration gradient in a first region of the body structure 12. The first region of the body structure 12 is a region in which both of the source regions 16 and 17 and the contact region 18 are not formed in the body region 13 in the second direction Y. For example, the first region of the body structure 12 is both end portions of the body region 13 in the second direction Y (refer to also FIG. 5). In FIG. 11A, a vertical axis represents the impurity concentration, and a horizontal axis represents the body width WB. FIG. 11A illustrates an example in which the body width WB is 2.6 μm.

FIG. 11A illustrates a first concentration distribution A1 (thin line), a second concentration distribution A2 (thin broken line), a third concentration distribution A3 (thick line), and a fourth concentration distribution A4 (thick broken line). The first concentration distribution A1 indicates a concentration distribution in the horizontal direction at a thickness position of 0.15 μm in the body region 13 (refer to FIG. 10A). The second concentration distribution A2 indicates a concentration distribution in the horizontal direction at a thickness position of 0.30 μm in the body region 13 (refer to FIG. 10A).

The third concentration distribution A3 indicates a concentration distribution in the horizontal direction at a thickness position of 0.45 μm in the body region 13 (refer to FIG. 10A). The fourth concentration distribution A4 indicates a concentration distribution in the horizontal direction at a thickness position of 0.60 μm in the body region 13 (refer to FIG. 10A). In this example, the intermediate portion of the body region 13 is at a thickness position of 0.35 μm. The first to fourth concentration distributions A1 to A4 indicate the n-type impurity concentration of the drift region 11 and the p-type impurity concentration of the body region 13.

The n-type impurity concentration of the drift region 11 may be 1×10¹⁶ cm⁻³ or higher and 5×10¹⁷ cm⁻³ or lower. The body region 13 has a p-type impurity concentration higher than the n-type impurity concentration of the drift region 11. The p-type impurity concentration of the body region 13 may be 1×10¹⁷ cm⁻³ or higher and 1×10¹⁹ cm⁻³ or lower. Preferably, the body region 13 contains aluminum as a trivalent element.

Referring to the first to fourth concentration distributions A1 to A4, the body region 13 includes a first concentration gradient portion 22 (refer to an upward arrow portion) and a second concentration gradient portion 23 (refer to a downward arrow portion) in the thickness direction. The first concentration gradient portion 22 is a region in which the p-type impurity concentration gradually increases from the upper end portion toward the intermediate portion. The second concentration gradient portion 23 is a region in which the p-type impurity concentration gradually decreases from the first concentration gradient portion 22 toward the lower end portion.

That is, in the body region 13, the p-type impurity concentration on the lower end portion side is lower than the p-type impurity concentration on the upper end portion side. For example, in this embodiment, in the body region 13, the p-type impurity concentration in a thickness range thicker than 0.15 μm and equal to or thinner than 0.60 μm is higher than the p-type impurity concentration of the upper end portion in a thickness range of 0.15 μm or thinner.

The body region 13 has a concentration gradient that gradually decreases from the inner portion side toward the peripheral edge portion side in the horizontal direction. Specifically, the body region 13 includes a first high concentration region 24, a low concentration region 25, and a second high concentration region 26 in the horizontal direction. The first high concentration region 24 is formed in the inner portion of the body region 13. The first high concentration region 24 forms a convex-shaped concentration gradient that is curved upwardly (positive direction), and includes a first maximum value P1 of the p-type impurity concentration.

The first high concentration region 24 has a concentration gradient in which the p-type impurity concentration gradually increases and decreases in the thickness direction along the first concentration gradient portion 22 and the second concentration gradient portion 23. That is, the first high concentration region 24 has a concentration gradient that gradually increases (monotonously increases) in a region on the upper end portion side with respect to the intermediate portion and gradually decreases (monotonously decreases) in a region on the lower end portion side with respect to the intermediate portion. The first high concentration region 24 forms a convex concentration gradient including the first maximum value P1 in both of the region on the upper end portion side with respect to the intermediate portion and the region on the lower end portion side with respect to the intermediate portion.

Preferably, the first high concentration region 24 occupies a range that is equal to or wider than 1/10 of the body region 13 and equal to or narrower than ½ of the body region 13 in the horizontal direction. The occupied range of the first high concentration region 24 may be equal to or wider than ⅕ of the body region 13. Preferably, the occupied range of the first high concentration region 24 is equal to or wider than ¼ of the body region 13.

The low concentration region 25 is formed in a region on the peripheral edge portion side of the body region 13 with respect to the first high concentration region 24, and forms a concentration gradient that gradually decreases from the first high concentration region 24. The low concentration region 25 is a region having a p-type impurity concentration lower than the p-type impurity concentration of the first high concentration region 24. Specifically, the p-type impurity concentration of the low concentration region 25 is lower than the first maximum value P1. The low concentration region 25 forms a concave-shaped concentration gradient that is curved downwardly (negative direction) in the surface portion of the body region 13, and includes a minimum value P2 of the p-type impurity concentration (refer to the first concentration distribution A1).

The low concentration region 25 has a concentration gradient in which the p-type impurity concentration gradually increases and decreases in the thickness direction along the first concentration gradient portion 22 and the second concentration gradient portion 23. That is, the low concentration region 25 has a concentration gradient that gradually increases (monotonously increases) in a region on the upper end portion side with respect to the intermediate portion and gradually decreases (monotonously decreases) in the thickness direction in a region on the lower end portion side with respect to the intermediate portion.

The low concentration region 25 has a concave-shaped concentration gradient including the minimum value P2 in a region on the upper end portion side with respect to the intermediate portion (refer to the first concentration distribution A1). The low concentration region 25 forms a gradual region having a concentration decrease rate which is lower than the concentration decrease rate of the region on the upper end portion side in the region on the lower end portion side with respect to the intermediate portion, and does not have a concave-shaped concentration gradient (minimum value P2).

Therefore, a concentration difference between the first high concentration region 24 and the low concentration region 25 gradually decreases toward the lower end portion of the body region 13. That is, the concentration difference on the lower end portion side is smaller than the concentration difference on the upper end portion side. The low concentration region 25 forms the main inclined portion 15, and is electrically connected to the drift region 11.

The second high concentration region 26 is formed in a peripheral edge portion of the body region 13 (refer to the first concentration distribution A1). The second high concentration region 26 is formed on the peripheral edge portion side of the body region 13 with respect to the low concentration region 25, and forms a concentration gradient that gradually increases from the low concentration region 25. The second high concentration region 26 has a convex-shaped concentration gradient including a second maximum value P3 of the p-type impurity concentration. The second maximum value P3 is larger than the minimum value P2. In this embodiment, the second maximum value P3 is larger than the first maximum value P1. As a matter of course, the second maximum value P3 may be smaller than the first maximum value P1.

The second high concentration region 26 is formed only in the peripheral edge portion of the body region 13 in the surface portion of the body region 13, and is not formed in the region on the lower end portion side of the body region 13. Specifically, the second high concentration region 26 forms the sub inclined portion 14. In other words, the sub inclined portion 14 is a region that includes the second high concentration region 26 and protrudes outwardly from the main inclined portion 15.

The second high concentration region 26 has a concentration gradient that gradually decreases in the thickness direction. The concentration difference between the low concentration region 25 and the second high concentration region 26 gradually decreases from the sub inclined portion 14 toward the main inclined portion 15, and becomes substantially 0 in the main inclined portion 15. That is, the second high concentration region 26 forms substantially the entire region of the sub inclined portion 14. The second high concentration region 26 may partially form a portion (upper portion) of the main inclined portion 15. The second high concentration region 26 may form only the sub inclined portion 14, and may not form the main inclined portion 15.

The second high concentration region 26 is connected to the drift region 11 in a region on the upper end portion side with respect to the intermediate portion. The body region 13 does not necessarily include the second high concentration region 26, and the low concentration region 25 may be formed in the upper end portion of the peripheral edge portion of the body region 13. That is, the sub inclined portion 14 may be formed by the low concentration region 25.

FIG. 11B is a graph showing a concentration gradient in a second region of the body structure 12. The second region of the body structure 12 is a region in which both of the source regions 16 and 17 and the contact region 18 are formed in the body region 13 in the second direction Y. For example, the second region of the body structure 12 is the intermediate portion of the body region 13 in the second direction Y. In FIG. 11B, a vertical axis represents the impurity concentration, and a horizontal axis represents the body width WB.

FIG. 11B illustrates a first concentration distribution B1 (thin line), a second concentration distribution B2 (thin broken line), a third concentration distribution B3 (thick line), and a fourth concentration distribution B4 (thick broken line). The first concentration distribution B1 has a concentration distribution obtained by adding the n-type impurity concentration of the source regions 16 and 17 and the p-type impurity concentration of the contact region 18 to the first concentration distribution A1.

The second concentration distribution B2 has a concentration distribution obtained by adding the n-type impurity concentration of the source regions 16 and 17 on the bottom portion side and the p-type impurity concentration of the contact region 18 on the bottom portion side to the second concentration distribution A2. The third and fourth concentration distributions B3 and B4 respectively correspond to the third and fourth concentration distributions A3 and A4.

The source regions 16 and 17 have the n-type impurity concentration higher than the n-type impurity concentration of the drift region 11. The n-type impurity concentration of the source regions 16 and 17 is higher than the p-type impurity concentration of the body region 13. The n-type impurity concentration of the source regions 16 and 17 is higher than the p-type impurity concentration of the low concentration region 25 (minimum value P2). The n-type impurity concentration of the source regions 16 and 17 is higher than the p-type impurity concentration (first maximum value P1) of the first high concentration region 24. The n-type impurity concentration of the source regions 16 and 17 is higher than the p-type impurity concentration (second maximum value P3) of the second high concentration region 26.

The n-type impurity concentration of the source regions 16 and 17 may be in a range of 1×10¹⁹ cm⁻³ or higher and 1×10²¹ cm⁻³ or lower. Preferably, the source regions 16 and 17 contain phosphorus as a pentavalent element. The source regions 16 and 17 may have a thickness in a range of 0.1 μm or thicker and 0.45 μm or thinner. Preferably, the thickness of the source regions 16 and 17 is in a range of 0.35 μm or thinner.

The contact region 18 has the p-type impurity concentration higher than the p-type impurity concentration of the body region 13. The p-type impurity concentration of the contact region 18 is higher than the p-type impurity concentration of the low concentration region 25 (minimum value P2). The p-type impurity concentration of the contact region 18 is higher than the p-type impurity concentration (first maximum value P1) of the first high concentration region 24. The p-type impurity concentration of the contact region 18 is higher than the p-type impurity concentration (second maximum value P3) of the second high concentration region 26.

In this embodiment, the p-type impurity concentration of the contact region 18 is higher than the n-type impurity concentration of the source regions 16 and 17. As a matter of course, the p-type impurity concentration of the contact region 18 may be lower than the n-type impurity concentration of the source regions 16 and 17. The p-type impurity concentration of the contact region 18 may be in a range of 1×10¹⁹ cm⁻³ or higher and 1×10²¹ cm⁻³ or lower. Preferably, the contact region 18 contains aluminum as a trivalent element. The contact region 18 may have a thickness in a range of 0.1 μm or thicker and 0.45 μm or thinner. Preferably, the thickness of the contact region 18 is in a range of 0.4 μm or thinner.

Referring to the first and second concentration distributions B1 and B2, the source regions 16 and 17 are formed in the low concentration region 25 of the body region 13. Specifically, the source regions 16 and 17 are formed in the low concentration region 25 of the body region 13 such as to be shifted inwardly with respect to the first high concentration region 24 and the second high concentration region 26 of the body region 13.

Thereby, the n-type impurity concentration of the source regions 16 and 17 is suppressed from being offset by the p-type impurity concentration of the first high concentration region 24 and the second high concentration region 26. The both end portions of the source regions 16 and 17 may partially overlap the first high concentration region 24 and the second high concentration region 26.

As a matter of course, the both end portions of the source regions 16 and 17 may be formed at an interval inwardly from the first high concentration region 24 and the second high concentration region 26. In the second concentration distribution B2, the p-type impurity concentration of the low concentration region 25 is lower as compared with the case of the second concentration distribution A2 because the p-type impurity concentration of the low concentration region 25 is offset by the n-type impurity concentration of the source regions 16 and 17 on the bottom portion side.

On the other hand, the contact region 18 is formed in the first high concentration region 24 of the body region 13. Specifically, the contact region 18 is formed in the first high concentration region 24 of the body region 13 such as to be shifted inwardly with respect to the low concentration region 25 and the second high concentration region 26 of the body region 13. Thereby, the p-type impurity concentration of the contact region 18 is increased by the first high concentration region 24.

That is, the first high concentration region 24 enhances an ohmic property of the contact region 18 with respect to the body region 13. In second concentration distribution B2, the p-type impurity concentration of the first high concentration region 24 is increased as compared with the case of the second concentration distribution A2 because the p-type impurity concentration of the contact region 18 on the bottom portion side is added to the p-type impurity concentration of the first high concentration region 24.

Referring to the third and fourth concentration distributions B3 and B4, the body region 13 includes the first high concentration region 24 in a thickness range below the contact region 18. The first high concentration region 24 has a concentration gradient that gradually decreases in the thickness direction in a thickness range below the contact region 18. Specifically, the first high concentration region 24 has a concentration gradient that monotonously decreases from the bottom portion of the contact region 18 toward the lower end portion of the body region 13. The concentration of the first high concentration region 24 on the lower end portion side of the body region 13 is lower than the concentration of the first high concentration region 24 on the bottom portion side of the contact region 18.

The body region 13 includes the low concentration region 25 in a region on the peripheral edge portion side of the body region 13 with respect to the first high concentration region 24 in the thickness range below the contact region 18. Specifically, the body region 13 includes the low concentration region 25 in a thickness range below the source regions 16 and 17.

The low concentration region 25 has a concentration gradient in which the impurity concentration gradually decreases in the thickness direction in the thickness range below the source regions 16 and 17. Specifically, the low concentration region 25 has a concentration gradient that monotonously decreases from the bottom portion (excluding the offset portion) of the source regions 16 and 17 toward the lower end portion of the body region 13. The concentration of the low concentration region 25 on the lower end portion side of the body region 13 is lower than the concentration of the low concentration region 25 on the bottom portion side of the source regions 16 and 17.

In the thickness range below the contact region 18, the concentration decrease rate of the low concentration region 25 is lower than the concentration decrease rate of the high concentration region. Therefore, a concentration difference between the high concentration region and the low concentration region 25 gradually decreases toward the lower end portion of the body region 13. That is, in the thickness range below the contact region 18, the concentration difference on the lower end portion side of the body region 13 is smaller than the concentration difference on the bottom portion side of the contact region 18.

Referring again to FIG. 6, FIG. 7, and FIG. 10A, the semiconductor device 1A includes a plurality of n-type surface layer drift regions 27 that are formed in a surface layer portion of the first main surface 3. In this embodiment, each of the surface layer drift regions 27 includes a portion of the drift region 11. As a matter of course, the surface layer drift regions 27 may have an n-type impurity concentration higher than the n-type impurity concentration of the drift region 11, or may have an n-type impurity concentration lower than the n-type impurity concentration of the drift region 11.

The surface layer drift regions 27 are defined in regions between the body regions 13 adjacent to each other in the first direction X in the surface layer portion of the drift region 11. That is, the surface layer drift regions 27 are arranged at intervals in the first direction X, and are respectively formed in a band shape extending in the second direction Y. Also, the surface layer drift regions 27 are formed in a stripe shape extending in the second direction Y. Hereinafter, a configuration of one surface layer drift region 27 will be described.

The surface layer drift region 27 has a drift width WD of 0.1 μm or wider and 5 μm or narrower in the horizontal direction (in this embodiment, the first direction X). Preferably, the drift width WD is narrower than the body width. As a matter of course, the drift width WD may be wider than the body width WB. Preferably, the drift width WD is in a range of 0.2 μm or wider and 2 μm or narrower.

The drift width WD may have a value in at least one range among a range of 0.1 μm or wider and 0.5 μm or narrower, a range of 0.5 μm or wider and 1 μm or narrower, a range of 1 μm or wider and 1.5 μm or narrower, a range of 1.5 μm or wider and 2 μm or narrower, a range of 2 μm or wider and 2.5 μm or narrower, a range of 2.5 μm or wider and 3 μm or narrower, a range of 3 μm or wider and 3.5 μm or narrower, a range of 3.5 μm or wider and 4 μm or narrower, a range of 4 μm or wider and 4.5 μm or narrower, and a range of 4.5 μm or wider and 5 μm or narrower.

The surface layer drift regions 27 are defined in regions between the body regions 13 such that the drift width WD increases in the thickness direction in accordance with the cross-sectional shape of the body region 13. In a case where the body regions 13 include the bulging portions 19, the surface layer drift region 27 includes a portion defined by the bulging portions 19 (refer to FIG. 10B to FIG. 10D).

The surface layer drift region 27 is formed such that the drift width WD increases in the thickness direction with the upper end portion of the body region 13 as a starting point. That is, the drift width WD increases from the upper end portion side toward the lower end portion side in the entire thickness range between the upper end portion and the lower end portion of the body region 13.

The surface layer drift region 27 forms an n-type (pnp-type) JFET structure with the body regions 13 located on both sides. The surface layer drift region 27 forms a current path extending in the thickness direction in a region between the body regions 13, and reduces the current constriction effect. That is, a JFET resistance component of the JFET structure is reduced due to the cross-sectional shape (that is, the cross-sectional shape of the surface layer drift regions 27) of the peripheral edge portions of the body regions 13. Also, the surface layer drift region 27 reduces current density in a region between the body regions 13, and reduces electric field concentration on the peripheral edge portions of the body regions 13.

The semiconductor device 1A includes a plurality of p-type channel regions 28 and 29 that are formed in the surface layer portion of the first main surface 3. In this embodiment, the channel regions 28 and 29 are arranged at an interval in the first direction X, and are respectively formed in a band shape extending in the second direction Y. Also, the channel regions 28 and 29 are arranged in a stripe shape extending in the second direction Y.

The channel regions 28 and 29 are formed due to the source regions 16 and 17 in the surface layer portion of the body region 13. Specifically, the channel regions 28 and 29 include a first channel region 28 on one side in the first direction X and a second channel region 29 on the other side in the first direction X. The first channel region 28 is formed in the surface layer portion of the body region 13 due to the first source region 16. The second channel region 29 is formed in the surface layer portion of the body region 13 due to the second source region 17.

The channel regions 28 and 29 are formed in regions between the peripheral edge portion (the surface layer drift regions 27) of the body region 13 and the source regions 16 and 17 in the surface layer portion of the body region 13. That is, the channel regions 28 and 29 include a portion formed along the sub inclined portion 14 and a portion formed along the upper end portion of the main inclined portion 15.

The semiconductor device 1A includes a plurality of planar-electrode-type gate structures 30 that are arranged on the first main surface 3 in the active region 8. The gate structures 30 are arranged at intervals in the first direction X, and are respectively formed in a band shape extending in the second direction Y. That is, the gate structures 30 are arranged in a stripe shape extending in the second direction Y. Also, the extension direction of the gate structures 30 coincides with the off direction of the SiC single crystal.

Each of the gate structures 30 covers the peripheral edge portion of at least one body region 13. Specifically, each of the gate structures 30 covers at least one sub inclined portion 14. Each of the gate structures 30 covers the peripheral edge portion of at least one body region 13, at least one of the source regions 16 and 17, and one surface layer drift region 27 such that the gate structure 30 is located on at least one of the channel regions 28 and 29.

In this embodiment, each of the gate structures 30 is arranged across one surface layer drift region 27 such that the gate structure 30 straddles the peripheral edge portions (sub inclined portions 14) of two adjacent body regions 13, and covers the channel regions 28 and 29. Specifically, each of the gate structures 30 is arranged to straddle the first source region 16 on one body region 13 side and the second source region 17 on the other body region 13 side, and covers the first source region 16, the second source region 17, the surface layer drift region 27, the first channel region 28, and the second channel region 29.

Each of the gate structures 30 partially covers the first source region 16 at an interval from the contact region 18, and exposes a portion of the first source region 16 and the contact region 18 from the first main surface 3. Each of the gate structures 30 partially covers the second source region 17 at an interval from the contact region 18, and exposes a portion of the second source region 17 and the contact region 18 from the first main surface 3.

Hereinafter, a configuration of one gate structure 30 will be described. The gate structure 30 has a laminated structure including an insulating film 31 and a gate electrode 32. The insulating film 31 may include at least one among a silicon oxide film, a silicon nitride film, and a silicon oxynitride film. In this embodiment, the insulating film 31 has a single layer structure including a silicon oxide film. It is particularly preferable that the insulating film 31 includes a silicon oxide film made of an oxide of the chip 2.

The insulating film 31 covers the first main surface 3 in a film shape. The insulating film 31 covers the peripheral edge portion of at least one body region 13. Specifically, the insulating film 31 covers at least one sub inclined portion 14. The insulating film 31 opposes the entire region of the sub inclined portion 14 and the entire region of the main inclined portion 15 in the lamination direction (vertical direction Z).

The insulating film 31 covers the peripheral edge portion of at least one body region 13, at least one of the source regions 16 and 17, and one surface layer drift region 27 such that the insulating film 31 is located on at least one of the channel regions 28 and 29. In this embodiment, the insulating film 31 is arranged across one surface layer drift region 27 such that the insulating film 31 straddles the peripheral edge portions (sub inclined portions 14) of two adjacent body regions 13, and covers the channel regions 28 and 29.

Specifically, the insulating film 31 is arranged to straddle the first source region 16 on one body region 13 side and the second source region 17 on the other body region 13 side, and covers the first source region 16, the second source region 17, the surface layer drift region 27, the first channel region 28, and the second channel region 29.

The insulating film 31 partially covers the first source region 16 at an interval from the contact region 18, and exposes a portion of the first source region 16 and the contact region 18 from the first main surface 3. The insulating film 31 partially covers the second source region 17 at an interval from the contact region 18, and exposes a portion of the second source region 17 and the contact region 18 from the first main surface 3.

The insulating film 31 may have a thickness in a range of 10 nm or thicker and 150 nm or thinner. The thickness of the insulating film 31 may have a value in at least one range among a range of 10 nm or thicker and 25 nm or thinner, a range of 25 nm or thicker and 50 nm or thinner, a range of 50 nm or thicker and 75 nm or thinner, a range of 75 nm or thicker and 100 nm or thinner, a range of 100 nm or thicker and 125 nm or thinner, and a range of 125 nm or thicker and 150 nm or thinner. Preferably, the thickness of the insulating film 31 is in a range of 25 nm or thicker and 75 nm or thinner.

The gate electrode 32 is arranged on the insulating film 31. A gate potential as a control potential is to be applied to the gate electrode 32. The gate electrode 32 may include either one or both of p-type conductive polysilicon and n-type conductive polysilicon. The conductivity type of the gate electrode 32 is adjusted according to a gate threshold voltage to be achieved.

The gate electrode 32 is formed in a band shape extending in the second direction Y. In this embodiment, the gate electrode 32 is formed at an interval inwardly from both ends of the insulating film 31 in the first direction X, and exposes the both end portions of the insulating film 31. The gate electrode 32 covers the peripheral edge portion of at least one body region 13 across the insulating film 31. Specifically, the gate electrode 32 covers at least one sub inclined portion 14 across the insulating film 31. The gate electrode 32 opposes the entire region of the sub inclined portion 14 and the entire region of the main inclined portion 15 across the insulating film 31 in the lamination direction (vertical direction Z).

The gate electrode 32 is arranged on the insulating film 31 such that the gate electrode 32 opposes at least one of the channel regions 28 and 29. Specifically, the gate electrode 32 covers the peripheral edge portion of at least one body region 13, at least one of the source regions 16 and 17, and one surface layer drift region 27 across the insulating film 31. In this embodiment, the gate electrode 32 is arranged across one surface layer drift region 27 such that the gate electrode 32 straddles the peripheral edge portions (sub inclined portions 14) of two adjacent body regions 13, and opposes the channel regions 28 and 29 across the insulating film 31.

Specifically, the gate electrode 32 is arranged to straddle the first source region 16 on one body region 13 side and the second source region 17 on the other body region 13 side, and covers the first source region 16, the second source region 17, the surface layer drift region 27, the first channel region 28, and the second channel region 29 across the insulating film 31.

The gate electrode 32 controls inversion and non-inversion of the channel regions 28 and 29 in response to the gate potential. When the gate potential is to be applied to the gate electrode 32, the channel regions 28 and 29 enter an ON state, and a drain current flows between the drift region 11 and the source regions 16 and 17 via the channel regions 28 and 29 (body region 13). As described above, the transistor structure Tr of the planar-gate-type including the drift region 11 is formed in the inner portion (active region 8) of the chip 2.

Referring to FIG. 4 to FIG. 9, the semiconductor device 1A includes p-type outer body region 35 that is formed in the surface layer portion of the first main surface 3 in the outer peripheral region 9. The outer body region 35 is formed in the surface layer portion of the drift region 11. The outer body region 35 has a p-type impurity concentration higher than the n-type impurity concentration of the drift region 11. The p-type impurity concentration of the outer body region 35 may be in a range of 1×10¹⁷ cm⁻³ or higher and 1×10¹⁹ cm⁻³ or lower.

Preferably, the outer body region 35 is simultaneously formed with the body region 13, and has a p-type impurity concentration substantially equal to the p-type impurity concentration of the body region 13. In this case, preferably, the outer body region 35 has a concentration gradient similar to the concentration gradient of the body region 13. As a matter of course, the p-type impurity concentration of the outer body region 35 may be lower than the p-type impurity concentration of the body region 13, or may be higher than the p-type impurity concentration of the body region 13.

The outer body region 35 is formed at an interval from the peripheral edge (first to fourth side surfaces 5A to 5D) of the first main surface 3 toward the active region 8 side in the surface layer portion of the drift region 11, and extends in a band shape along the active region 8. The outer body region 35 includes a portion extending in a band shape in the first direction X and a portion extending in a band shape in the second direction Y in a plan view, and defines the body regions 13 (active region 8) from a plurality of directions.

In this embodiment, the outer body region 35 collectively surrounds the body regions 13 (active region 8) in a plan view, and is defined in a polygonal round shape (in this embodiment, a quadrangular round shape) having four sides parallel to the peripheral edge of the first main surface 3. That is, the outer body region 35 forms a boundary portion between the active region 8 and the outer peripheral region 9. The outer body region 35 may include an edge portion that connects the portion extending in the first direction X and the portion extending in the second direction Y in a circular arc shape (preferably, a quarter arc shape) in a plan view (refer to FIG. 4).

The outer body region 35 is exposed from the first main surface 3. The outer body region 35 is formed at an interval from the bottom portion of the drift region 11 toward the first main surface 3 side, and opposes the drain region 10 across a portion of the drift region 11. Preferably, the outer body region 35 is formed at an interval from the intermediate portion of the drift region 11 toward the first main surface 3 side. As a matter of course, the outer body region 35 may traverse a depth position of the intermediate portion of the drift region 11 in the thickness direction.

The outer body region 35 includes an inner edge portion on the active region 8 side and an outer edge portion on the peripheral edge side of the first main surface 3. The inner edge portion of the outer body region 35 is connected to the body regions 13 in a portion extending in the first direction X, and defines the body regions 13 and the surface layer drift regions 27 in the surface layer portion of the drift region 11.

That is, the outer body region 35 is electrically connected to the body regions 13. Thereby, the source potential is to be applied to the outer body region 35 via the body regions 13. The outer body region 35 forms a pn-junction portion with the drift region 11, and expands a depletion layer to the drift region 11 when a reverse bias voltage is applied.

The outer body region 35 is connected to the body regions 13 at an interval in the second direction Y from the source regions 16 and 17. Therefore, the outer body region 35 does not include the source regions 16 and 17 in the surface layer portion. Also, the outer body region 35 is connected to the body regions 13 at an interval in the second direction Y from the contact region 18. Therefore, the outer body region 35 does not include the contact region 18 in the surface layer portion.

Preferably, the outer body region 35 has a width wider than the width of the body region 13. The width of the outer body region 35 is a width in a direction orthogonal to the extension direction. As a matter of course, the width of the outer body region 35 may be substantially equal to the width of the body region 13, or may be narrower than the thickness of the body region 13.

A ratio of the width of the outer body region 35 to the width of the body region 13 may be 1 or larger and 50 or smaller. The ratio of the width may have a value in at least one range among a range of 1 or larger and 10 or smaller, a range of 10 or larger and 20 or smaller, a range of 20 or larger and 30 or smaller, a range of 30 or larger and 40 or smaller, and a range of 40 or larger and 50 or smaller. Preferably, the ratio of the width is in a range of 10 or larger. Preferably, the ratio of the width is in a range of 20 or larger and 40 or smaller.

Preferably, the outer body region 35 has a thickness (depth) substantially equal to the thickness (depth) of the body region 13. As a matter of course, the thickness of the outer body region 35 may be thinner than the thickness of the body region 13, or may be thicker than the thickness of the body region 13.

The semiconductor device 1A includes a p-type terminal region 40 that is formed in the first main surface 3 in the outer peripheral region 9. The terminal region 40 may be referred to as a “well region,” a “terminal well region,” etc. The terminal region 40 is formed in the surface layer portion of the drift region 11 in the outer peripheral region 9. A p-type impurity concentration of the terminal region 40 may be in a range of 1×10¹⁷ cm⁻³ or higher and 1×10²⁰ cm⁻³ or lower.

The terminal region 40 may have a p-type impurity concentration different from the p-type impurity concentration of the body region 13. The p-type impurity concentration of the terminal region 40 may be higher than the p-type impurity concentration of the body region 13, or may be lower than the p-type impurity concentration of the body region 13. As a matter of course, the p-type impurity concentration of the terminal region 40 may be substantially equal to the p-type impurity concentration of the body region 13.

The terminal region 40 may have a p-type impurity concentration different from the p-type impurity concentration of the outer body region 35. The p-type impurity concentration of the terminal region 40 may be higher than the p-type impurity concentration of the outer body region 35, or may be lower than the p-type impurity concentration of the outer body region 35. As a matter of course, the p-type impurity concentration of the terminal region 40 may be substantially equal to the p-type impurity concentration of the outer body region 35.

The terminal region 40 is formed in a region between the peripheral edge of the first main surface 3 and the outer body region 35 at an interval inwardly from the peripheral edge of the first main surface 3. The terminal region 40 extends in a band shape along the outer body region 35 in a plan view. The terminal region 40 includes a portion extending in a band shape in the first direction X and a portion extending in a band shape in the second direction Y in a plan view, and defines the active region 8 from a plurality of directions.

In this embodiment, the terminal region 40 surrounds the outer body region 35 (the active region 8 and the body regions 13) in a plan view, and is defined in a polygonal round shape (in this embodiment, a quadrangular round shape) having four sides parallel to the peripheral edge of the first main surface 3. The terminal region 40 may include an edge portion that connects the portion extending in the first direction X and the portion extending in the second direction Y in a circular arc shape (preferably, a quarter arc shape) in a plan view (refer to FIG. 4).

The terminal region 40 is formed at an interval from the bottom portion of the drift region 11 toward the first main surface 3 side, and opposes the drain region 10 across a portion of the drift region 11. Preferably, the terminal region 40 is formed at an interval from the intermediate portion of the drift region 11 toward the first main surface 3 side. As a matter of course, the terminal region 40 may traverse a depth position of the intermediate portion of the drift region 11 in the thickness direction. The terminal region 40 may have a thickness (depth) substantially equal to the thickness (depth) of the outer body region 35. The thickness of the terminal region 40 may be thicker than the thickness of the outer body region 35, or may be thinner than the thickness of the outer body region 35.

The terminal region 40 includes an inner edge portion on the active region 8 side and an outer edge portion on the peripheral edge side of the first main surface 3. The inner edge portion of the terminal region 40 is connected to the outer edge portion of the outer body region 35 in the surface layer portion of the drift region 11. Thereby, the terminal region 40 is electrically connected to the outer body region 35. Also, the terminal region 40 is electrically connected to the body regions 13 via the outer body region 35. The terminal region 40 forms a pn-junction portion with the drift region 11, and expands a depletion layer to the drift region 11 when a reverse bias voltage is applied.

In this embodiment, the inner edge portion of the terminal region 40 is connected to the outer edge portion of the outer body region 35 over the entire periphery. In a case where the terminal region 40 has a p-type impurity concentration substantially equal to the p-type impurity concentration of the outer body region 35, the terminal region 40 may be regarded as a portion (lead-out portion) of the outer body region 35.

The terminal region 40 (inner edge portion) includes an overlap region 41 overlapping the outer edge portion of the outer body region 35 in the surface layer portion of the drift region 11. The overlap region 41 is a high concentration region including the outer edge portion of the outer body region 35 and the inner edge portion of the terminal region 40. That is, the overlap region 41 includes both of the p-type impurity of the outer body region 35 and the p-type impurity of the terminal region 40, and has a p-type impurity concentration higher than both of the p-type impurity concentration of the outer body region 35 and the p-type impurity concentration of the terminal region 40.

The p-type impurity concentration of the overlap region 41 is higher than the p-type impurity concentration of the body region 13. The p-type impurity concentration of the overlap region 41 may be lower than the p-type impurity concentration of the contact region 18. As a matter of course, the p-type impurity concentration of the overlap region 41 may be higher than the p-type impurity concentration of the contact region 18.

The overlap region 41 extends in a band shape along the outer body region 35 in a plan view. The overlap region 41 includes a portion extending in a band shape in the first direction X and a portion extending in a band shape in the second direction Y in a plan view, and defines the active region 8 from a plurality of directions. In this embodiment, the overlap region 41 is defined in a polygonal round shape (in this embodiment, a quadrangular round shape) having four sides parallel to the peripheral edge of the first main surface 3.

The overlap region 41 may include an edge portion that connects the portion extending in the first direction X and the portion extending in the second direction Y in a circular arc shape (preferably, a quarter arc shape) in a plan view (refer to FIG. 4). Preferably, a width of the overlap region 41 is wider than the width of the body region 13. As a matter of course, the width of the overlap region 41 may be narrower than the width of the body region 13.

The semiconductor device 1A may include a p-type well region (46) having a relatively high concentration instead of the overlap region 41. In this case, the well region (46) has a p-type impurity concentration higher than both of the p-type impurity concentration of the outer body region 35 and the p-type impurity concentration of the terminal region 40.

The p-type impurity concentration of the well region (46) is higher than the p-type impurity concentration of the body region 13. The p-type impurity concentration of the well region (46) may be substantially equal to the p-type impurity concentration of the contact region 18. As a matter of course, the p-type impurity concentration of the well region (46) may be lower than the p-type impurity concentration of the contact region 18, or may be higher than the p-type impurity concentration of the contact region 18.

The well region (46) may be formed in any one or both of the surface layer portion of the outer body region 35 and the surface layer portion of the terminal region 40. Such a configuration is effective in a case where the terminal region 40 has a p-type impurity concentration substantially equal to the p-type impurity concentration of the outer body region 35 and is formed as a portion (lead-out portion) of the outer body region 35.

The semiconductor device 1A includes at least one p-type field region 42 that is formed in the surface layer portion of the first main surface 3 in the outer peripheral region 9. A plurality of field regions 42 may be formed in an electrically floating state. The field regions 42 may be fixed to the source potential.

The number of the field region 42 is arbitrary. The number of the field region 42 may be 1 or more and 20 or less. The number of the field region 42 may have a value in at least one range among a range of 1 or more and 5 or less, a range of 5 or more and 10 or less, a range of 10 or more and 15 or less, and a range of 15 or more and 20 or less. The number of the field region 42 is typically 1 or more and 8 or less. In this embodiment, the semiconductor device 1A includes three field regions 42.

The field regions 42 are formed in the surface layer portion of the drift region 11. The field regions 42 are formed in a region between the peripheral edge of the first main surface 3 and the body regions 13 (the active region 8) at an interval inwardly from the peripheral edge of the first main surface 3. Specifically, the field regions 42 are formed in a region between the peripheral edge of the first main surface 3 and the outer body region 35. More specifically, the field regions 42 are arranged at an interval from the outer edge portion of the terminal region 40 toward the peripheral edge side of the first main surface 3 in a region between the peripheral edge of the first main surface 3 and the terminal region 40.

The field regions 42 are formed in band shapes extending along the body regions 13 (terminal region 40) in a plan view. Each of the field regions 42 includes a portion extending in a band shape in the first direction X and a portion extending in a band shape in the second direction Y. In this embodiment, the field regions 42 are formed in a polygonal round shape (in this embodiment, a quadrangular round shape) surrounding the body regions 13 (terminal region 40) in a plan view. The field regions 42 may include an edge portion that connects the portion extending in the first direction X and the portion extending in the second direction Y in a circular arc shape (preferably, a quarter arc shape) (refer to FIG. 4).

The field regions 42 are formed at an interval from the depth position of the bottom portion of the drift region 11 toward the first main surface 3 side. Preferably, the field regions 42 are formed at an interval from the depth position of the intermediate portion of the drift region 11 toward the first main surface 3 side. As a matter of course, the field regions 42 may traverse the depth position of the intermediate portion of the drift region 11 in the thickness direction. Each of the field regions 42 forms a pn-junction portion with the drift region 11, and expands a depletion layer to the drift region 11 when a reverse bias voltage is applied.

The widths, the depths, the intervals, the p-type impurity concentrations, etc., of the field regions 42 are arbitrary, and can take various values according to the electric field to be relaxed. The widths of the field regions 42 may be substantially constant, or may be non-uniform. The widths of the field regions 42 may gradually increase toward the peripheral edge side of the first main surface 3. The widths of the field regions 42 may gradually decrease toward the peripheral edge side of the first main surface 3.

The depths of the field regions 42 may be substantially constant, or may be non-uniform. The depths of the field regions 42 may gradually increase toward the peripheral edge side of the first main surface 3. The depths of the field regions 42 may gradually decrease toward the peripheral edge side of the first main surface 3. As a matter of course, the field regions 42 may include a relatively shallow portion and a deep portion that is deeper than the shallow portion. The shallow portion may be formed on the inner side, and the deep portion may be formed on the peripheral edge side. The shallow portion may be formed on the peripheral edge side, and the deep portion may be formed on the inner side.

The intervals of the field regions 42 may be substantially constant, or may be non-uniform. The intervals of the field regions 42 may gradually increase toward the peripheral edge side of the first main surface 3. The intervals of the field regions 42 may gradually decrease toward the peripheral edge side of the first main surface 3.

The p-type impurity concentrations of the field regions 42 may be substantially constant, or may be non-uniform. The p-type impurity concentrations of the field regions 42 may gradually increase toward the peripheral edge side of the first main surface 3. The p-type impurity concentrations of the field regions 42 may gradually decrease toward the peripheral edge side of the first main surface 3.

The field regions 42 may be simultaneously formed with the body region 13, and may have a p-type impurity concentration substantially equal to the p-type impurity concentration of the body region 13. In this case, the field regions 42 may have a concentration gradient similar to the concentration gradient of the body region 13. The p-type impurity concentrations of the field regions 42 may be higher than the p-type impurity concentration of the body region 13 (outer body region 35), or may be lower than the p-type impurity concentration of the body region 13 (outer body region 35).

The p-type impurity concentrations of the field regions 42 may be substantially equal to the p-type impurity concentration of the terminal region 40. The p-type impurity concentrations of the field regions 42 may be higher than the p-type impurity concentration of the terminal region 40, or may be lower than the p-type impurity concentration of the terminal region 40. The p-type impurity concentrations of the field regions 42 may be in a range of 1×10¹⁷ cm⁻³ or higher and 1×10²⁰ cm⁻³ or lower.

The semiconductor device 1A includes an outer peripheral insulating film 43 that covers the first main surface 3 in the outer peripheral region 9. The outer peripheral insulating film 43 may include at least one among a silicon oxide film, a silicon nitride film, and a silicon oxynitride film. In this embodiment, the outer peripheral insulating film 43 has a single layer structure including a silicon oxide film. It is particularly preferable that the outer peripheral insulating film 43 includes a silicon oxide film which is made of an oxide of the chip 2. Preferably, the outer peripheral insulating film 43 is made of the same kind of insulating material as the insulating material of the insulating film 31. Preferably, the outer peripheral insulating film 43 has a thickness substantially equal to the thickness of the insulating film 31.

The outer peripheral insulating film 43 covers the first main surface 3 in a film shape in the outer peripheral region 9. The outer peripheral insulating film 43 collectively covers the drift region 11, the outer body region 35, the terminal region 40, and the field regions 42. The outer peripheral insulating film 43 is connected to the insulating films 31 on the active region 8 side. Specifically, the outer peripheral insulating film 43 is integrally formed with the insulating films 31, and forms one insulating film with the insulating films 31.

The semiconductor device 1A includes a gate wiring 44 arranged on the first main surface 3 in the outer peripheral region 9. The gate wiring 44 is selectively drawn onto the first main surface 3, and includes a portion extending in a direction different from the extending direction of the gate electrodes 32. The gate wiring 44 is connected to the gate electrodes 32, and applies a gate signal to the gate electrodes 32. The gate wiring 44 may be referred to as a “second gate electrode,” etc.

The gate wiring 44 may include either one or both of p-type conductive polysilicon and n-type conductive polysilicon. Preferably, the gate wiring 44 has the same conductivity type as the conductivity type of the gate electrode 32.

The gate wiring 44 is arranged on the outer peripheral insulating film 43 at an interval from the peripheral edge of the first main surface 3 toward the active region 8 side in the outer peripheral region 9. In this embodiment, the gate wiring 44 is arranged at an interval from the terminal region 40 toward the active region 8 side, and is arranged on a portion of the outer peripheral insulating film 43 that covers the outer body region 35. That is, the gate wiring 44 opposes the outer body region 35 across the outer peripheral insulating film 43. The gate wiring 44 may be arranged at a position that opposes the terminal region 40 in the lamination direction.

The gate wiring 44 extends in a band shape along the body regions 13 (active region 8) in a plan view. The gate wiring 44 includes a portion extending in a band shape in the first direction X and a portion extending in a band shape in the second direction Y in a plan view, and defines the body regions 13 (active region 8) from a plurality of directions. In this embodiment, the gate wiring 44 surrounds the body regions 13 (active region 8) in a plan view, and is defined in a polygonal round shape (in this embodiment, a quadrangular round shape) having four sides parallel to the peripheral edge of the first main surface 3. The gate wiring 44 may have an end shape or an endless shape.

In this embodiment, the gate wiring 44 extends in a band shape (in this embodiment, a round shape) along the outer body region 35 in a plan view, and opposes the outer body region 35 over the entire range in the lamination direction across the outer peripheral insulating film 43. The gate wiring 44 may include an edge portion that connects the portion extending in the first direction X and the portion extending in the second direction Y in a circular arc shape (preferably, a quarter arc shape) in a plan view (refer to FIG. 4).

The gate wiring 44 is formed to be narrower than the outer body region 35 in a plan view, and is arranged on the outer body region 35 at an interval from the inner edge portion and the outer edge portion of the outer body region 35. That is, in this embodiment, the gate electrodes 32 are led out onto the outer body region 35, and the gate wiring 44 is connected to the gate electrodes 32 on the outer body region 35.

Preferably, a thickness of the gate wiring 44 is substantially equal to the thickness of the gate electrode 32. Preferably, a width of the gate wiring 44 is wider than the width of the gate electrode 32. The width of the gate wiring 44 is a width in a direction orthogonal to the extension direction. For example, the ratio of the width of the gate wiring 44 to the width of the gate electrode 32 may be 1 or larger and 50 or smaller.

The ratio of the width may have a value in at least one range among a range of 1 or larger and 10 or smaller, a range of 10 or larger and 20 or smaller, a range of 20 or larger and 30 or smaller, a range of 30 or larger and 40 or smaller, and a range of 40 or larger and 50 or smaller. The ratio of the width may be 5 or larger. The ratio of the width may be 20 or larger and 40 or smaller. As a matter of course, the width of the gate wiring 44 may be equal to or narrower than the width of the gate electrode 32. The width of the gate wiring 44 may be wider than the width of the outer body region 35.

The semiconductor device 1A includes an interlayer film 50 of an insulating property that covers the first main surface 3. The interlayer film 50 may be referred to as an “interlayer insulating film,” an “intermediate insulating film,” etc. The interlayer film 50 has an insulating surface 51 extending along the first main surface 3. The interlayer film 50 collectively covers the active region 8 and the outer peripheral region 9 on the first main surface 3.

The interlayer film 50 covers the gate structures 30 in the active region 8. The interlayer film 50 collectively covers the drift region 11, the outer body region 35, the terminal region 40, and the field regions 42 across the outer peripheral insulating film 43 in the outer peripheral region 9. The interlayer film 50 covers the gate wiring 44 in the outer peripheral region 9. The interlayer film 50 is continuous with the first to fourth side surfaces 5A to 5D. The interlayer film 50 may be formed at an interval inwardly from the first to fourth side surfaces 5A to 5D, and expose the peripheral edge portion (drift region 11) of the first main surface 3.

In this embodiment, the interlayer film 50 has a laminated structure including a first oxide film 52 (first insulating film) and a second oxide film 53 (second insulating film) laminated in this order from the first main surface 3 side. That is, the interlayer film 50 has an insulating surface 51 formed by the second oxide film 53. The first oxide film 52 has a single layer structure made of a silicon oxide film with no impurity added. The first oxide film 52 may be referred to as a non-doped silicate glass film (NSG). In this embodiment, the first oxide film 52 has a thickness thinner than the thickness of the gate electrode 32. As a matter of course, the thickness of the first oxide film 52 may be thicker than the thickness of the gate electrode 32.

The first oxide film 52 collectively covers the active region 8 and the outer peripheral region 9. The first oxide film 52 collectively covers the gate structures 30 in the active region 8. The first oxide film 52 covers both of the insulating film 31 and the gate electrode 32 of each gate structure 30 in a film shape.

The first oxide film 52 includes a portion that covers the insulating film 31 (first main surface 3) in a film shape along the horizontal direction. The first oxide film 52 covers the insulating film 31 at an interval from a height position of the electrode surface (upper end) of the gate electrode 32 toward the insulating film 31 side. The first oxide film 52 includes a portion extending in a film shape in the lamination direction along the side wall of the gate electrode 32.

The first oxide film 52 includes a portion that covers the electrode surface of the gate electrode 32 in a film shape along the horizontal direction. Preferably, the first oxide film 52 includes an arc corner portion that is curved in a circular arc shape in a portion that covers the corner portion of the gate electrode 32. The arc corner portion may have a center of curvature on the gate electrode 32 side.

The first oxide film 52 collectively covers the drift region 11, the outer body region 35, the terminal region 40, and the field regions 42 across the outer peripheral insulating film 43 in the outer peripheral region 9. The first oxide film 52 covers the gate wiring 44 in the outer peripheral region 9.

The first oxide film 52 includes a portion that covers the outer peripheral insulating film 43 (first main surface 3) in a film shape along the horizontal direction. The first oxide film 52 covers the outer peripheral insulating film 43 at an interval from a height position of a wiring surface (upper end) of the gate wiring 44 toward the outer peripheral insulating film 43 side. The first oxide film 52 includes a portion extending in a film shape in the lamination direction along the side wall of the gate wiring 44.

The first oxide film 52 includes a portion that covers the wiring surface of the gate wiring 44 in a film shape along the horizontal direction. Preferably, the first oxide film 52 includes an arc corner portion that is curved in a circular arc shape in a portion that covers the corner portion of the gate wiring 44. The arc corner portion may have a center of curvature on the gate wiring 44 side.

The second oxide film 53 may have a single layer structure made of a silicon oxide film containing phosphorus or a laminated structure including a silicon oxide film containing phosphorus. The silicon oxide film containing phosphorus may contain boron. The silicon oxide film containing phosphorus may be referred to as a phosphorus silicon glass film (PSG film). The silicon oxide film containing both of phosphorus and boron may be referred to as a boron phosphorus silicon glass film (BPSG film).

The second oxide film 53 may have a single layer structure including a PSG film or a BPSG film laminated on the first oxide film 52. The second oxide film 53 may have a laminated structure including a PSG film laminated on the first oxide film 52 and a BPSG film laminated on the PSG film. The second oxide film 53 may have a laminated structure including a BPSG film laminated on the first oxide film 52 and a PSG film laminated on the BPSG film.

In this embodiment, the second oxide film 53 has a single layer structure made of a PSG film as an example. The thickness of the second oxide film 53 may be thicker than the thickness of the first oxide film 52. The second oxide film 53 may have a thickness thinner than the thickness of the first oxide film 52. The thickness of the second oxide film 53 may be thicker than the thickness of the gate electrode 32. The second oxide film 53 may have a thickness thinner than the thickness of the gate electrode 32.

The second oxide film 53 covers the first oxide film 52 in a film shape, and collectively covers the active region 8 and the outer peripheral region 9 across the first oxide film 52. The second oxide film 53 collectively covers the gate structures 30 across the first oxide film 52 in the active region 8. Specifically, the second oxide film 53 covers both of the insulating film 31 and the gate electrode 32 in a film shape across the first oxide film 52.

The second oxide film 53 includes a portion that covers the insulating film 31 across the first oxide film 52. The second oxide film 53 extends in a film shape in the lamination direction along the side wall of the gate electrode 32, and includes a portion that covers the side wall of the gate electrode 32 across the first oxide film 52. The second oxide film 53 extends in a film shape along the horizontal direction along the electrode surface of the gate electrode 32, and includes a portion that covers the electrode surface of the gate electrode 32 across the first oxide film 52. Preferably, the second oxide film 53 includes an arc corner portion that is curved in a circular arc shape in a portion that covers the corner portion of the gate electrode 32. The arc corner portion may have a center of curvature on the gate electrode 32 side.

The second oxide film 53 collectively covers the drift region 11, the outer body region 35, the terminal region 40, and the field regions 42 across the outer peripheral insulating film 43 and the first oxide film 52 in the outer peripheral region 9. The second oxide film 53 covers the gate wiring 44 across the first oxide film 52 in the outer peripheral region 9.

The second oxide film 53 includes a portion that covers the outer peripheral insulating film 43 across the first oxide film 52. The second oxide film 53 extends in a film shape in the lamination direction along the side wall of the gate wiring 44, and includes a portion that covers the side wall of the gate wiring 44 across the first oxide film 52. The second oxide film 53 extends in a film shape in the horizontal direction along the wiring surface of the gate wiring 44, and includes a portion that covers the wiring surface of the gate wiring 44 across the first oxide film 52. Preferably, the second oxide film 53 includes an arc corner portion that is curved in a circular arc shape in a portion that covers the corner portion of the gate wiring 44. The arc corner portion may have a center of curvature on the gate wiring 44 side.

The semiconductor device 1A includes a plurality of source openings 54 formed in the interlayer film 50 in the active region 8. The source openings 54 are formed at intervals from the gate electrodes 32 in regions on side of the gate electrodes 32, and expose the first main surface 3 (chip 2). Specifically, the source openings 54 penetrate the insulating film 31 and the interlayer film 50 in regions between the gate electrodes 32.

The source openings 54 have wall surfaces that penetrate both of the first oxide film 52 and the second oxide film 53 and are defined by both of the first oxide film 52 and the second oxide film 53. Each of the source openings 54 has an opening end portion defined by the arc corner portion of the interlayer film 50. Each of the source openings 54 exposes the corresponding source regions 16 and 17 and the corresponding contact region 18.

In this embodiment, the source openings 54 are formed at an interval in the first direction X, and are respectively formed in a band shape extending in the second direction Y. That is, the source openings 54 are formed in a stripe shape extending in the second direction Y. The source openings 54 are formed at an interval from the gate wiring 44 in the second direction Y. That is, the source openings 54 are formed in regions surrounded by the gate electrodes 32 and the gate wiring 44.

The source openings 54 may be formed in regions between two gate structures 30 adjacent to each other in the first direction X. In this case, the source openings 54 may be formed at an interval in a line in the second direction Y. Further, in this case, each source opening 54 may be formed in a quadrangular shape (square shape) in a plan view, a rectangular shape extending in the first direction X, a rectangular shape extending in the second direction Y, a hexagonal shape, a circular shape, etc.

The source opening 54 may have a width W of 0.1 μm or wider and 3 μm or narrower. The width W of the source opening 54 may have a value in at least one range among a range of 0.1 μm or wider and 0.25 μm or narrower, a range of 0.25 μm or wider and 0.5 μm or narrower, a range of 0.5 μm or wider and 0.75 μm or narrower, a range of 0.75 μm or wider and 1 μm or narrower, a range of 1 μm or wider and 1.25 μm or narrower, a range of 1.25 μm or wider and 1.5 μm or narrower, a range of 1.5 μm or wider and 1.75 μm or narrower, a range of 1.75 μm or wider and 2 μm or narrower, a range of 2 μm or wider and 2.25 μm or narrower, a range of 2.25 μm or wider and 2.5 μm or narrower, a range of 2.5 μm or wider and 2.75 μm or narrower, and a range of 2.75 μm or wider and 3 μm or narrower. Preferably, the width W of the source opening 54 is in a range of 0.2 μm or wider and 1 μm or narrower.

The source opening 54 may have a depth D of 0.1 μm or deeper and 2 μm or shallower. The depth D of the source opening 54 may have a value in at least one range among a range of 0.1 μm or deeper and 0.25 μm or shallower, a range of 0.25 μm or deeper and 0.5 μm or shallower, a range of 0.5 μm or deeper and 0.75 μm or shallower, a range of 0.75 μm or deeper and 1 μm or shallower, a range of 1 μm or deeper and 1.25 μm or shallower, a range of 1.25 μm or deeper and 1.5 μm or shallower, a range of 1.5 μm or deeper and 1.75 μm or shallower, and a range of 1.75 μm or deeper and 2 μm or shallower. Preferably, the depth D of the source opening 54 is in a range of 0.5 μm or deeper and 1 μm or shallower.

Preferably, the source opening 54 has an aspect ratio D/W of 0.5 or larger and 3 or smaller. The aspect ratio D/W is defined by a ratio of the depth D of the source opening 54 to the width W of the source opening 54. The aspect ratio D/W may have a value in at least one range among a range of 0.5 or larger and 0.75 or smaller, a range of 0.75 or larger and 1 or smaller, a range of 1 or larger and 1.25 or smaller, a range of 1.25 or larger and 1.5 or smaller, a range of 1.5 or larger and 1.75 or smaller, a range of 1.75 or larger and 2 or smaller, a range of 2 or larger and 2.25 or smaller, a range of 2.25 or larger and 2.5 or smaller, a range of 2.5 or larger and 2.75 or smaller, and a range of 2.75 or larger and 3 or smaller.

Preferably, the aspect ratio D/W is larger than 1. That is, preferably, each of the source openings 54 has the depth D deeper than the width W, and is formed in a vertically long shape in a cross-sectional view. According to this configuration, the gate structures 30 are arranged at a narrow pitch. Preferably, the aspect ratio D/W of the vertically long source opening 54 is larger than 1 and 2 or smaller.

The semiconductor device 1A includes a plurality of source recesses 55 that are respectively formed in portions of the first main surface 3 exposed from the source openings 54. The semiconductor device 1A does not necessarily include the source recess 55. Therefore, a configuration without the source recess 55 may be adopted.

Each of the source recesses 55 has a planar shape that matches the planar shape of the corresponding source opening 54, and is recessed from the first main surface 3 toward the second main surface 4 side. The source recesses 55 are formed at an interval from the lower end portion of the corresponding body region 13 toward the first main surface 3 side, and respectively expose the corresponding source regions 16 and 17 and the corresponding contact region 18.

Specifically, the source recesses 55 are formed at an interval from the bottom portions of the corresponding source regions 16 and 17 (contact regions 18) toward the first main surface 3 side. The source recesses 55 oppose at least the sub inclined portion 14 in the horizontal direction. As a matter of course, the source recesses 55 may oppose both of the sub inclined portion 14 and the main inclined portion 15 in the horizontal direction.

The semiconductor device 1A includes at least one (in this embodiment, a plurality of) outer openings 56 formed in the interlayer film 50 in the outer peripheral region 9. The outer openings 56 are formed in portions of the interlayer film 50 that cover the terminal region 40. The outer openings 56 penetrate the interlayer film 50, and expose the terminal region 40. In this embodiment, the outer openings 56 are formed in portions of the interlayer film 50 that cover the overlap region 41 of the terminal region 40, and expose the overlap region 41.

The outer openings 56 may expose the outer body region 35 instead of or in addition to the terminal region 40 (overlap region 41). The outer openings 56 penetrate both of the first oxide film 52 and the second oxide film 53, and have wall surfaces that are defined by both of the first oxide film 52 and the second oxide film 53. Each of the outer openings 56 has an opening end portion defined by the arc corner portion of the interlayer film 50.

The outer openings 56 are formed at an interval along the terminal region 40 (overlap region 41) (refer to FIG. 4 and FIG. 5). The outer openings 56 may be formed in a quadrangular shape (square shape), a rectangular shape, a hexagonal shape, a circular shape, etc., in a plan view. The outer openings 56 may be formed in a band shape extending along the terminal region 40 (overlap region 41) in a plan view. Similarly to the source opening 54, the outer opening 56 may have the aspect ratio D/W (=0.5 or larger and 3 or smaller, preferably larger than 1).

The semiconductor device 1A may have a single outer opening 56. The single outer opening 56 may be formed in a band shape extending along the terminal region 40 (overlap region 41). The single outer opening 56 may include a portion extending in a band shape in the first direction X and a portion extending in a band shape in the second direction Y in a plan view.

The single outer opening 56 may be formed in a polygonal round shape having four sides parallel to the peripheral edge of the first main surface 3, either with ends or without ends (in this embodiment, a quadrangular round shape). The single outer opening 56 may include an edge portion that connects a portion extending in the first direction X and a portion extending in the second direction Y along the terminal region 40 (overlap region 41) in a plan view in a circular arc shape (preferably, a quarter arc shape) (refer to FIG. 4).

The semiconductor device 1A includes a plurality of outer recesses 57 that are respectively formed in portions of the first main surface 3 exposed from the outer openings 56. The semiconductor device 1A does not necessarily include the outer recess 57. Therefore, a configuration without the outer recess 57 may be adopted.

Each of the outer recesses 57 has a planar shape that matches the planar shape of the corresponding outer opening 56, and is recessed from the first main surface 3 toward the second main surface 4 side. The outer recesses 57 are formed at an interval from the bottom portion of the terminal region 40 (overlap region 41) toward the first main surface 3 side, and respectively expose the terminal region 40 (overlap region 41). The outer recess 57 may have a depth substantially equal to the depth of the source recess 55. In a case where the single outer opening 56 is formed, a single outer recess 57 that matches the planar shape of the single outer opening 56 is formed.

The semiconductor device 1A includes at least one (in this embodiment, a plurality of) gate openings 58 formed in the interlayer film 50 in the outer peripheral region 9. The gate openings 58 are formed in portions that cover the gate wiring 44 in the interlayer film 50. The gate openings 58 penetrate the interlayer film 50, and expose the gate wiring 44. The gate openings 58 penetrate both of the first oxide film 52 and the second oxide film 53, and have wall surfaces that are defined by both of the first oxide film 52 and the second oxide film 53. Each of the gate openings 58 has an opening end defined by the arc corner portion of the interlayer film 50.

The gate openings 58 are formed at an interval along the gate wiring 44 (refer to FIG. 4 and FIG. 5). The gate openings 58 may be formed in a quadrangular shape (square shape), a rectangular shape, a hexagonal shape, a circular shape, etc., in a plan view. The gate openings 58 may be formed in a band shape extending along the gate wiring 44 in a plan view. Similarly to the source opening 54, the gate opening 58 may have the aspect ratio D/W (=0.5 or larger and 3 or smaller, preferably larger than 1).

The semiconductor device 1A may include a single gate opening 58. The single gate opening 58 may be formed in a band shape extending along the gate wiring 44. The single gate opening 58 may include a portion extending in a band shape in the first direction X and a portion extending in a band shape in the second direction Y in a plan view.

The single gate opening 58 may be formed in a polygonal round shape having four sides parallel to the peripheral edge of the first main surface 3, either with ends or without ends (in this embodiment, a quadrangular round shape). The single gate opening 58 may include an edge portion that connects a portion extending in the first direction X and a portion extending in the second direction Y along the gate wiring 44 in a plan view in a circular arc shape (preferably, a quarter arc shape) (refer to FIG. 4).

Referring to FIG. 1, etc., the semiconductor device 1A includes a source pad electrode 60 arranged on the interlayer film 50. The source pad electrode 60 is a terminal electrode to which the source potential is to be applied from the outside. The source pad electrode 60 may be referred to as a “first pad electrode,” a “first main surface electrode,” a “first terminal electrode,” etc.

The source pad electrode 60 is arranged on a portion of the interlayer film 50 that covers the active region 8. The source pad electrode 60 covers the gate electrodes 32 across the interlayer film 50, and is electrically separated from the gate electrodes 32 by the interlayer film 50. The source pad electrode 60 is electrically connected to the body regions 13, the source regions 16 and 17, the contact region 18, etc., via the source openings 54.

In this embodiment, the source pad electrode 60 includes a first pad portion 60a, a second pad portion 60b, and a third pad portion 60c. The first pad portion 60a has a relatively large planar area, and forms a main body of the source pad electrode 60. In this embodiment, the first pad portion 60a is formed in a polygonal shape (in this embodiment, quadrangular shape) having four sides parallel to the peripheral edge of the chip 2 in a plan view, and is unevenly distributed on the fourth side surface 5D side with respect to a central portion of the active region 8. The first pad portion 60a covers the gate electrodes 32 across the interlayer film 50, and is electrically connected to the body regions 13, etc., via the source openings 54.

The second pad portion 60b has a planar area smaller than the planar area of the first pad portion 60a, and is led out in a band shape (quadrangular shape) from one end portion (end portion on the first side surface 5A side) of the first pad portion 60a in the second direction Y toward the third side surface 5C side. The second pad portion 60b covers the gate electrodes 32 across the interlayer film 50, and is electrically connected to the body regions 13, etc., via the source openings 54.

The third pad portion 60c has a planar area smaller than the planar area of the first pad portion 60a, and is led out in a band shape (quadrangular shape) from the other end portion (end portion on the second side surface 5B side) of the first pad portion 60a in the second direction Y toward the third side surface 5C side, and opposes the second pad portion 60b in the second direction Y. The third pad portion 60c covers the gate electrodes 32 across the interlayer film 50, and is electrically connected to the body regions 13, etc., via the source openings 54.

The planar area of the third pad portion 60c may be substantially equal to the planar area of the second pad portion 60b. As a matter of course, the planar area of the third pad portion 60c may be larger than the planar area of the second pad portion 60b, or may be smaller than the planar area of the second pad portion 60b. Either one or both of the second pad portion 60b and the third pad portion 60c may be used as a terminal portion for current monitoring.

The source pad electrode 60 does not necessarily include both of the second pad portion 60b and the third pad portion 60c at the same time. The source pad electrode 60 may include only one of the second pad portion 60b and the third pad portion 60c. As a matter of course, the source pad electrode 60 may include only the first pad portion 60a, and may not include the second pad portion 60b and the third pad portion 60c.

Referring to FIG. 6 and FIG. 7, the source pad electrode 60 includes a first underlying electrode film 61, a plurality of first embedded electrodes 62, and a first main electrode film 63. The first underlying electrode film 61 may be referred to as a “source underlying electrode film,” the first embedded electrode 62 may be referred to as a “source-embedded electrode,” and the first main electrode film 63 may be referred to as a “source main electrode film.”

The first underlying electrode film 61 forms a lower layer portion of the source pad electrode 60 (the first pad portion 60a, the second pad portion 60b, and the third pad portion 60c), and covers the interlayer film 50 in the active region 8. The first underlying electrode film 61 collectively covers a region of the interlayer film 50 in which the source openings 54 are formed in a film shape, and enters the source openings 54 from above the insulating surface 51.

The first underlying electrode film 61 includes a portion that covers the insulating surface 51 in a film shape and a portion that covers the wall surfaces of the source openings 54 in a film shape. The first underlying electrode film 61 may include a portion that covers the gate wiring 44 across the interlayer film 50. The first underlying electrode film 61 may be formed at an interval inwardly from the gate wiring 44 in a plan view.

In this embodiment, the first underlying electrode film 61 has a laminated structure including a first electrode film 64 laminated on the interlayer film 50 and a second electrode film 65 laminated on the first electrode film 64. In this embodiment, the first electrode film 64 includes a Ti film, and the second electrode film 65 includes a TiN film. The first underlying electrode film 61 does not necessarily have a laminated structure, and may have a single layer structure including one of the first electrode film 64 (Ti film) and the second electrode film 65 (TiN film).

The thickness of the first electrode film 64 may be in a range of 10 nm or thicker and 100 nm or thinner. The thickness of the first electrode film 64 may have a value in at least one range among a range of 10 nm or thicker and 25 nm or thinner, a range of 25 nm or thicker and 50 nm or thinner, a range of 50 nm or thicker and 75 nm or thinner, and a range of 75 nm or thicker and 100 nm or thinner.

The thickness of the second electrode film 65 may be in a range of 50 nm or thicker and 200 nm or thinner. The thickness of the second electrode film 65 may have a value in at least one range among a range of 50 nm or thicker and 75 nm or thinner, a range of 75 nm or thicker and 100 nm or thinner, a range of 100 nm or thicker and 125 nm or thinner, a range of 125 nm or thicker and 150 nm or thinner, a range of 150 nm or thicker and 175 nm or thinner, and a range of 175 nm or thicker and 200 nm or thinner. Preferably, the thickness of the second electrode film 65 is thicker than the thickness of the first electrode film 64.

The first electrode film 64 collectively covers a region of the interlayer film 50 in which the source openings 54 are formed in a film shape, and enters the source openings 54 from above the insulating surface 51. The first electrode film 64 includes a portion that covers the insulating surface 51 in a film shape and a portion that covers the wall surfaces of the source openings 54 in a film shape. The first electrode film 64 directly covers the insulating surface 51 (second oxide film 53), and opposes the gate electrodes 32 across the interlayer film 50.

The first electrode film 64 covers the arc corner portion in a film shape along the arc corner portion of the interlayer film 50 (second oxide film 53), and enters the source opening 54. The first electrode film 64 includes a portion extending in a circular arc shape at the arc corner portion. Thereby, the film formability of the first electrode film 64 with respect to the interlayer film 50 (the wall surface of the source opening 54) is improved.

The first electrode film 64 extends along the wall surface of the source opening 54, and covers the insulating film 31, the first oxide film 52, and the second oxide film 53. The first electrode film 64 opposes the side wall of the gate electrode 32 across the interlayer film 50. The first electrode film 64 covers the first main surface 3 in a film shape at a bottom portion of each source opening 54, and is electrically connected to the first main surface 3. Specifically, the first electrode film 64 includes a portion that covers the source recess 55 in a film shape at the bottom portion of each source opening 54, and is electrically connected to the body regions 13, the source regions 16 and 17, and the contact region 18.

The first electrode film 64 may be formed at an interval from a height position of the first main surface 3 toward the bottom portion side of the source recess 55, and cover the source recess 55 in a film shape. The first electrode film 64 may include a portion that is located on the bottom portion side of the source recess 55 with respect to the height position of the first main surface 3, and a portion that is located on the insulating film 31 side with respect to the height position of the first main surface 3.

The second electrode film 65 collectively covers a region of the interlayer film 50 which is arranged on the first electrode film 64 and in which the source openings 54 are formed in a film shape. The second electrode film 65 includes a portion that covers the insulating surface 51 in a film shape across the first electrode film 64 and a portion that covers the wall surfaces of the source openings 54 in a film shape across the first electrode film 64.

The second electrode film 65 opposes the gate electrodes 32 across the first electrode film 64 and the interlayer film 50 in a portion that covers the insulating surface 51. The second electrode film 65 covers the arc corner portion of the interlayer film 50 (second oxide film 53) in a film shape along the first electrode film 64, and enters the source opening 54. The second electrode film 65 includes a portion extending in a circular arc shape at the arc corner portion of the interlayer film 50. Thereby, the film formability of the second electrode film 65 with respect to the interlayer film 50 (the wall surface of the source opening 54) is improved.

The second electrode film 65 extends along the wall surface of the source opening 54, and covers the insulating film 31, the first oxide film 52, and the second oxide film 53 across the first electrode film 64. The second electrode film 65 opposes the side wall of the gate electrode 32 across the first electrode film 64 and the interlayer film 50. The second electrode film 65 includes a portion that covers the source recess 55 in a film shape at the bottom portion of each source opening 54 across the first electrode film 64, and is electrically connected to the body regions 13, the source regions 16 and 17, and the contact region 18 via the first electrode film 64.

In a case where the first electrode film 64 is located on the bottom portion side of the source recess 55 with respect to the first main surface 3, the second electrode film 65 may include a portion that is located in the source recess 55. In a case where the first electrode film 64 includes a portion that is located above the first main surface 3, the entire second electrode film 65 is located above the source recess 55.

The first embedded electrodes 62 form an intermediate layer portion of the source pad electrode 60 (the first pad portion 60a, the second pad portion 60b, and the third pad portion 60c), and are respectively embedded in the source openings 54. The first embedded electrode 62 includes a conductive material different from the conductive material of the first underlying electrode film 61. The first embedded electrode 62 includes at least one of tungsten, molybdenum, a tungsten alloy, and a molybdenum alloy. In this embodiment, the first embedded electrode 62 includes tungsten.

In this embodiment, the first embedded electrodes 62 are respectively embedded in a one-to-one correspondence relationship with respect to the source openings 54 via the single first underlying electrode film 61. The first embedded electrodes 62 are electrically connected to the first main surface 3 (chip 2) in the source openings 54. Specifically, the first embedded electrode 62 is electrically connected to the source regions 16 and 17 and the contact region 18 via the first underlying electrode film 61. Hereinafter, the configuration of one first embedded electrode 62 will be described.

The first embedded electrode 62 has a first embedded electrode surface 66 exposed from the source opening 54, and exposes the insulating surface 51. The first embedded electrode surface 66 may be referred to as a “source-embedded electrode film.” The first embedded electrode 62 is embedded in the source opening 54 at an interval from the insulating surface 51 toward the first main surface 3 side, and exposes a portion of the first underlying electrode film 61 (the second electrode film 65) that covers the insulating surface 51.

The first embedded electrode 62 covers the first oxide film 52 and the second oxide film 53 across the first underlying electrode film 61. The first embedded electrode 62 opposes the side wall of the gate electrode 32 in the horizontal direction. In a case where the first underlying electrode film 61 is located on the bottom portion side of the source recess 55 with respect to the first main surface 3, the first embedded electrode 62 may include a portion that is located in the source recess 55. In a case where the first underlying electrode film 61 includes a portion that is located above the first main surface 3, the entire first embedded electrode 62 is located above the source recess 55.

The first embedded electrode surface 66 is located on the first main surface 3 side with respect to the insulating surface 51, and does not include a portion that opposes the electrode surface of the gate electrode 32 across the interlayer film 50 in the lamination direction (vertical direction Z). In this embodiment, the first embedded electrode surface 66 includes a portion that covers the arc corner portion of the interlayer film 50 across the first underlying electrode film 61.

As a matter of course, the first embedded electrode surface 66 may be located below the arc corner portion of the interlayer film 50. The first embedded electrode surface 66 is located on the insulating surface 51 side with respect to the height position of the first oxide film 52. Preferably, the first embedded electrode surface 66 is located above the electrode surface of the gate electrode 32.

The first embedded electrode surface 66 has a recess that is recessed toward the first main surface 3 (chip 2) side at the central portion. Preferably, a bottom portion of the recess is located on the insulating surface 51 side with respect to the height position of the electrode surface of the gate electrode 32. As a matter of course, a portion (for example, the recess) or the whole of the first embedded electrode surface 66 may be located below the electrode surface of the gate electrode 32. A portion (for example, the recess) or the whole of the first embedded electrode surface 66 may be located on the insulating surface 51 side with respect to the height position of the first oxide film 52.

The first main electrode film 63 forms an upper layer portion of the source pad electrode 60 (the first pad portion 60a, the second pad portion 60b, and the third pad portion 60c), and covers the first underlying electrode film 61 and the first embedded electrodes 62 in a film shape. The first main electrode film 63 includes a conductive material different from the conductive material of the first underlying electrode film 61 and the conductive material of the first embedded electrode 62.

The first main electrode film 63 may include at least one of an Al film, an Al alloy film, a Cu film, and a Cu alloy film. The Al alloy film may include at least one of an AlSi alloy film, an AlCu alloy film, and an AlSiCu alloy film. The first main electrode film 63 has a thickness thicker than the thickness (total thickness) of the first underlying electrode film 61. The first main electrode film 63 has a thickness thicker than the thickness of the first embedded electrode 62.

The thickness of the first main electrode film 63 may be in a range of 0.5 μm or thicker and 5 μm or thinner. The thickness of the first main electrode film 63 may have a value in at least one range among a range of 0.5 μm or thicker and 1 μm or thinner, a range of 1 μm or thicker and 1.5 μm or thinner, a range of 1.5 μm or thicker and 2 μm or thinner, a range of 2 μm or thicker and 2.5 μm or thinner, a range of 2.5 μm or thicker and 3 μm or thinner, a range of 3 μm or thicker and 3.5 μm or thinner, a range of 3.5 μm or thicker and 4 μm or thinner, a range of 4 μm or thicker and 4.5 μm or thinner, and a range of 4.5 μm or thicker and 5 μm or thinner.

The first main electrode film 63 is mechanically and electrically connected to the first underlying electrode film 61 in a portion that covers the insulating surface 51, and opposes the gate electrodes 32 across the first underlying electrode film 61 and the interlayer film 50. The first main electrode film 63 is mechanically and electrically connected to the first embedded electrodes 62 in a portion that covers the source openings 54. Thereby, the first main electrode film 63 is electrically connected to the body regions 13, the source regions 16 and 17, the contact region 18, etc., via both of the first underlying electrode film 61 and the first embedded electrodes 62.

The first main electrode film 63 is connected to the first embedded electrode surface 66 at the height position of the first main surface 3 side with respect to the height position of the insulating surface 51. The first main electrode film 63 includes a portion that covers the recess of the first embedded electrode surface 66. The first main electrode film 63 may include a portion that covers the arc corner portion of the interlayer film 50 across the first underlying electrode film 61.

The first main electrode film 63 is connected to the first embedded electrode surface 66 above the height position of the first oxide film 52. In this embodiment, the first main electrode film 63 is connected to the first embedded electrode surface 66 above the electrode surface of the gate electrode 32. That is, the first main electrode film 63 does not include a portion that opposes the gate electrode 32 in the horizontal direction. In a case where the first embedded electrode surface 66 is located below the height position of the electrode surface of the gate electrode 32 or the height position of the first oxide film 52, the first main electrode film 63 may include a portion that opposes the gate electrode 32 in the horizontal direction.

The film formability of the first main electrode film 63 with respect to the source openings 54 is improved by the first embedded electrodes 62. Thereby, a current path between the first main surface 3 and the first main electrode film 63 is appropriately secured. Such a configuration is effective in suppressing film formation defects caused by the source openings 54 and reducing wiring resistance.

The semiconductor device 1A includes a plurality of first silicide portions 67 that are respectively formed in surface portions of portions of the first main surface 3 that are exposed from the source openings 54. The first silicide portions 67 are formed in a film shape along wall surfaces (side walls and bottom walls) of the source recesses 55, and are mechanically and electrically connected to the first underlying electrode film 61. That is, the first silicide portions 67 are formed in the surface layer portions of the body regions 13, and electrically connect the first embedded electrodes 62 to the body regions 13 via the first underlying electrode film 61.

The first silicide portion 67 may include at least one among Ti silicide, Ni silicide, Co silicide, Mo silicide, and W silicide. Preferably, the first silicide portion 67 is made of Ti silicide, Ni silicide, or Co silicide.

The semiconductor device 1A includes a source finger electrode 68 that is led out from the source pad electrode 60 onto the outer peripheral region 9. The source finger electrode 68 transmits the source potential applied to the source pad electrode 60 to the outer peripheral region 9. In this embodiment, the source finger electrode 68 is drawn from a portion of the source pad electrode 60 (first pad portion 60a) on the fourth side surface 5D side onto a portion of the interlayer film 50 that covers the outer peripheral region 9.

The source finger electrode 68 is led out to above the terminal region 40, and is electrically connected to the terminal region 40 via the outer openings 56. Specifically, the source finger electrode 68 is electrically connected to the overlap region 41 of the terminal region 40 via the outer openings 56.

The source finger electrode 68 extends in a band shape along the terminal region 40 (overlap region 41). The source finger electrode 68 includes a portion extending in a band shape in the first direction X and a portion extending in a band shape in the second direction Y in a plan view. In this embodiment, the source finger electrode 68 is formed in a polygonal round shape (in this embodiment, a quadrangular round shape) having four sides parallel to the peripheral edge of the first main surface 3, and surrounds the source pad electrode 60. The source finger electrode 68 may include an edge portion that connects the portion extending in the first direction X and the portion extending in the second direction Y in a circular arc shape (preferably, a quarter arc shape) in a plan view (refer to FIG. 4).

Similarly to the source pad electrode 60, the source finger electrode 68 includes the first underlying electrode film 61, the plurality of first embedded electrodes 62, and the first main electrode film 63. The first underlying electrode film 61 forms a lower layer portion of the source finger electrode 68, and covers the interlayer film 50 in the outer peripheral region 9. The first underlying electrode film 61 collectively covers a region of the interlayer film 50 in which the outer openings 56 are formed in a film shape, and enters the outer openings 56 from above the insulating surface 51. The first underlying electrode film 61 includes a portion that covers the insulating surface 51 in a film shape and a portion that covers the wall surfaces of the outer openings 56 in a film shape.

Similarly to the source pad electrode 60, the first underlying electrode film 61 has a laminated structure including the first electrode film 64 and the second electrode film 65. The first electrode film 64 collectively covers a region of the interlayer film 50 in which the outer openings 56 are formed in a film shape, and enters the outer openings 56 from above the insulating surface 51. The first electrode film 64 includes a portion that covers the insulating surface 51 in a film shape and a portion that covers the wall surfaces of the outer openings 56 in a film shape.

The first electrode film 64 covers the arc corner portion in a film shape along the arc corner portion of the interlayer film 50 (second oxide film 53), and enters the outer opening 56. The first electrode film 64 includes a portion extending in a circular arc shape at the arc corner portion. Thereby, the film formability of the first electrode film 64 with respect to the interlayer film 50 (the wall surface of the outer opening 56) is improved. The first electrode film 64 extends along the wall surface of the outer opening 56, and covers the outer peripheral insulating film 43, the first oxide film 52, and the second oxide film 53.

The first electrode film 64 covers the first main surface 3 in a film shape at a bottom portion of each outer opening 56, and is electrically connected to the first main surface 3 (chip 2). Specifically, the first electrode film 64 includes a portion that covers the outer recess 57 in a film shape at the bottom portion of each outer opening 56, and is electrically connected to the terminal region 40 (overlap region 41) in the outer recess 57.

The first electrode film 64 may be formed at an interval from a height position of the first main surface 3 toward the bottom portion side of the outer recess 57, and cover the outer recess 57 in a film shape. The first electrode film 64 may include a portion that is located on the bottom portion side of the outer recess 57 with respect to the height position of the first main surface 3, and a portion that is located on the outer peripheral insulating film 43 side with respect to the height position of the first main surface 3.

The second electrode film 65 collectively covers a region of the interlayer film 50 which is arranged on the first electrode film 64 and in which the outer openings 56 are formed in a film shape. The second electrode film 65 includes a portion that covers the insulating surface 51 in a film shape across the first electrode film 64 and a portion that covers the wall surfaces of the outer openings 56 in a film shape across the first electrode film 64.

The second electrode film 65 covers the arc corner portion of the interlayer film 50 (second oxide film 53) in a film shape along the first electrode film 64, and enters the outer opening 56. The second electrode film 65 includes a portion extending in a circular arc shape at the arc corner portion of the interlayer film 50 (second oxide film 53). Thereby, the film formability of the second electrode film 65 with respect to the interlayer film 50 (the wall surface of the outer opening 56) is improved. The second electrode film 65 extends along the wall surface of the outer opening 56, and covers the outer peripheral insulating film 43, the first oxide film 52, and the second oxide film 53 across the first electrode film 64.

The second electrode film 65 includes a portion that covers the outer recess 57 in a film shape across the first electrode film 64 at the bottom portion of each outer opening 56, and is electrically connected to the terminal region 40 (overlap region 41) via the first electrode film 64. In a case where the first electrode film 64 is located on the bottom portion side of the outer recess 57 with respect to the first main surface 3, the second electrode film 65 may include a portion that is located in the outer recess 57. In a case where the first electrode film 64 includes a portion that is located above the first main surface 3, the entire second electrode film 65 is located above the outer recess 57.

The first embedded electrodes 62 form an intermediate layer portion of the source finger electrode 68, and are respectively embedded in the outer openings 56. In this embodiment, the first embedded electrodes 62 are respectively embedded in a one-to-one correspondence relationship with the outer openings 56 via the single first underlying electrode film 61. The first embedded electrodes 62 are electrically connected to the terminal region 40 (overlap region 41) via the first underlying electrode film 61.

The first embedded electrode 62 has a first embedded electrode surface 66 exposed from the outer opening 56, and exposes the insulating surface 51. Specifically, the first embedded electrode 62 is embedded in the outer opening 56 at an interval from the insulating surface 51 toward the first main surface 3 side, and exposes a portion of the first underlying electrode film 61 (the second electrode film 65) that covers the insulating surface 51. That is, the first embedded electrode surface 66 is located on the first main surface 3 side with respect to the insulating surface 51.

The first embedded electrode 62 covers the first oxide film 52 and the second oxide film 53 across the first underlying electrode film 61. The first embedded electrode 62 includes a portion that covers the arc corner portion of the interlayer film 50 across the first underlying electrode film 61. The first embedded electrode 62 may be embedded at an interval from the arc corner portion of the interlayer film 50 toward the outer peripheral insulating film 43 side, and expose the entire region of the arc corner portion. The first embedded electrode surface 66 is located on the insulating surface 51 side with respect to the height position of the first oxide film 52 in the outer opening 56. As a matter of course, the first embedded electrode surface 66 may be located on the outer peripheral insulating film 43 side with respect to the height position of the first oxide film 52.

In a case where the first underlying electrode film 61 is located on the bottom portion side of the outer recess 57 with respect to the first main surface 3, the first embedded electrode 62 may include a portion that is located in the outer recess 57. In a case where the first underlying electrode film 61 includes a portion that is located above the first main surface 3, the entire first embedded electrode 62 is located above the outer recess 57.

The first main electrode film 63 forms an upper layer portion of the source finger electrode 68, and covers the first underlying electrode film 61 and the first embedded electrodes 62 in a film shape. The first main electrode film 63 is mechanically and electrically connected to the first underlying electrode film 61 in a portion that covers the insulating surface 51, and is mechanically and electrically connected to the first embedded electrodes 62 in a portion that covers the outer openings 56. The first main electrode film 63 is electrically connected to the terminal region 40 (overlap region 41) via the first underlying electrode film 61 and the first embedded electrodes 62.

The first main electrode film 63 is connected to the first embedded electrode surface 66 at the height position of the first main surface 3 side with respect to the height position of the insulating surface 51. The first main electrode film 63 is connected to the first embedded electrode surface 66 above the height position of the first oxide film 52. The first main electrode film 63 includes a portion that covers the recess of the first embedded electrode surface 66.

The first main electrode film 63 may include a portion that covers the arc corner portion of the interlayer film 50 across the first underlying electrode film 61. In a case where the first embedded electrode 62 is located below the first oxide film 52, the first main electrode film 63 may be connected to the first embedded electrode 62 in a region below the first oxide film 52.

The film formability of the first main electrode film 63 with respect to the outer openings 56 is improved by the first embedded electrodes 62. Thereby, a current path between the terminal region 40 (overlap region 41) and the first main electrode film 63 is appropriately secured. Such a configuration is effective in suppressing film formation defects caused by the outer openings 56 and reducing wiring resistance.

The semiconductor device 1A includes a plurality of second silicide portions 69 that are respectively formed in surface portions of portions of the first main surface 3 that are exposed from the outer openings 56. The second silicide portions 69 are formed in a film shape along wall surfaces (side walls and bottom walls) of the outer recesses 57, and are mechanically and electrically connected to the first underlying electrode film 61. That is, the second silicide portions 69 are formed in the surface layer portion of the terminal region 40 (overlap region 41), and electrically connect the first embedded electrodes 62 to the terminal region 40 (overlap region 41) via the first underlying electrode film 61.

The second silicide portion 69 may include at least one among Ti silicide, Ni silicide, Co silicide, Mo silicide, and W silicide. Preferably, the second silicide portion 69 is made of Ti silicide, Ni silicide, or Co silicide. It is particularly preferable that the second silicide portion 69 is made of the same type of silicide as the first silicide portion 67.

The semiconductor device 1A includes a gate finger electrode 70 that is selectively drawn onto the interlayer film 50. The gate finger electrode 70 transmits the gate potential to the gate wiring 44. The gate finger electrode 70 is drawn onto a portion of the interlayer film 50 that covers the gate wiring 44 (that is, on the outer peripheral region 9), and is electrically connected to the gate wiring 44 via the gate openings 58.

The gate finger electrode 70 is arranged in a region between the source pad electrode 60 and the source finger electrode 68 at an interval from the source pad electrode 60 and the source finger electrode 68. The gate finger electrode 70 extends in a band shape along the gate wiring 44. The gate finger electrode 70 includes a portion extending in a band shape in the first direction X and a portion extending in a band shape in the second direction Y in a plan view.

In this embodiment, the gate finger electrode 70 is formed in a band shape with ends that has four sides parallel to the peripheral edge of the first main surface 3, and surrounds the source pad electrode 60. The gate finger electrode 70 may include an edge portion that connects the portion extending in the first direction X and the portion extending in the second direction Y in a circular arc shape (preferably, a quarter arc shape) in a plan view (refer to FIG. 4). The gate finger electrode 70 has a pair of open ends through which the source finger electrode 68 pass on the fourth side surface 5D side.

Referring to FIG. 8 and FIG. 9, the gate finger electrode 70 includes a second underlying electrode film 71, at least one (in this embodiment, a plurality of) second embedded electrodes 72, and a second main electrode film 73. The second underlying electrode film 71 may be referred to as a “gate underlying electrode film,” the second embedded electrode 72 may be referred to as a “gate embedded electrode,” and the second main electrode film 73 may be referred to as a “gate main electrode film.”

The second underlying electrode film 71 forms a lower layer portion of the gate finger electrode 70, and covers the interlayer film 50 in the outer peripheral region 9. The second underlying electrode film 71 collectively covers a region of the interlayer film 50 in which the gate openings 58 are formed in a film shape, and enters the gate openings 58 from above the insulating surface 51. The second underlying electrode film 71 includes a portion that covers the insulating surface 51 in a film shape and a portion that covers the wall surfaces of the gate openings 58 in a film shape.

The second underlying electrode film 71 has a laminated structure including a first electrode film 74 laminated on the interlayer film 50 and a second electrode film 75 laminated on the first electrode film 74. Preferably, the first electrode film 74 includes the same type of conductive material as the first electrode film 64 on the source side, and the second electrode film 75 includes the same type of conductive material as the second electrode film 65 on the source side. In this embodiment, the first electrode film 74 includes a Ti film, and the second electrode film 75 includes a TiN film.

The second underlying electrode film 71 does not necessarily have a laminated structure, and may have a single layer structure including one of the first electrode film 74 (Ti film) and the second electrode film 75 (TiN film). The first electrode film 74 may have a thickness substantially equal to the thickness of the first electrode film 64 on the source side. The second electrode film 75 may have a thickness substantially equal to the thickness of the second electrode film 65 on the source side.

The first electrode film 74 collectively covers a region of the interlayer film 50 in which the gate openings 58 are formed in a film shape, and enters the gate openings 58 from above the insulating surface 51. That is, the first electrode film 74 includes a portion that covers the insulating surface 51 in a film shape and a portion that covers the wall surfaces of the gate openings 58 in a film shape.

The first electrode film 74 covers the arc corner portion in a film shape along the arc corner portion of the interlayer film 50 (second oxide film 53), and enters the gate opening 58. The first electrode film 74 includes a portion extending in a circular arc shape at the arc corner portion. Thereby, the film formability of the first electrode film 74 with respect to the interlayer film 50 (the wall surface of the gate opening 58) is improved.

The first electrode film 74 extends along the wall surface of the gate opening 58, and covers the first oxide film 52 and the second oxide film 53. The first electrode film 74 covers the gate wiring 44 in a film shape at the bottom portion of each gate opening 58, and is electrically connected to the gate wiring 44.

The second electrode film 75 collectively covers a region of the interlayer film 50 which is arranged on the first electrode film 74 and in which the gate openings 58 are formed in a film shape. That is, the second electrode film 75 includes a portion that covers the insulating surface 51 in a film shape across the first electrode film 74 and a portion that covers the wall surfaces of the gate openings 58 in a film shape across the first electrode film 74.

The second electrode film 75 covers the arc corner portion of the interlayer film 50 (second oxide film 53) in a film shape along the first electrode film 74, and enters the gate opening 58. The second electrode film 75 includes a portion extending in a circular arc shape at the arc corner portion of the interlayer film 50 (second oxide film 53). Thereby, the film formability of the second electrode film 75 with respect to the interlayer film 50 (the wall surface of the gate opening 58) is improved.

The second electrode film 75 extends along the wall surface of the gate opening 58, and covers the first oxide film 52 and the second oxide film 53 across the first electrode film 74. The second electrode film 75 includes a portion that covers the gate wiring 44 in a film shape across the first electrode film 74 at the bottom portion of each gate opening 58, and is electrically connected to the gate wiring 44 via the first electrode film 74.

The second embedded electrodes 72 form an intermediate layer portion of the gate finger electrode 70, and are respectively embedded in the gate openings 58. The second embedded electrode 72 includes a conductive material different from the conductive material of the second underlying electrode film 71. The second embedded electrode 72 includes at least one of tungsten, molybdenum, a tungsten alloy, and a molybdenum alloy. Preferably, the second embedded electrode 72 includes the same type of conductive material as the conductive material of the first embedded electrode 62. In this embodiment, the second embedded electrode 72 includes tungsten.

In this embodiment, the second embedded electrodes 72 are respectively embedded in a one-to-one correspondence relationship with respect to the gate openings 58 via the single second underlying electrode film 71. The second embedded electrodes 72 are electrically connected to the gate wiring 44 via the second underlying electrode film 71 in the gate openings 58.

The second embedded electrode 72 has a second embedded electrode surface 76 exposed from the gate opening 58, and exposes the insulating surface 51. The second embedded electrode surface 76 may be referred to as a “gate embedded electrode surface.” The second embedded electrode 72 is embedded in the gate opening 58 at an interval from the insulating surface 51 toward the first main surface 3 side, and exposes a portion of the second underlying electrode film 71 (the second electrode film 75) that covers the insulating surface 51. That is, the second embedded electrode surface 76 is located on the first main surface 3 side with respect to the insulating surface 51.

The second embedded electrode 72 covers the first oxide film 52 and the second oxide film 53 across the second underlying electrode film 71. The second embedded electrode 72 includes a portion that covers the arc corner portion of the interlayer film 50 across the second underlying electrode film 71. The second embedded electrode 72 may be embedded at an interval from the arc corner portion of the interlayer film 50 toward the gate wiring 44 side, and expose the entire region of the arc corner portion. The second embedded electrode surface 76 is located on the insulating surface 51 side with respect to the height position of the first oxide film 52. As a matter of course, the second embedded electrode surface 76 may be located on the gate wiring 44 side with respect to the height position of the first oxide film 52.

The second main electrode film 73 forms an upper layer portion of the gate finger electrode 70, and covers the second underlying electrode film 71 and the second embedded electrodes 72 in a film shape. The second main electrode film 73 includes a conductive material different from the conductive material of the second underlying electrode film 71 and the conductive material of the second embedded electrode 72.

The second main electrode film 73 may include at least one of an Al film, an Al alloy film, a Cu film, and a Cu alloy film. The Al alloy film may include at least one of an AlSi alloy film, an AlCu alloy film, and an AlSiCu alloy film. Preferably, the second main electrode film 73 includes the same type of conductive material as the conductive material of the first main electrode film 63. The second main electrode film 73 may have a thickness substantially equal to the thickness of the first main electrode film 63.

The second main electrode film 73 is mechanically and electrically connected to the second underlying electrode film 71 in a portion that covers the insulating surface 51, and is mechanically and electrically connected to the second embedded electrodes 72 in a portion that covers the gate openings 58. Thereby, the second main electrode film 73 is electrically connected to the gate wiring 44 via the second underlying electrode film 71 and the second embedded electrodes 72.

The second main electrode film 73 is connected to the second embedded electrode 72 at the height position of the first main surface 3 side with respect to the height position of the insulating surface 51. The second main electrode film 73 is connected to the second embedded electrode surface 76 above the height position of the first oxide film 52. The second main electrode film 73 includes a portion that covers the recess of the second embedded electrode surface 76.

The second main electrode film 73 may include a portion that covers the arc corner portion of the interlayer film 50 across the second underlying electrode film 71. In a case where the second embedded electrode 72 is located below the first oxide film 52, the second main electrode film 73 may be connected to the second embedded electrode 72 in a region below the first oxide film 52.

The film formability of the second main electrode film 73 with respect to the gate openings 58 is improved by the second embedded electrodes 72. Thereby, a current path between the gate wiring 44 and the second main electrode film 73 is appropriately secured. Such a configuration is effective in suppressing film formation defects caused by the gate openings 58 and reducing wiring resistance.

The semiconductor device 1A includes a gate pad electrode 80 that is arranged on the interlayer film 50. The gate pad electrode 80 is a terminal electrode to which the gate potential is to be applied from the outside. The gate pad electrode 80 may be referred to as a “second pad electrode,” a “second main surface electrode,” a “second terminal electrode,” etc. The gate pad electrode 80 is arranged in a region between the source pad electrode 60 and the source finger electrode 68 at an interval from the source pad electrode 60 and the source finger electrode 68.

In this embodiment, the gate pad electrode 80 is arranged in a region on the third side surface 5C side with respect to the first pad portion 60a, and is interposed between the second pad portion 60b and the third pad portion 60c. That is, the gate pad electrode 80 opposes the first pad portion 60a in the first direction X, and opposes the second pad portion 60b and the third pad portion 60c in the second direction Y.

The gate pad electrode 80 is formed in a polygonal shape (in this embodiment, quadrangular shape) having four sides parallel to the peripheral edge of the chip 2 in a plan view. The gate pad electrode 80 has a planar area smaller than a planar area of the source pad electrode 60 (first pad portion 60a). The gate pad electrode 80 may have a planar area smaller than the planar area of the second pad portion 60b (third pad portion 60c).

The gate pad electrode 80 is arranged on a portion that covers the active region 8 and the outer peripheral region 9, and is connected to the gate finger electrode 70. The gate pad electrode 80 may cover the gate electrodes 32 across the interlayer film 50, or may cover the gate wiring 44 across the interlayer film 50.

Similarly to the gate finger electrode 70, the gate pad electrode 80 includes the second underlying electrode film 71 and the second main electrode film 73. The second underlying electrode film 71 forms a lower layer portion of the gate pad electrode 80, and covers the interlayer film 50 in a film shape. Similarly to the gate finger electrode 70, the second underlying electrode film 71 has a laminated structure including the first electrode film 74 and the second electrode film 75. The first electrode film 74 covers the interlayer film 50 in a film shape, and the second electrode film 75 covers the first electrode film 74 in a film shape. The second main electrode film 73 forms an upper layer portion of the gate pad electrode 80, and covers the second underlying electrode film 71 in a film shape.

Although not specifically illustrated, the gate pad electrode 80 may include a plurality of second embedded electrodes 72 similarly to the gate finger electrode 70. In this case, similarly to the gate finger electrode 70, the gate pad electrode 80 may be electrically connected to the gate wiring 44 via the second embedded electrodes 72.

In a case where the gate electrodes 32 are arranged below the gate pad electrode 80, the gate pad electrode 80 may be electrically connected to the gate electrodes 32 via the second embedded electrodes 72. As a matter of course, the gate pad electrode 80 may not include the second embedded electrodes 72. That is, the gate pad electrode 80 may not include an electrical connection portion with respect to the gate electrodes 32 and an electrical connection portion with respect to the gate wiring 44 in the region immediately below.

The gate potential applied to the gate pad electrode 80 is to be applied to the gate wiring 44 via the gate finger electrode 70. The gate potential is transmitted to the gate electrodes 32 via a wiring path (current path) along the gate wiring 44. Thereby, the gate electrodes 32 enter an ON state, and ON/OFF of the channel regions 28 and 29 is controlled.

The semiconductor device 1A includes a drain pad electrode 85 that covers the second main surface 4. The drain pad electrode 85 is a terminal electrode to which a drain potential is to be applied from the outside. The drain pad electrode 85 may be referred to as a “third pad electrode,” a “third main surface electrode,” a “third terminal electrode,” etc. The drain pad electrode 85 is electrically connected to the drain region 10. The drain pad electrode 85 may cover the entire region of the second main surface 4 such as to be continuous with peripheral edge (the first to fourth side surfaces 5A to 5D) of the second main surface 4. The drain pad electrode 85 may partially cover the second main surface 4 such as to expose the peripheral edge portions of the second main surface 4.

A breakdown voltage that can be applied between the source pad electrode 60 and the drain pad electrode 85 (between the first main surface 3 and the second main surface 4) may be in a range of 500 V or higher and 3000 V or lower. The breakdown voltage may have a value in at least one range among a range of 500 V or higher and 1000 V or lower, a range of 1000 V or higher and 1500 V or lower, a range of 1500 V or higher and 2000 V or lower, a range of 2000 V or higher and 2500 V or lower, and a range of 2500 V or higher and 3000 V or lower.

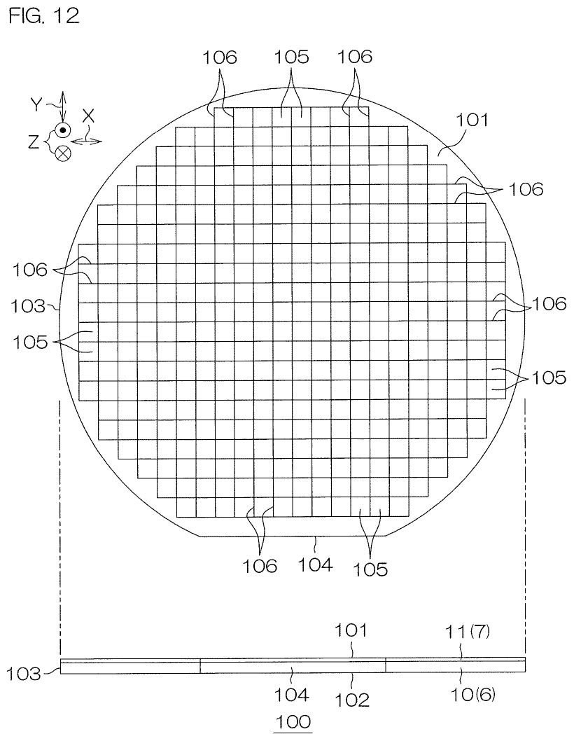

FIG. 12 is a schematic view illustrating a wafer 100 used in a manufacturing of the semiconductor device 1A. Referring to FIG. 12, the wafer 100 is a base material of the chip 2, and includes an SiC single crystal. The wafer 100 is formed in a flat disc shape. As a matter of course, the wafer 100 may be formed in a flat rectangular parallelepiped shape. The wafer 100 has a first wafer main surface 101 on one side, a second wafer main surface 102 on the other side, and a wafer side surface 103 that connects the first wafer main surface 101 and the second wafer main surface 102.

The first wafer main surface 101 corresponds to the first main surface 3 of the chip 2, and the second wafer main surface 102 corresponds to the second main surface 4 of the chip 2. The first wafer main surface 101 and the second wafer main surface 102 are formed by c-planes of the SiC single crystal. The first wafer main surface 101 is formed by a silicon plane of the SiC single crystal, and the second wafer main surface 102 is formed by a carbon plane of the SiC single crystal. The wafer 100 (the first wafer main surface 101 and the second wafer main surface 102) has the off direction and the off angle described above.

The wafer 100 has a mark 104 that indicates a crystal orientation of the SiC single crystal, on the wafer side surface 103. The mark 104 may include either or both of an orientation flat and an orientation notch. The orientation flat is made of a notched portion that is notched linearly in a plan view. The orientation notch is made of a notched portion that is notched in a recessed shape (for example, a tapered shape) toward a central portion of the first wafer main surface 101 in a plan view.

The mark 104 may include either or both of a first orientation flat that extends in the m-axis direction and a second orientation flat that extends in the a-axis direction. The mark 104 may include either or both of an orientation notch that is recessed in the m-axis direction and an orientation notch that is recessed in the a-axis direction.

In this embodiment, the wafer 100 has a laminated structure including the first semiconductor layer 6 and the second semiconductor layer 7. The first semiconductor layer 6 is made of a semiconductor wafer (SiC wafer) including an SiC single crystal (semiconductor single crystal), and has the off direction and the off angle described above. The first semiconductor layer 6 forms the second wafer main surface 102 and the wafer side surface 103.

The second semiconductor layer 7 is made of an epitaxial layer (SiC epitaxial layer) including an SiC single crystal (semiconductor single crystal), and is laminated on the first semiconductor layer 6. That is, in this embodiment, the wafer 100 is made of an epitaxial wafer (so-called epi-wafer) having a laminated structure including a semiconductor wafer and an epitaxial layer. The second semiconductor layer 7 has the off direction and the off angle described above. The second semiconductor layer 7 forms the first wafer main surface 101 and the wafer side surface 103.

The wafer 100 includes the drain region 10 in a region (surface layer portion) on the second wafer main surface 102 side. The drain region 10 is formed in a layer shape extending along the second wafer main surface 102. In this embodiment, the drain region 10 is formed by the first semiconductor layer 6.

The wafer 100 includes the drift region 11 in a region (surface layer portion) on the first wafer main surface 101 side. The drift region 11 is formed in a layer shape extending along the first wafer main surface 101, and is electrically connected to the drain region 10. In this embodiment, the drift region 11 is formed by the second semiconductor layer 7.

The wafer 100 includes a plurality of device regions 105 and a plurality of intended cutting lines 106. For example, the device regions 105 and the intended cutting lines 106 are defined by alignment marks, etc., formed in the first wafer main surface 101 side. Each of the device regions 105 is a region corresponding to the semiconductor device 1A. The device regions 105 are respectively set in a quadrangle shape in a plan view.

In this embodiment, the device regions 105 are set in a matrix shape along the first direction X and the second direction Y in a plan view. The device regions 105 are respectively set at an interval inwardly from a peripheral edge of the first wafer main surface 101 in a plan view. The intended cutting lines 106 are set in a lattice shape that extends along the first direction X and the second direction Y such that the device regions 105 are defined.

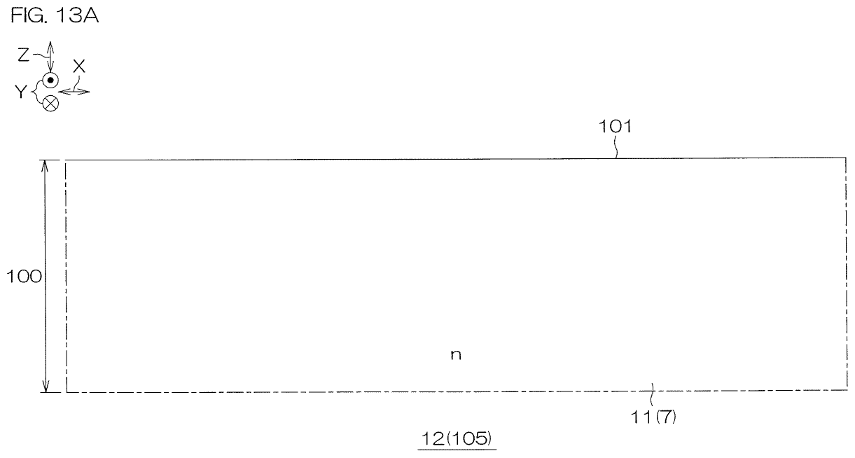

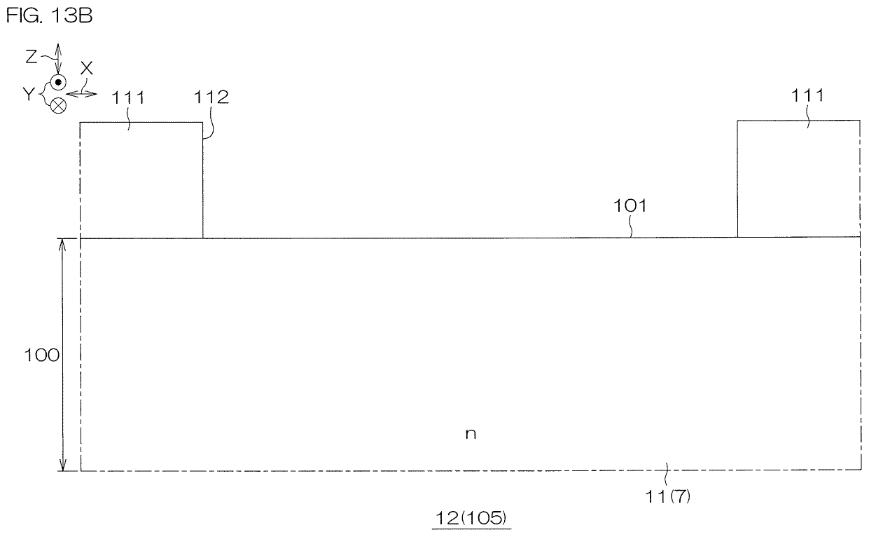

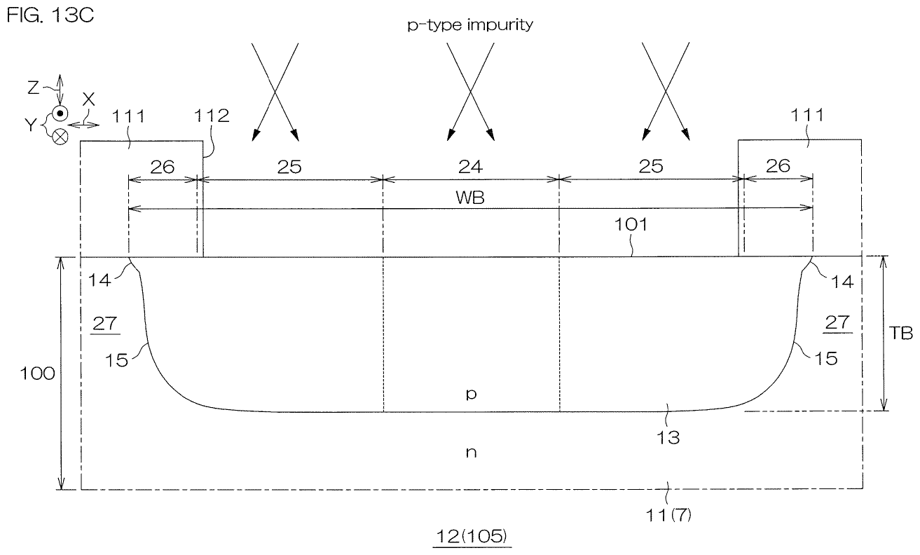

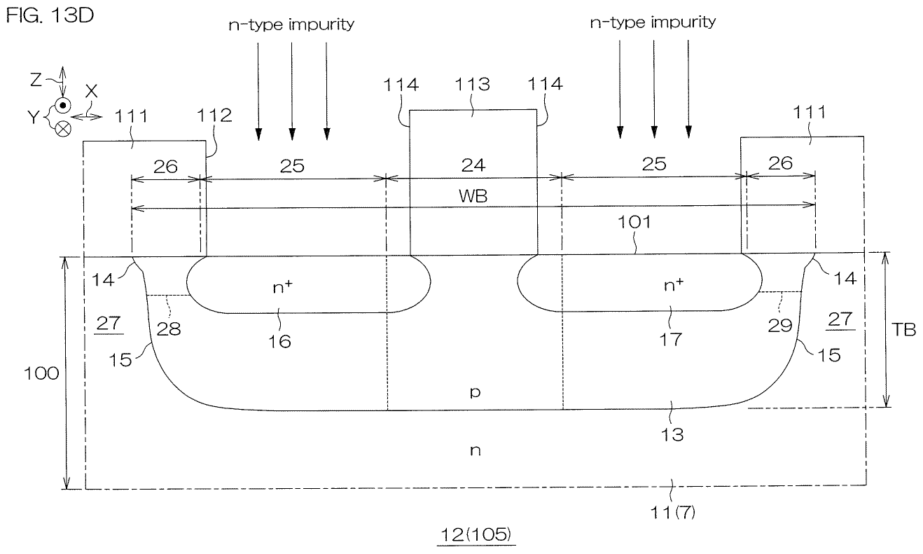

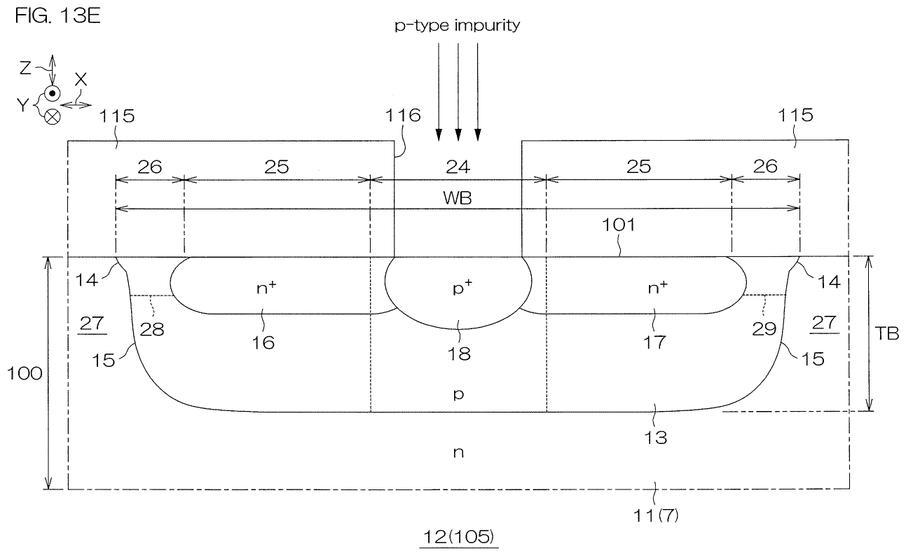

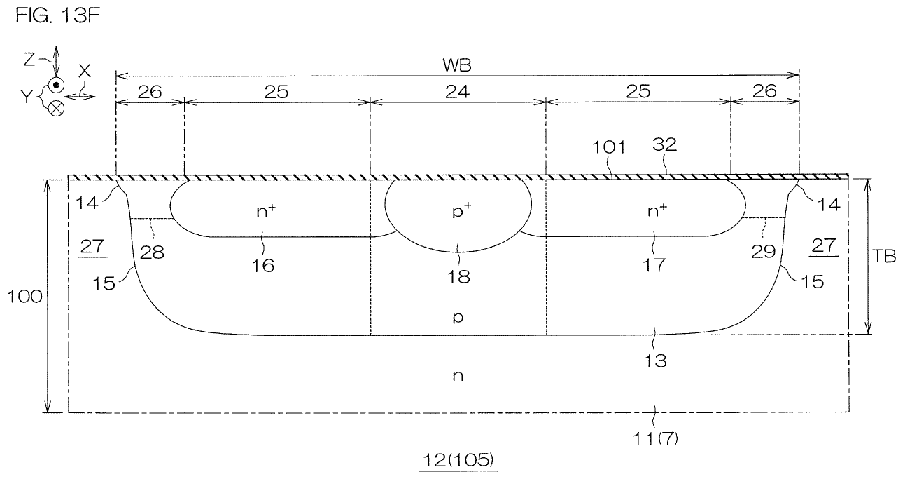

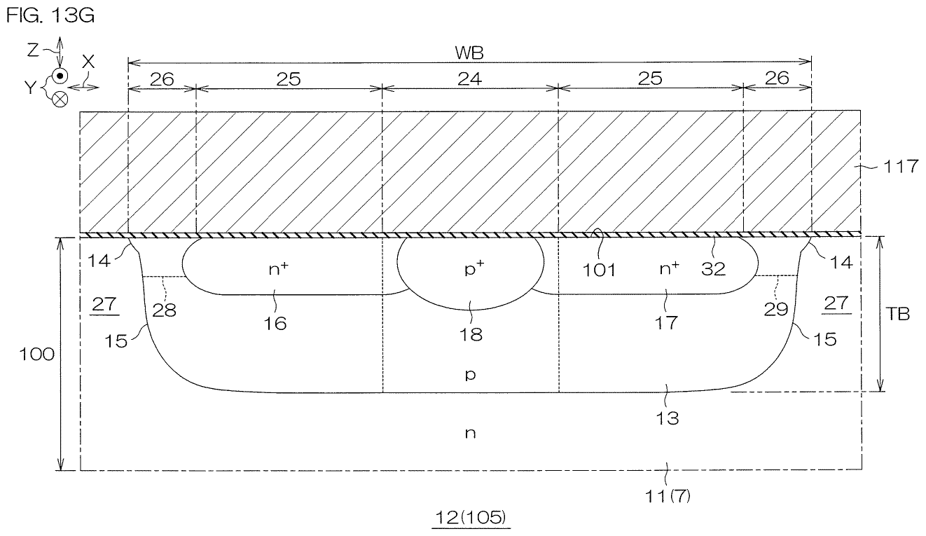

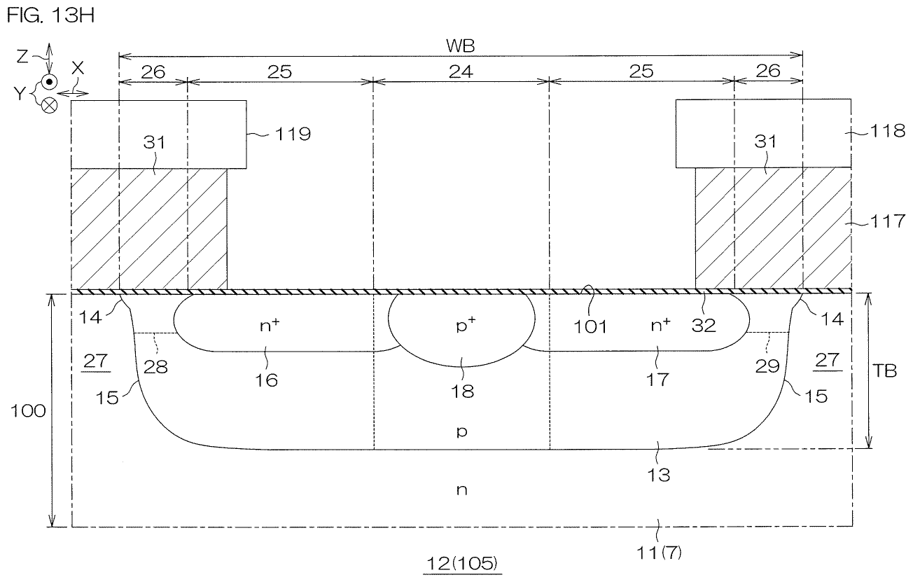

FIG. 13A to FIG. 13H are cross-sectional views illustrating a manufacturing method for the semiconductor device 1A. FIG. 13A to FIG. 13H illustrate a cross-section of a portion (a portion in which the body structures 12 are formed) of the active region 8 of one device region 105.

Referring to FIG. 13A, first, a step of preparing the above-described wafer 100 is performed. Next, referring to FIG. 13B, a step of forming a first mask 111 having a predetermined layout is performed. The first mask 111 is formed on the first wafer main surface 101. The first mask 111 has a plurality of openings 112 that expose regions in which the body regions 13 are to be formed.

The first mask 111 may include one or both of an inorganic mask (so-called hard mask) and an organic mask (so-called soft mask). The first mask 111 may have a single layer structure including an inorganic mask or an organic mask. The first mask 111 may have a laminated structure including an inorganic mask and an organic mask laminated in this order from the first wafer main surface 101 side.

The first mask 111 may include at least one of a silicon oxide film, a silicon nitride film, and a polysilicon film as an inorganic mask. The first mask 111 may include a positive type or negative type photosensitive resin film (that is, a resist film) as an organic mask.

Next, referring to FIG. 13C, a step of forming the body regions 13 is performed. In this step, p-type impurities (trivalent elements) are implanted into the surface layer portion of the drift region 11 by an ion implantation method through the openings 112 (first mask 111). Preferably, the p-type impurities (trivalent elements) contain aluminum. The p-type impurities are implanted into the surface layer portion of the drift region 11 such that the implantation range in the horizontal direction decreases in the thickness direction. Thereby, the body region 13 including the peripheral edge portion inclined in the oblique direction with respect to the first wafer main surface 101 is formed.

Specifically, the p-type impurities are implanted into the surface layer portion of the drift region 11 at an implantation angle inclined in the oblique direction with respect to the first wafer main surface 101 by an oblique ion implantation method. When a vertical line extending along the vertical direction Z is set as a reference angle (0°), the implantation angle is an irradiation angle of the p-type impurities with respect to the vertical line.

In the oblique ion implantation method, the p-type impurities are implanted at a positive implantation angle and a negative implantation angle with respect to the vertical line. The positive and negative implantation angles are relatively defined. Therefore, in a case where one side in the horizontal direction (in this embodiment, the first direction X) with respect to the vertical line is defined as a positive implantation angle, the other side in the horizontal direction (in this embodiment, the first direction X) with respect to the vertical line is defined as a negative implantation angle.

In the oblique ion implantation method, the p-type impurities are also introduced into a region of the drift region 11 immediately below the first mask 111. A part of the p-type impurities may be implanted into the surface layer portion of the drift region 11 through a lower end portion of the first mask 111. The p-type impurities are implanted in an arc shape (circular arc shape) with a lower end portion of the opening 112 of the first mask 111 as a starting point.

Thereby, the body region 13 including the peripheral edge portion (that is, the sub inclined portion 14 and the main inclined portion 15) inclined in the oblique direction is appropriately formed. Also, by introducing the p-type impurities at the positive and negative implantation angles, overlapping implantation locations of the p-type impurities are generated in the inner portion (intermediate portion) of the opening 112, and the first high concentration region 24, the low concentration region 25, and the second high concentration region 26 are formed.

The p-type impurities may be implanted to a target depth position in the surface layer portion of the drift region 11 in a single-stage. Preferably, the p-type impurities are implanted to different target depth positions in the surface layer portion of the drift region 11 at different implantation angles in multi-stages. The step of implanting the p-type impurities may include a step of implanting the p-type impurities to the same target depth position in the drift region 11 at a plurality of times under the same process condition or different process conditions in either case of the single-stage implantation step and the multi-stage implantation step.

That is, the “single-stage implantation step” mentioned here means a step of forming the body region 13 by introducing the p-type impurities to the same target depth position once or a plurality of times. On the other hand, the “multi-stage implantation step” means a step of forming the body region 13 by implanting the p-type impurities to a plurality of target depth positions once or a plurality of times.

The number of p-type impurity implantation stages (the number of target depth positions) in the multi-stage implantation step may be two stages, three stages, four stages, five stages, six stages, seven stages, eight stages, nine stages, or ten stages. Preferably, the number of implantation stages is in a range of two stages or more and five stages or less. In the case of the multi-stage implantation step, the p-type impurities are implanted to different target depth positions such that the implantation locations of the p-type impurities overlap in the thickness direction. Thereby, the body region 13 having a concentration gradient (the first concentration gradient portion 22 and the second concentration gradient portion 23) that gradually increases and decreases in the thickness direction is formed.

In a case where the p-type impurities are implanted into a deep region of the drift region 11 in the multi-stage implantation step, capturing of the p-type impurities by the drift region 11 and cancellation of the p-type impurity concentration are taken into consideration, and an undesirable decrease in the p-type impurity concentration at the lower end portion of the body region 13 is suppressed. For example, in the multi-stage implantation step, as the implantation location becomes deeper, a dose amount (impurity concentration) of the p-type impurities into the drift region 11 is adjusted to increase. The dose amount is appropriately adjusted according to the p-type impurity concentration of the body region 13 to be formed.

Also, in the multi-stage implantation step, as the implantation location becomes deeper, implantation energy of the p-type impurities into the drift region 11 is adjusted to increase. The implantation energy is in a range of 50 KeV or higher and 1000 KeV or lower, and the p-type impurity concentration is appropriately adjusted according to a target depth position for implantation.

In the deep region of the drift region 11, the implantation range of the p-type impurities can be expanded in the horizontal direction due to process conditions (the dose amount and the implantation energy). Therefore, in the multi-stage implantation step, as the implantation location becomes deeper, the implantation angle of the p-type impurities with respect to the drift region 11 is adjusted to decrease. In other words, in the multi-stage implantation step, as the implantation location becomes shallower, the implantation angle of the p-type impurities with respect to the drift region 11 is adjusted to increase.

Thereby, the expansion range (implantation range) of the p-type impurities in the deep region is appropriately limited, and the region on the lower end portion side of the body region 13 is suppressed from protruding outwardly from the region on the upper end portion side of the body region 13. That is, the body region 13 having a tapered shape in the thickness direction is appropriately formed. For example, the body region 13 can have a maximum value of the body width WB in the upper end portion or a region on the upper end portion side. Also, the body region 13 can have a minimum value of the body width WB in the lower end portion or a region on the lower end portion side.

Preferably, the implantation angle of the p-type impurities is set to 0° or larger and 45° or smaller in consideration of shadowing by the first mask 111. The p-type impurities may be implanted to a first target depth position for forming a region on the lower side with respect to the intermediate portion of the body region 13 in a single-stage or multi-stages at a first implantation angle. In a case where the p-type impurities are implanted to a first target depth position in multi-stages, as the implantation location becomes deeper, the first implantation angle is adjusted to decrease.

The first implantation angle may be in a range of 0° or larger and 20° or smaller. The first implantation angle may be set to a value in at least one range among a range of 0° or larger and 2.5° or smaller, a range of 2.5° or larger and 5° or smaller, a range of 5° or larger and 7.5° or smaller, a range of 7.5° or larger and 10° or smaller, a range of 10° or larger and 12.5° or smaller, a range of 12.5° or larger and 15° or smaller, a range of 15° or larger and 17.5° or smaller, and a range of 17.5° or larger and 20° or smaller. Preferably, the first implantation angle is in a range larger than 0° and smaller than 10°.

In a case where the p-type impurities are implanted to a first target depth position in multi-stages, the first implantation angle for the deepest portion may be in a range of 0° or larger and 5° or smaller. The first implantation angle for a region other than the deepest portion may be in a range larger than 0° and equal to or smaller than 10°. According to the first implantation angle, the main inclined portion 15 of the body region 13 is appropriately formed.

The p-type impurities may be implanted to a second target depth position for forming a region on the upper side with respect to the intermediate portion of the body region 13 in a single-stage or multi-stages at a second implantation angle equal to or smaller than the first implantation angle. Preferably, the second implantation angle is smaller than the first implantation angle. In a case where the p-type impurities are implanted to a second target depth position in multi-stages, as the implantation location becomes deeper, the second implantation angle is adjusted to decrease.

The second implantation angle may be in a range of 10° or larger and 45° or smaller. The second implantation angle may be set to a value in at least one range among a range of 10° or larger and 15° or smaller, a range of 15° or larger and 20° or smaller, a range of 20° or larger and 25° or smaller, a range of 25° or larger and 30° or smaller, a range of 30° or larger and 35° or smaller, a range of 35° or larger and 40° or smaller, a range of 40° or larger and 45° or smaller, and a range of 45° or larger and 50° or smaller. Preferably, the second implantation angle is in a range of 5° or larger and 30° or smaller. It is particularly preferable that the second implantation angle is in a range of 10° or larger and 25° or smaller. According to the second implantation angle, the sub inclined portion 14 of the body region 13 is appropriately formed.

In a case where the body region 13 is formed only by the single-stage implantation step, the implantation angle of the p-type impurities may be in a range of 5° or larger and 30° or smaller. In this case, preferably, the implantation angle is in a range of 10° or larger and 25° or smaller. The body region 13 (refer to FIG. 10A to FIG. 10F) and the concentration profile of the body region 13 (refer to FIG. 11A and FIG. 11B) according to the first to sixth configuration examples described above can be obtained by appropriately adjusting the process conditions described above.

Although not specifically illustrated, the step of forming the body region 13 may include a step of forming the outer body region 35. In this case, the opening 112 of the first mask 111 may expose a region in which the outer body region 35 is to be formed in addition to the region in which the body region 13 is to be formed.

In this case, the p-type impurity step (oblique ion implantation step) includes a step of implanting p-type impurities into a region in which the outer body region 35 is to be formed through the opening 112. According to this step, the outer body region 35 having a concentration gradient similar to the concentration gradient of the body region 13 is formed.

Next, referring to FIG. 13D, a step of forming a second mask 113 having a predetermined layout is performed. In this embodiment, the second mask 113 is used in combination with the first mask 111, and is arranged on the first wafer main surface 101 in the opening 112 of the first mask 111. The second mask 113 defines a plurality of inner openings 114 together with the first mask 111 in the opening 112. The inner openings 114 expose regions in which the source regions 16 and 17 are to be formed.

The second mask 113 may include one or both of an inorganic mask (so-called hard mask) and an organic mask (so-called soft mask). The second mask 113 may have a single layer structure including an inorganic mask or an organic mask. The second mask 113 may have a laminated structure including an inorganic mask and an organic mask laminated in this order from the second wafer main surface 102 side.

The second mask 113 may include at least one of a silicon oxide film, a silicon nitride film, and a polysilicon film as an inorganic mask. The second mask 113 may include a positive type or negative type photosensitive resin film (that is, a resist film) as an organic mask.

Preferably, the second mask 113 includes a mask material different from the mask material of the first mask 111. The second mask 113 may have a thickness thicker than the thickness of the first mask 111. As a matter of course, the second mask 113 may have a thickness thinner than the thickness of the first mask 111.

Next, a step of forming the source regions 16 and 17 is performed. In this step, n-type impurities (pentavalent elements) are implanted into the surface layer portion of the body region 13 by an ion implantation method through the inner openings 114 (the first mask 111 and the second mask 113). Preferably, the n-type impurities (pentavalent elements) is phosphorus. The n-type impurities are introduced to be substantially perpendicular to the first wafer main surface 101 by a vertical ion implantation method. Thereby, the source regions 16 and 17 are formed.

After the forming step of the source regions 16 and 17, the first mask 111 and the second mask 113 are removed. As a matter of course, the first mask 111 may be removed after the forming step of the body region 13 and before the forming step of the source regions 16 and 17. In this case, the second mask 113 that has the inner openings 114 exposing the regions in which the source regions 16 and 17 are to be formed is formed.

Next, referring to FIG. 13E, a step of forming a third mask 115 having a predetermined layout is performed. The third mask 115 is arranged on the first wafer main surface 101. The third mask 115 has a plurality of openings 116 that expose regions in which the contact regions 18 are to be formed. The third mask 115 may include one or both of an inorganic mask (so-called hard mask) and an organic mask (so-called soft mask). The third mask 115 may be formed of a mask material similar to the mask material of the second mask 113.

Next, a step of forming the contact region 18 is performed. In this step, p-type impurities (trivalent elements) are implanted into the surface layer portion of the body region 13 by an ion implantation method through the openings 116 (third mask 115). Preferably, the p-type impurities (trivalent elements) contain aluminum. The p-type impurities are introduced to be substantially perpendicular to the first wafer main surface 101 by a vertical ion implantation method. Thereby, the contact region 18 is formed. After the forming step of the contact region 18, the third mask 115 is removed. The body structure 12 is formed through fixing including the above steps.

Next, referring to FIG. 13F, a step of forming the insulating film 31 is performed. The insulating film 31 is formed in a film shape on the first wafer main surface 101. The insulating film 31 may be formed by a chemical vapor deposition (CVD) method or an oxidation treatment method (for example, a thermal oxidation treatment method).

Next, referring to FIG. 13G, a step of forming a base electrode 117 as a base of the gate electrode 32 is performed. The base electrode 117 is formed in a film shape on the insulating film 31. The base electrode 117 may be formed by a CVD method.

Next, referring to FIG. 13H, a step of forming a fourth mask 118 having a predetermined layout is performed. The fourth mask 118 is arranged on the base electrode 117, and has an opening 119 for exposing a region other than the region in which the gate electrode 32 is to be formed. The fourth mask 118 may include one or both of an inorganic mask (so-called hard mask) and an organic mask (so-called soft mask). The fourth mask 118 may be formed of a mask material similar to the mask material of the second mask 113, etc.

Next, an unnecessary portion of the base electrode 117 is removed by an etching method through the opening 119 (fourth mask 118). The unnecessary portion of the base electrode 117 is removed until the insulating film 31 is exposed. The etching method may be either or both of a wet etching method and a dry etching method.

Thereby, the gate electrode 32 is formed on the insulating film 31. Thereafter, a step of forming the remaining configuration is sequentially performed, and the wafer 100 is cut out along the intended cutting lines 106. Thereby, a plurality of semiconductor devices 1A are cut out from one wafer 100. The semiconductor device 1A is produced through the steps including the above.

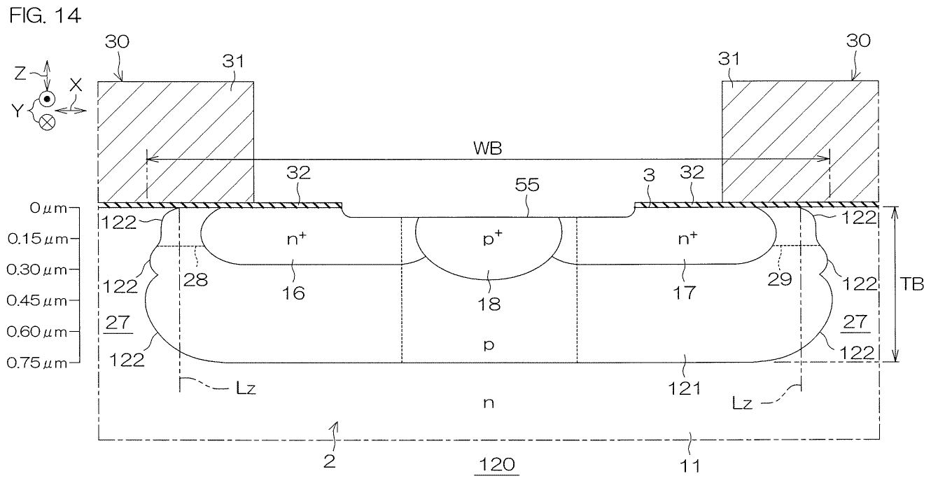

FIG. 14 is an enlarged cross-sectional view illustrating a body structure 120 (hereinafter, simply referred to as a “body structure 120”) according to a reference example. The body structure 120 includes a body region 121 (hereinafter, simply referred to as a “body region 121”) according to the reference example instead of the body region 13. The body region 121 is formed by performing single-stage implantation or multi-stage implantation (multi-stage implantation in this embodiment) of p-type impurities to different depth positions in the surface layer portion of the drift region 11 by a vertical ion implantation method through the first mask 111 in the p-type impurity implantation step according to FIG. 13C.

The body region 121 is formed in the surface layer portion of the drift region 11 such that the body width WB does not decrease in the thickness direction, and does not include a peripheral edge portion inclined in the oblique direction (that is, the body gradient GB). The peripheral edge portion of the body region 121 extends along a direction perpendicular to the first main surface 3 (that is, the vertical direction Z), and does not include both of the sub inclined portion 14 and the main inclined portion 15.

For example, in a case where a vertical line Lz (refer to a two-dot chain line portion) passing through the upper end portion of the peripheral edge portion in the vertical direction Z is set, the body region 121 includes a portion located on the vertical line Lz in a thickness range equal to or thicker than ½ (=50%) of the body thickness TB. In this example, in the body region 121, a region other than a region in the vicinity of the lower end portion is located on the vertical line Lz. For example, in the body region 121, a region having a thickness equal to or thicker than ⅘ (=80%) of the body thickness TB is located on the vertical line Lz.

In this example, the body region 121 includes a plurality of bulging portions 122 protruding in the horizontal direction similarly to the bulging portions 19 (refer to FIG. 10B and FIG. 10C) of the body region 13 according to the second to fourth configuration examples. In the region on the lower end portion side of the body region 121, p-type impurities are implanted with higher implantation energy and relatively higher concentration than in the region on the upper end portion side. On the other hand, in the case of the vertical ion implantation method, the implantation range of the p-type impurities is not controlled. Thus, the implantation range of the p-type impurities is expanded in the horizontal direction as the implantation location becomes deeper due to process conditions.

Therefore, unlike the bulging portions 19 of the body region 13, the bulging portions 122 are formed in multi-stage such as to sequentially protrude outwardly from the upper end portion side toward the lower end portion side, and form undulations in which protrusions and recesses are repeated. That is, in this example, the body region 121 is formed in a club-shaped shape such that the body width WB increases in the thickness direction. Even in a case where the p-type impurities are implanted in a single-stage by the vertical ion implantation method, the implantation range of the p-type impurities is expanded in the horizontal direction in the region on the lower end portion side of the body region 121 for the same reason as in the lowermost bulging portion 122.

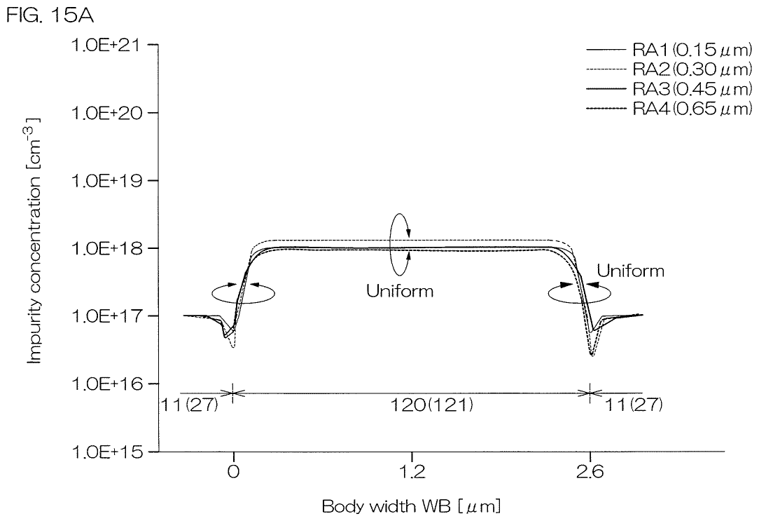

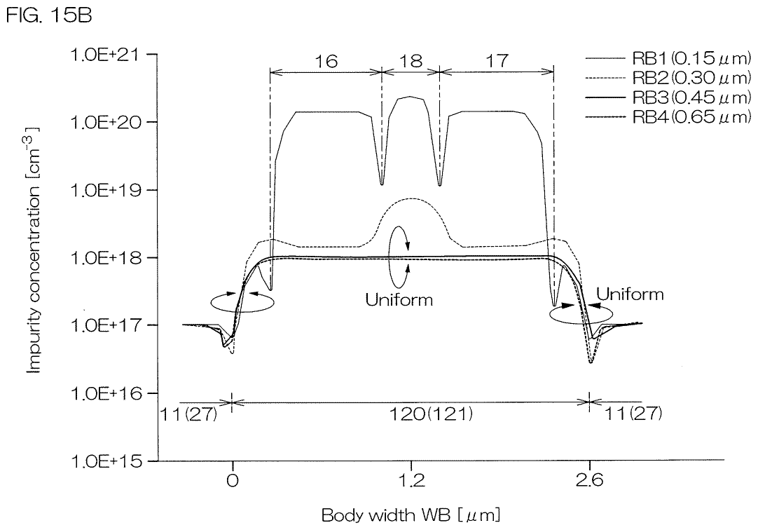

FIG. 15A is a graph showing a concentration gradient in the first region of the body structure 120 according to the reference example. The graph according to FIG. 15A corresponds to the graph according to FIG. 11A. The first region of the body structure 120 is a region in which both of the source regions 16 and 17 and the contact region 18 are not formed in the body region 121 in the second direction Y. For example, the second region of the body structure 120 is both end portions of the body region 121 in the second direction Y. In FIG. 15A, a vertical axis represents the impurity concentration, and a horizontal axis represents the body width WB.

FIG. 15A illustrates a first reference concentration distribution RA1 (thin line), a second reference concentration distribution RA2 (thin broken line), a third reference concentration distribution RA3 (thick line), and a fourth reference concentration distribution RA4 (thick broken line). The first to fourth reference concentration distributions RA1 to RA4 are respectively compared with the first to fourth concentration distributions A1 to A4 (refer to FIG. 11A) described above.

Referring to the first to fourth reference concentration distributions RA1 to RA4, the body region 121 has a substantially constant p-type impurity concentration in both of the thickness direction and the horizontal direction, and does not have a concentration gradient. That is, the body region 121 does not include the first concentration gradient portion 22 and the second concentration gradient portion 23. Also, the body region 121 does not include the first high concentration region 24, the low concentration region 25, and the second high concentration region 26.

As understood from the first to fourth reference concentration distributions RA1 to RA4, the peripheral edge portion of the body region 121 is located on the same line. That is, the peripheral edge portion of the body region 121 is located on the vertical line Lz extending perpendicularly to the first main surface 3 in the thickness direction, and does not have the body gradient GB.

FIG. 15B is a graph showing a concentration gradient in the second region of the body structure 120 according to the reference example. The graph according to FIG. 15B corresponds to the graph according to FIG. 11B. The second region of the body structure 120 is a region in which both of the source regions 16 and 17 and the contact region 18 are formed in the body region 121 in the second direction Y. For example, the second region of the body structure 120 is the intermediate portion of the body region 121 in the second direction Y. In FIG. 15B, a vertical axis represents the impurity concentration, and a horizontal axis represents the body width WB.

FIG. 15B illustrates a first reference concentration distribution RB1 (thin line), a second reference concentration distribution RB2 (thin broken line), a third reference concentration distribution RB3 (thick line), and a fourth reference concentration distribution RB4 (thick broken line). The first reference concentration distribution RB1 has a concentration distribution obtained by adding the n-type impurity concentration of the source regions 16 and 17 and the p-type impurity concentration of the contact region 18 to the first reference concentration distribution RA1.

The second reference concentration distribution RB2 has a concentration distribution obtained by adding the n-type impurity concentration of the source regions 16 and 17 on the bottom portion side and the p-type impurity concentration of the contact region 18 on the bottom portion side to the second reference concentration distribution RA2. The third and fourth reference concentration distributions RB3 and RB4 respectively correspond to the third and fourth reference concentration distributions RA3 and RA4. The first to fourth reference concentration distributions RB1 to RB4 are respectively compared with the first to fourth concentration distributions B1 to B4 (refer to FIG. 11B) described above.

Referring to the first to fourth reference concentration distributions RB1 to RB4, the body region 121 has a substantially constant p-type impurity concentration in both of the thickness direction and the horizontal direction even in the second region, and does not have a concentration gradient. That is, the body region 121 does not include the first concentration gradient portion 22 and the second concentration gradient portion 23 in the second region. Also, the body region 121 does not include the first high concentration region 24, the low concentration region 25, and the second high concentration region 26 in the second region.

As understood from the first to fourth reference concentration distributions RB1 to RB4, the peripheral edge portion of the body region 121 is located on the same line even in the second region. That is, the peripheral edge portion of the body region 121 is located on the vertical line Lz extending perpendicularly to the first main surface 3 in the thickness direction in the second region, and does not have the body gradient GB.

In a case where the body region 121 is formed, the surface layer drift region 27 is formed such that the drift width WD decreases in the thickness direction along the peripheral edge portion of the body region 121 (refer to FIG. 14). Thus, the surface layer drift region 27 forms a current path that narrows in the thickness direction in regions between the body regions 121, and exhibits a current constriction effect. As a result, the JFET resistance component increases. Also, the current density in the regions between the body regions 121 increases, and the electric field concentrates on the peripheral edge portions of the body regions 121.

On the other hand, the semiconductor device 1A includes the chip 2, the n-type drift region 11, and the p-type body region 13. The chip 2 has the first main surface 3. The drift region 11 is formed in the surface layer portion of the first main surface 3. The body region 13 is formed in a tapered shape in the surface layer portion of the drift region 11 such that the width (WB) in the horizontal direction decreases in the thickness direction, and includes the peripheral edge portion inclined in the oblique direction with respect to the first main surface 3.

According to this configuration, the semiconductor device 1A having a novel configuration for the body region 13 is provided. In the semiconductor device 1A, the current path in a vicinity of the body region 13 in the surface layer portion of the drift region 11 is expanded in the horizontal direction by the peripheral edge portion of the body region 13.

Thereby, an increase in the resistance value in the vicinity of the peripheral edge portion of the body region 13 is suppressed. Also, the current density in the vicinity of the peripheral edge portion of the body region 13 is reduced, and the electric field concentration on the peripheral edge portion of the body region 13 is alleviated. Therefore, electrical characteristics are improved. Preferably, the chip 2 includes an SiC single crystal. According to this configuration, an SiC semiconductor device having a novel configuration for the body region 13 is provided.

Preferably, the body region 13 is formed such that the width decreases in the thickness direction with the upper end portion on the first main surface 3 side as the starting point. That is, preferably, the body region 13 includes the peripheral edge portion inclined in the oblique direction with the upper end portion as the starting point. According to this configuration, the current path in the vicinity of the body region 13 is expanded in the horizontal direction with the upper end portion of the body region 13 as the starting point. Thereby, an increase in the resistance value in the vicinity of the peripheral edge portion of the body region 13 is appropriately suppressed, and the electric field concentration on the peripheral edge portion of the body region 13 is appropriately alleviated.

Preferably, the body region 13 has a thickness of 0.5 μm or thicker, and when the upper end portion of the peripheral edge portion is set as the reference position, the body region 13 has the gradient (GB) in which the change amount of the peripheral edge portion in the horizontal direction at the thickness position of 0.5 μm is 0.05 μm or larger.

The body region 13 may have the concentration gradient that gradually decreases in the thickness direction. The body region 13 includes the first high concentration region 24 on the inner side and the low concentration region 25 on the peripheral edge side in the horizontal direction, and may have the concentration gradient that gradually decreases from the first high concentration region 24 toward the low concentration region 25. The first high concentration region 24 may include a portion formed in the region below the intermediate portion of the body region 13. The low concentration region 25 may include a portion formed in the region below the intermediate portion of the body region 13.

The first high concentration region 24 may have the concentration gradient that gradually decreases in the thickness direction. The low concentration region 25 may have the concentration gradient that gradually decreases in the thickness direction. The concentration difference between the first high concentration region 24 and the low concentration region 25 may gradually decrease toward the bottom portion of the body region 13. The peripheral edge portion of the body region 13 may include the bulging portions 19 protruding in the horizontal direction in multiple stages in the thickness direction.

The semiconductor device 1A may include the body regions 13 formed at an interval in the surface layer portion of the drift region 11. In this case, the semiconductor device 1A may include the n-type surface layer drift region 27 that is defined in the region between the body regions 13 in the surface layer portion of the drift region 11. The surface layer drift region 27 is defined such that the width (WD) in the horizontal direction gradually increases in the thickness direction, and form the JFET structures with the body regions 13.

According to this configuration, the surface layer drift region 27 forms a current path extending in the thickness direction in the region between the body regions 13, and reduces the current constriction. Thereby, the JFET resistance component of the JFET structure is reduced. Also, the surface layer drift region 27 reduces current density in the region between the body regions 13, and reduces electric field concentration on the peripheral edge portions of the body regions 13.

The semiconductor device 1A may include the n-type source region 16, 17. The source region 16, 17 may have the n-type impurity concentration higher than the n-type impurity concentration of the drift region 11, and may be formed in the surface layer portion of the body region 13. The semiconductor device 1A may include the p-type contact region 18. The contact region 18 may have the p-type impurity concentration higher than the p-type impurity concentration of the body region 13, and may be formed in the surface layer portion of the body region 13.

From another viewpoint, the semiconductor device 1A may include the chip 2, the n-type drift region 11, the p-type body regions 13, and the p-type contact regions 18. The chip 2 has the first main surface 3. The drift region 11 is formed in the surface layer portion of the first main surface 3. The body region 13 is formed in the surface layer portion of the drift region 11. The contact region 18 has the p-type impurity concentration higher than the p-type impurity concentration of the body region 13, and is formed in the surface layer portion of the body region 13.

In such a configuration, the body region 13 includes the first high concentration region 24 in the thickness range below the contact region 18. The body region 13 includes the low concentration region 25 formed in the region on the peripheral edge side with respect to the first high concentration region 24 in the thickness range below the contact region 18. According to this configuration, the ohmic property of the contact region 18 is enhanced by the first high concentration region 24.

Preferably, the first high concentration region 24 has the p-type impurity concentration lower than the p-type impurity concentration of the contact region 18. Preferably, the low concentration region 25 has the p-type impurity concentration lower than the p-type impurity concentration of the first high concentration region 24. According to this configuration, the function of the body region 13 is appropriately secured.

The semiconductor device 1A may include the n-type source region 16, 17 formed in the surface layer portion of the body region 13. In this case, preferably, the low concentration region 25 is formed in the thickness range below the source region 16, 17. According to this configuration, the n-type impurity concentration of the source region 16, 17 is suppressed from being offset by the p-type impurity concentration of the first high concentration region 24. Therefore, the function of the source regions 16 and 17 is appropriately secured.

The body region 13 may include the peripheral edge portion inclined in the oblique direction with respect to the first main surface 3. According to this configuration, the current path in the vicinity of the body region 13 in the surface layer portion of the drift region 11 is expanded in the horizontal direction by the peripheral edge portion of the body region 13. Thereby, an increase in the resistance value in the vicinity of the body region 13 is suppressed.

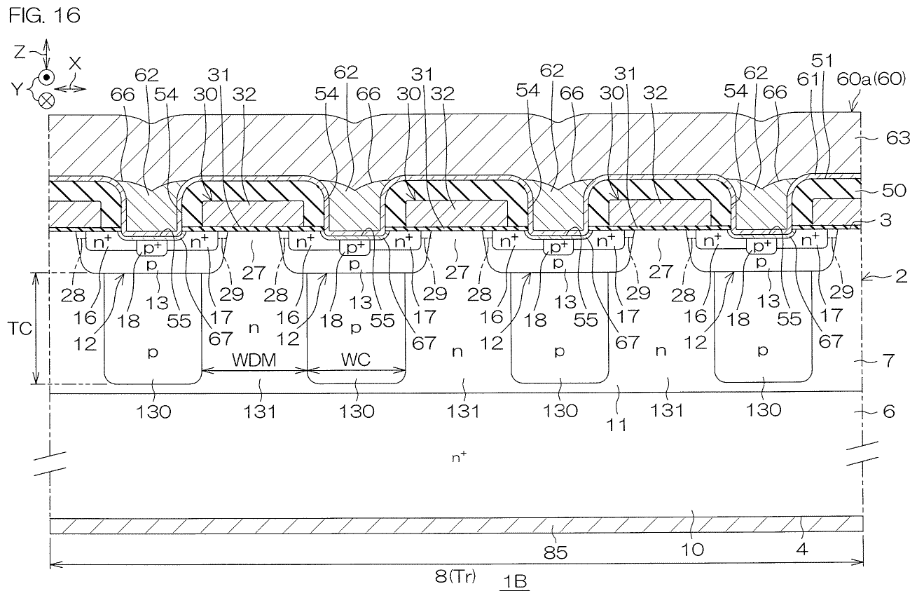

FIG. 16 is a cross-sectional view illustrating a semiconductor device 1B according to a second embodiment. The semiconductor device 1B includes a plurality of p-type column regions 130 formed in a thickness range below the body regions 13 in the drift region 11.

The column regions 130 have a p-type impurity concentration lower than the p-type impurity concentration of the contact region 18. The p-type impurity concentration of the column regions 130 may be lower than the p-type impurity concentration of the body region 13. The p-type impurity concentration of the column regions 130 may be in a range of 1×10¹⁶ cm⁻³ or higher and 5×10¹⁷ cm⁻³ or lower.

The column regions 130 are arranged at intervals in the first direction X, and are respectively formed in a band shape extending in the second direction Y. That is, the column regions 130 are formed in a stripe shape extending in the second direction Y along the body regions 13. Also, the extension direction of the body structures 12 coincides with the off direction of the SiC single crystal.

The column regions 130 are formed in a columnar shape extending in the thickness direction in a cross-sectional view, and overlap the body regions 13 in a one-to-one correspondence relationship. The column regions 130 may have a single layer structure including a single p-type impurity region, or may have a laminated structure in which a plurality of p-type impurity regions are laminated in the thickness direction. Hereinafter, the configuration of one column region 130 will be specifically described.

The column region 130 has a column width WC narrower than the body width WB of the body region 13, and is formed at an interval inwardly from the peripheral edge portion (main inclined portion 15) of the body region 13 (refer to also FIG. 7, FIG. 10A, etc). Thereby, electrical interference of the column region 130 with the peripheral edge portion of the body region 13 is suppressed. For example, the column width WC is wider than the width of the contact region 18. The column width WC is appropriately adjusted according to the body width WB.

The column region 130 has a column thickness TC thicker than the body thickness TB of the body region 13 (refer to also FIG. 7, FIG. 10A, etc). For example, the column thickness TC is thinner than the thickness of the drift region 11. The column thickness TC is appropriately adjusted according to the thickness of the drift region 11.

The column region 130 traverses the intermediate portion of the drift region 11 in the thickness direction. The column region 130 includes a lower end portion and an upper end portion. The lower end portion of the column region 130 is located on the bottom portion side of the drift region 11 with respect to the intermediate portion of the drift region 11. The lower end portion of the column region 130 may be formed at an interval from the bottom portion of the drift region 11 toward the body region 13 side. The lower end portion of the column region 130 may traverse the bottom portion of the drift region 11, and may be located in the surface layer portion of the drain region 10.

The upper end portion of the column region 130 is located on the bottom portion (lower end portion) side of the body region 13 with respect to the intermediate portion of the drift region 11. Preferably, the upper end portion of the column region 130 is connected to the bottom portion of the body region 13. That is, preferably, the column region 130 is electrically connected to the body region 13. As a matter of course, the upper end portion of the column region 130 may be formed at an interval from the bottom portion of the body region 13 toward the bottom portion side of the drift region 11, and may oppose the body region 13 across a portion of the drift region 11.

The semiconductor device 1B includes a plurality of n-type intermediate drift regions 131 formed in the drift region 11. Each of the intermediate drift regions 131 includes a region of the drift region 11 that is defined by the column regions 130.

The intermediate drift region 131 may have an n-type impurity concentration higher than the n-type impurity concentration of the drift region 11, or may have an n-type impurity concentration lower than the n-type impurity concentration of the drift region 11. The intermediate drift region 131 may have an n-type impurity concentration higher than the n-type impurity concentration of the surface layer drift region 27, or may have an n-type impurity concentration lower than the n-type impurity concentration of the surface layer drift region 27.

The intermediate drift regions 131 are alternately arranged with the column regions 130 in the first direction X, and are respectively formed in a band shape extending in the second direction Y. That is, the intermediate drift regions 131 are formed in a stripe shape extending in the second direction Y along the column regions 130. Also, the extension direction of the intermediate drift regions 131 coincides with the off direction of the SiC single crystal.

The intermediate drift regions 131 are formed in a columnar shape extending in the thickness direction in a cross-sectional view, and are connected to the surface layer drift regions 27 in a one-to-one correspondence relationship. Each of the intermediate drift regions 131 has an intermediate drift width WDM wider than the drift width WD of the surface layer drift regions 27, and includes both end portions connected to two body regions 13 adjacent to each other in the first direction X.

The intermediate drift regions 131 form a plurality of pn-junction portions having a charge balance together with the column regions 130 in the thickness range below the body region 13. A state of having the charge balance means a state where, in regard to the column regions 130 that are adjacent to each other, the depletion layer expanding from the pn-junction portion on one side and the depletion layer expanding from the pn-junction portion on the other side are connected in the intermediate drift regions 131. Thereby, the intermediate drift regions 131 form a super junction structure with the column regions 130 in regions below the body regions 13.

A step of forming the column regions 130 includes a mask forming step and a p-type impurity implantation step. In the mask forming step, a mask having openings for exposing regions in which the column regions 130 are to be formed is formed on the first wafer main surface 101. In the p-type impurity implantation step, the p-type impurities are implanted into the drift region 11 by an ion implantation method through the mask.

Preferably, the ion implantation method is a channeling ion implantation method. In the channeling ion implantation step, the p-type impurities are implanted along a channel axis (for example, c-axis) in which atomic rows are sparse among crystal axes of the chip 2 (second semiconductor layer 7). The p-type impurities are implanted into a deep region of the drift region 11 while repeating small-angle scattering caused by a channeling effect. That is, in the case of the channeling implantation method, a collision probability of the trivalent elements with the atomic rows of the SiC single crystal is reduced. Thereby, the column regions 130 are formed.

The forming step of the column region 130 may be performed after the forming step of the body region 13. In this case, the column region 130 is formed in the inner portion of the drift region 11 such as to be connected to the body region 13 in the thickness direction. Preferably, the forming step of the column region 130 is performed before the forming step of the body region 13. In this case, in the forming step of the body region 13, the body region 13 is formed in the surface layer portion of the drift region 11 such as to be connected to the column region 130 in the thickness direction.

According to this step order, the forming step of the body region 13 is performed after the forming step of the column region 130, and thus, deformation of the body region 13 (particularly, deformation of the peripheral edge portion of the body region 13) due to the step of implanting the p-type impurities into the column region 130 is suppressed. Also, according to this step order, a change in the concentration of the body region 13 due to the step of implanting the p-type impurities into the column region 130 is suppressed.

As described above, the semiconductor device 1B includes the p-type column regions 130 in addition to the configuration of the semiconductor device 1A. The column regions 130 are formed in the thickness range below the body region 13 in the drift region 11. According to this configuration, there is provided the super-junction-type semiconductor device 1B in which an increase in the resistance value in the vicinity of the body region 13 is suppressed. In a case where the chip 2 includes an SiC single crystal, there is provided a super-junction-type SiC semiconductor device having a novel configuration for the body region 13.

In this embodiment, an example is illustrated in which the column regions 130 (the intermediate drift regions 131) are formed in a stripe shape extending in the second direction Y along the body regions 13. On the other hand, the column regions 130 may be formed in a band shape extending in the first direction X, and may be arranged at intervals in the second direction Y. That is, the extension direction of the column regions 130 may intersect (specifically, be orthogonal to) the off direction of the SiC single crystal. In this case, the column regions 130 intersect (specifically, are orthogonal to) the body regions 13.

As a matter of course, the column regions 130 (the intermediate drift regions 131) may be arranged at intervals in an intersection direction intersecting both of the first direction X and the second direction Y, and may be respectively formed in a band shape extending in an orthogonal direction orthogonal to the intersection direction. That is, the extension direction of the column regions 130 may intersect the off direction of the SiC single crystal. In this case, the column regions 130 intersect the body regions 13.

In this embodiment, an example is illustrated in which the body regions 13 (body structures 12) are formed in a stripe shape extending in the second direction Y. On the other hand, the body regions 13 may be respectively formed in a band shape extending in the first direction X, and may be arranged at intervals in the second direction Y. That is, the body regions 13 may be formed in a stripe shape extending in the first direction X. Further, the extension direction of the body regions 13 may intersect (specifically, be orthogonal to) the off direction of the SiC single crystal.

In this case, the column regions 130 (the intermediate drift regions 131) may be respectively formed in a band shape extending in the first direction X, and may be arranged at intervals in the second direction Y. That is, the column regions 130 (the intermediate drift regions 131) may be formed in a stripe shape extending in the first direction X along the body regions 13.

As a matter of course, the column regions 130 may be arranged at intervals in the first direction X, and may be respectively formed in a band shape extending in the second direction Y. That is, the column regions 130 may be formed in a stripe shape extending in the second direction Y. Also, the extension direction of the column regions 130 may coincide with the off direction of the SiC single crystal.

In this case, the column regions 130 intersect (specifically, are orthogonal to) the body regions 13. As a matter of course, the column regions 130 (the intermediate drift regions 131) may be arranged at intervals in an intersection direction intersecting both of the first direction X and the second direction Y, and may be respectively formed in a band shape extending in an orthogonal direction orthogonal to the intersection direction.

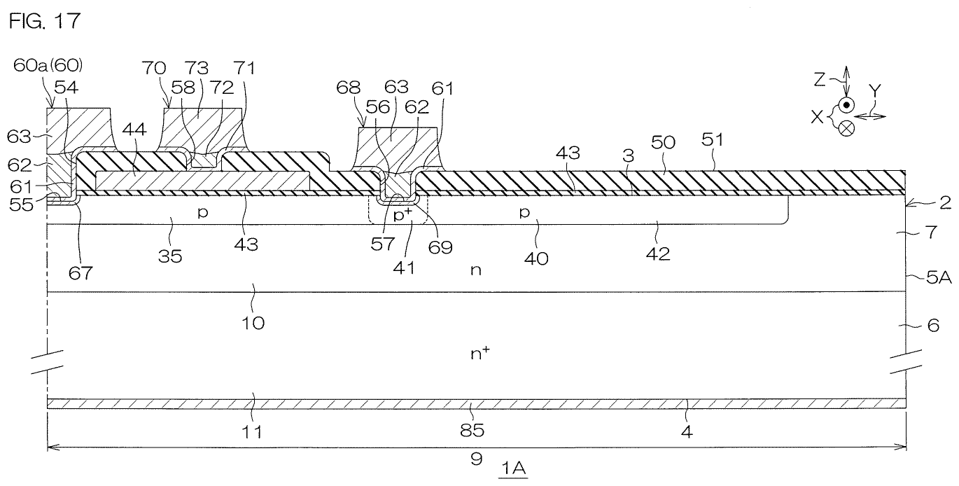

Hereinafter, modification examples applied to the semiconductor devices 1A and 1B according to the first and second embodiments will be described. FIG. 17 is a cross-sectional view illustrating a modification example of the field region 42. FIG. 17 illustrates a configuration in which the field region 42 according to the modification example is applied to the semiconductor device 1A. As a matter of course, the field region 42 according to the modification example can be applied to the semiconductor device 1B.

In the embodiments described above, an example is illustrated in which the field regions 42 are formed in the surface layer portion of the drift region 11. On the other hand, as illustrated in FIG. 17, the single field region 42 may be formed in the surface layer portion of the drift region 11.

The single field region 42 is formed in the region between the peripheral edge of the first main surface 3 and the body regions 13 (the active region 8) at an interval inwardly from the peripheral edge of the first main surface 3. Specifically, the single field region 42 is formed in the region between the peripheral edge of the first main surface 3 and the outer body region 35. More specifically, the single field region 42 is formed in the region between the peripheral edge of the first main surface 3 and the terminal region 40.

The single field region 42 is formed in a band shape extending along the body regions 13 (terminal region 40) in a plan view. The single field region 42 includes a portion extending in a band shape in the first direction X and a portion extending in a band shape in the second direction Y. In this embodiment, the single field region 42 is formed in a polygonal round shape (in this embodiment, a quadrangular round shape) surrounding the body regions 13 (terminal region 40) in a plan view. The single field region 42 may include an edge portion that connects the portion extending in the first direction X and the portion extending in the second direction Y in a circular arc shape (preferably, a quarter arc shape) (refer to FIG. 4).

A ratio of the width of the single field region 42 to the outer peripheral width may be equal to or larger than 0.1 and smaller than 1. The outer peripheral width is the width of the outer peripheral region 9. The width of the outer peripheral region 9 may be defined by a width between the peripheral edge of the first main surface 3 and the active region 8 (for example, the inner edge portion of the outer body region 35). The ratio of the width may have a value in at least one range among a range of 0.1 or larger and 0.2 or smaller, a range of 0.2 or larger and 0.4 or smaller, a range of 0.4 or larger and 0.6 or smaller, a range of 0.6 or larger and 0.8 or smaller, and a range equal to or larger than 0.8 and smaller than 1.

The single field region 42 is formed at an interval from the bottom portion of the drift region 11 toward the first main surface 3 side, and opposes the drain region 10 across a portion of the drift region 11. Preferably, the single field region 42 is formed at an interval from the depth position of the intermediate portion of the drift region 11 toward the first main surface 3 side. As a matter of course, the single field region 42 may traverse the depth position of the intermediate portion of the drift region 11 in the thickness direction.

The single field region 42 includes an inner edge portion on the terminal region 40 side and an outer edge portion on the peripheral edge side of the first main surface 3. In this embodiment, the inner edge portion of the single field region 42 is connected to the outer edge portion of the terminal region 40. Thereby, the single field region 42 is electrically connected to the terminal region 40. In this embodiment, the inner edge portion of the single field region 42 is connected to the outer edge portion of the terminal region 40 over the entire periphery.

The p-type impurity concentration of the single field region 42 is the same as the p-type impurity concentration in the semiconductor device 1A. In a case where the single field region 42 has the p-type impurity concentration substantially equal to the p-type impurity concentration of the terminal region 40, the single field region 42 may be led out from the terminal region 40 to the surface layer portion of the drift region 11 as a lead-out portion of the terminal region 40.

That is, the terminal region 40 may include the single field region 42 as a lead-out portion. As a matter of course, the p-type impurity concentration of the single field region 42 may be different from the p-type impurity concentration of the terminal region 40. Also, the single field region 42 may be formed at an interval from the terminal region 40.

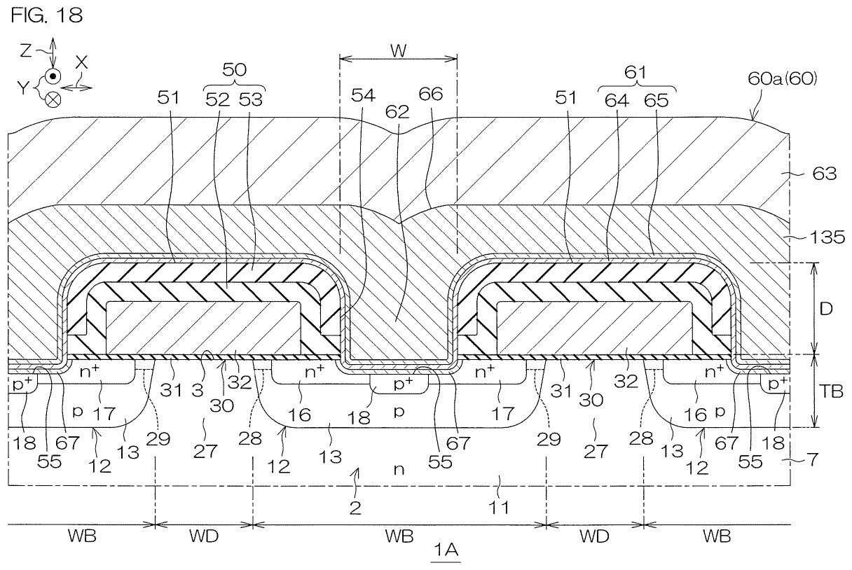

FIG. 18 is a cross-sectional view illustrating a first modification example of the source pad electrode 60. FIG. 18 illustrates a configuration in which the source pad electrode 60 according to the modification example is applied to the semiconductor device 1A. As a matter of course, the field region 42 according to the modification example can be applied to the semiconductor device 1B.

In the embodiments described above, the first embedded electrodes 62 are embedded in the source openings 54 such as to expose the insulating surface 51. On the other hand, as illustrated in FIG. 18, the source pad electrode 60 may include the first embedded electrodes 62 that are led out from the source openings 54 onto the insulating surface 51 and cover the insulating surface 51.

The first embedded electrodes 62 cover the first underlying electrode film 61 on the insulating surface 51, and includes a portion that covers the insulating surface 51 across the first underlying electrode film 61. That is, each of the first embedded electrodes 62 has the first embedded electrode surface 66 exposed from the source openings 54 above the insulating surface 51. The first embedded electrodes 62 include a portion that opposes the gate electrode 32 across the first underlying electrode film 61 and the interlayer film 50 in the lamination direction (vertical direction Z).

The first embedded electrodes 62 are integrated on the insulating surface 51, and one intermediate electrode 135 is formed. The intermediate electrode 135 (the first embedded electrodes 62) covers the entire region of the first underlying electrode film 61. The electrode surface (first embedded electrode surface 66) of the intermediate electrode 135 is located above the insulating surface 51.

In this embodiment, the first main electrode film 63 is mechanically and electrically connected to the first embedded electrode surfaces 66 of the first embedded electrodes 62 (intermediate electrode 135) above the insulating surface 51. The first main electrode film 63 includes a portion that opposes the insulating surface 51 across the first embedded electrodes 62 (intermediate electrode 135). In this embodiment, the first main electrode film 63 does not include a mechanical connection portion to the first underlying electrode film 61.

The configuration of the first embedded electrodes 62 (intermediate electrode 135) according to the modification example can also be applied to the first embedded electrodes 62 of the source finger electrode 68. Similarly, the configuration of the first embedded electrodes 62 (intermediate electrode 135) according to the modification example can also be applied to the second embedded electrodes 72 of the gate finger electrode 70.

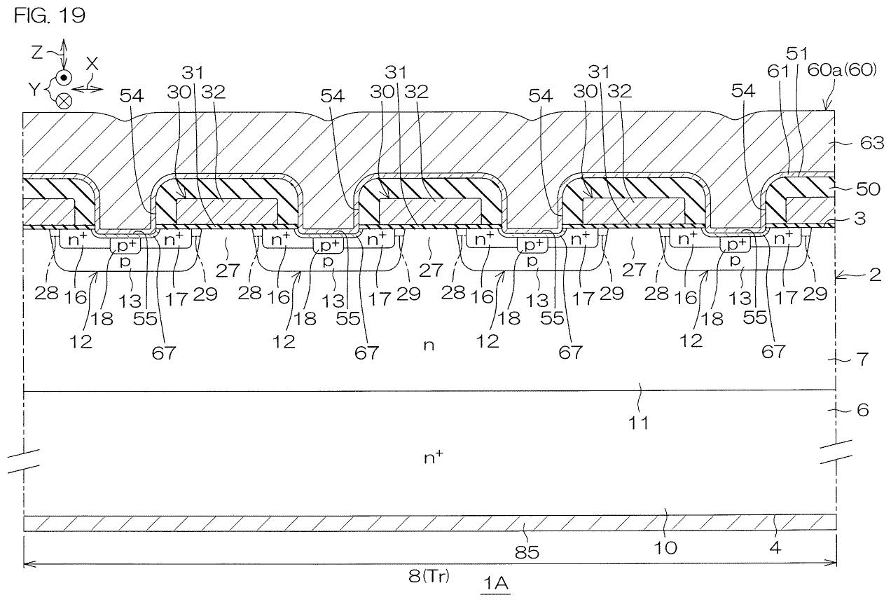

FIG. 19 is a cross-sectional view illustrating a second modification example of the source pad electrode 60. FIG. 19 illustrates a configuration in which the source pad electrode 60 according to the modification example is applied to the semiconductor device 1A. As a matter of course, the field region 42 according to the modification example can be applied to the semiconductor device 1B.

In the embodiments described above, the source pad electrode 60 includes the first embedded electrodes 62. However, the source pad electrode 60 does not necessarily include the first embedded electrodes 62. In this case, the first main electrode film 63 of the source pad electrode 60 enters the source openings 54 from above the interlayer film 50, and is electrically connected to the body regions 13, etc., in the source openings 54.

Similarly, the source finger electrode 68 does not necessarily include the first embedded electrode 62. In this case, the first main electrode film 63 of the source finger electrode 68 enters the outer openings 56 from above the interlayer film 50, and is electrically connected to the terminal region 40 (overlap region 41) in the outer openings 56.

Similarly, the gate finger electrode 70 does not necessarily include the second embedded electrode 72. In this case, the second main electrode film 73 of the gate finger electrode 70 enters the gate openings 58 from above the interlayer film 50, and is electrically connected to the gate wirings 44 in the gate openings 58.

The semiconductor devices 1A and 1B may include the first embedded electrode 62 for the source pad electrode 60, but may not include the first embedded electrode 62 for the source finger electrode 68. The semiconductor devices 1A and 1B may include the first embedded electrode 62 for the source finger electrode 68, but may not include the first embedded electrode 62 for the source pad electrode 60.

The semiconductor devices 1A and 1B may include the first embedded electrode 62 for the source pad electrode 60, but may not include the second embedded electrode 72. The semiconductor devices 1A and 1B may include the second embedded electrode 72, but may not include the first embedded electrode 62 for the source pad electrode 60. The semiconductor devices 1A and 1B may include the first embedded electrode 62 for the source finger electrode 68, but may not include the second embedded electrode 72. The semiconductor devices 1A and 1B may include the second embedded electrode 72, but may not include the first embedded electrode 62 for the source finger electrode 68.

The above-described embodiments (including the modification examples) can be implemented in still other forms. For example, in the above-described embodiments, a configuration in which the relationship between the a-axis direction and the m-axis direction is interchanged may be adopted. A specific configuration in this case can be obtained by interchanging “a-axis direction (off direction)” and “m-axis direction (direction orthogonal to off direction)” in the above description and the accompanying drawings.

In the above-described embodiments, a structure in which the conductivity type of the “n-type” semiconductor region is inverted to the “p-type” and the conductivity type of the “p-type” semiconductor region is inverted to the “n-type” may be adopted. A specific configuration in this case can be obtained by replacing the “n-type” with the “p-type” at the same time as replacing the “p-type” with the “n-type” in the above descriptions and accompanying drawings.

In the embodiments described above, the chip 2 including an SiC single crystal is adopted. On the other hand, the chip 2 may include a single crystal of a wide bandgap semiconductor other than the SiC single crystal. The wide bandgap semiconductor is a semiconductor having a bandgap greater than a bandgap of silicon. Examples of the single crystal of the wide bandgap semiconductor include gallium nitride, gallium oxide, and diamond. As a matter of course, the chip 2 may include a silicon single crystal.

Similarly, the first semiconductor layer 6 may include a single crystal of a wide bandgap semiconductor other than the SiC single crystal. The first semiconductor layer 6 may contain gallium nitride, gallium oxide, diamond, etc. As a matter of course, the first semiconductor layer 6 may include a silicon single crystal.

Similarly, the second semiconductor layer 7 may include a single crystal of a wide bandgap semiconductor other than the SiC single crystal. The second semiconductor layer 7 may contain gallium nitride, gallium oxide, diamond, etc. As a matter of course, the second semiconductor layer 7 may include a silicon single crystal.

In the embodiments described above, the n-type drain region 10 is illustrated. On the other hand, a p-type collector region (10) may be adopted instead of the n-type drain region 10. In this case, an insulated gate bipolar transistor (IGBT) structure is formed in place of the MISFET structure. In this case, in the above descriptions, the “source” of the MISFET structure is replaced with an “emitter” of the IGBT structure and the “drain” of the MISFET structure is replaced with a “collector” of the IGBT structure. The p-type collector region (10) may be an impurity region including p-type impurities implanted into the surface layer portion of the second main surface 4 of the n-type chip 2 (n-type chip 2) by an ion implantation method.

Hereinafter, examples of features extracted from this description and the attached drawings are indicated. Hereinafter, the alphanumeric characters, etc., in parentheses represent the corresponding components, etc., in the embodiments described above, but are not intended to limit the scope of each clause to the embodiments described above. The “semiconductor device” in the following clauses may be replaced with an “SiC semiconductor device,” a “wide bandgap semiconductor device,” a “semiconductor switching device,” an “MISFET device,” an “IGBT device,” a “semiconductor rectifier,” etc., as needed.

[A1] A semiconductor device (1A, 1B) comprising: a chip (2) that has a main surface (3); a drift region (11) of a first conductivity type (n-type) that is formed in a surface layer portion of the main surface (3); and a body region (13) of a second conductivity type (p-type) that is formed in a tapered shape in a surface layer portion of the drift region (11) such that a width in a horizontal direction (WB) decreases in a thickness direction, and includes a peripheral edge portion inclined in an oblique direction with respect to the main surface (3).

[A2] The semiconductor device (1A, 1B) according to A1, wherein the chip (2) includes an SiC single crystal.

[A3] The semiconductor device (1A, 1B) according to A1 or A2, wherein the body region (13) is formed such that the width (WB) decreases in the thickness direction with an upper end portion on the main surface (3) side as a starting point, and includes the peripheral edge portion inclined in the oblique direction with the upper end portion as the starting point.

[A4] The semiconductor device (1A, 1B) according to A3, wherein the body region (13) has a thickness (TB) of 0.5 μm or thicker, and when the upper end portion of the peripheral edge portion is set as a reference position, the body region (13) has a gradient (GB) in which a change amount of the peripheral edge portion in the horizontal direction at a thickness position of 0.5 μm is 0.05 μm or larger.

[A5] The semiconductor device (1A, 1B) according to any one of A1 to A4, wherein the body region (13) has a concentration gradient that gradually decreases in the thickness direction.

[A6] The semiconductor device (1A, 1B) according to any one of A1 to A5, wherein the body region (13) includes a high concentration region (24) on an inner side and a low concentration region (25) on a peripheral edge side in the horizontal direction, and has a concentration gradient that gradually decreases from the high concentration region (24) toward the low concentration region (25).

[A7] The semiconductor device (1A, 1B) according to A6, wherein the high concentration region (24) includes a portion formed below an intermediate portion of the body region (13), and the low concentration region (25) includes a portion formed below the intermediate portion of the body region (13).

[A8] The semiconductor device (1A, 1B) according to A7, wherein a concentration difference between the high concentration region (24) and the low concentration region (25) gradually decreases toward a bottom portion of the body region (13).

[A9] The semiconductor device (1A, 1B) according to any one of A1 to A8, wherein the peripheral edge portion of the body region (13) includes bulging portions (19) protruding in the horizontal direction in multi-stages along the thickness direction.

[A10] The semiconductor device (1A, 1B) according to any one of A1 to A9, further comprising: the body regions (13) that are formed at an interval in the surface layer portion of the drift region (11); and a surface layer drift region (27) of the first conductivity type (n-type) that is defined in a region between the body regions (13) such that a width (WD) in the horizontal direction increases in the thickness direction in the surface layer portion of the drift region (11), and forms a JFET structures with the body regions (13).

[A11] The semiconductor device (1A, 1B) according to any one of A1 to A10, further comprising: an impurity region (16, 17) of the first conductivity type (n-type) that is formed in a surface layer portion of the body region (13), and has an impurity concentration higher than an impurity concentration of the drift region (11); and a contact region (18) of the second conductivity type (p-type) that is formed in the surface layer portion of the body region (13), and has an impurity concentration higher than an impurity concentration of the body region (13).

[A12] The semiconductor device (1A, 1B) according to any one of A1 to A11, further comprising: a column region (130) of the second conductivity type (p-type) that is formed in a thickness range below the body region (13) in the drift region (11).

[A13] A semiconductor device (1A, 1B) comprising: a chip (2) that has a main surface (3); a drift region (11) of a first conductivity type (n-type) that is formed in a surface layer portion of the main surface (3); a body region (13) of a second conductivity type (p-type) that is formed in a surface layer portion of the drift region (11); and a contact region (18) of the second conductivity type (p-type) that is formed in a surface layer portion of the body region (13), and has an impurity concentration higher than an impurity concentration of the body region (13); wherein the body region (13) includes a high concentration region (24) formed in a thickness range below the contact region (18) and a low concentration region (25) formed in a region on a peripheral edge side with respect to the high concentration region (24) in the thickness range.

[A14] The semiconductor device (1A, 1B) according to A13, wherein the high concentration region (24) has an impurity concentration lower than the impurity concentration of the contact region (18), and the low concentration region (25) has an impurity concentration lower than the impurity concentration of the high concentration region (24).

[A15] The semiconductor device (1A, 1B) according to A13 or A14, wherein the body region (13) includes a peripheral edge portion inclined in an oblique direction with respect to the main surface (3).

[A16] A manufacturing method for a semiconductor device (1A, 1B) comprising: a step of preparing a wafer (100) including a drift region (11) of a first conductivity type (n-type) in a surface layer portion of a main surface (101); and a step of implanting impurities of a second conductivity type (p-type) into a surface layer portion of the drift region (11) such that an implantation range in a horizontal direction decreases in a thickness direction, and forming a body region (13) of the second conductivity type (p-type) that includes a peripheral edge portion inclined in an oblique direction with respect to the main surface (101).

[A17] The manufacturing method for the semiconductor device (1A, 1B) according to A16, wherein the forming step of the body region (13) includes a step of implanting the impurities into the surface layer portion of the drift region (11) by an oblique ion implantation method.

[A18] The manufacturing method for the semiconductor device (1A, 1B) according to A17, wherein the forming step of the body region (13) includes a step of implanting the impurities to different depth positions in multi-stages in the surface layer portion of the drift region (11) at different implantation angles.

[A19] The manufacturing method for the semiconductor device (1A, 1B) according to any one of A16 to A18, further comprising: a step of forming a mask (111) having an opening (112) on the main surface (101), wherein the forming step of the body region (13) includes a step of implanting the impurities into the surface layer portion of the drift region (11) through the opening (112) of the mask (111).

[A20] The manufacturing method for the semiconductor device (1A, 1B) according to A19, wherein the forming step of the body region (13) includes a step of implanting the impurities into a region immediately below the mask (111) in the surface layer portion of the drift region (11).

While specific embodiments have been described in detail above, these are merely specific examples used to clarify the technical contents. The various technical ideas extracted from this description can be combined as appropriate with each other without being limited by the order of description, the order of configuration examples, the order of modification examples, etc., in this description.

What is claimed is:

1. A semiconductor device comprising:
a chip that has a main surface;
a drift region of a first conductivity type that is formed in a surface layer portion of the main surface; and
a body region of a second conductivity type that is formed in a tapered shape in a surface layer portion of the drift region such that a width in a horizontal direction decreases in a thickness direction, and includes a peripheral edge portion inclined in an oblique direction with respect to the main surface.

2. The semiconductor device according to claim 1,
wherein the chip includes an SiC single crystal.

3. The semiconductor device according to claim 1,
wherein the body region is formed such that the width decreases in the thickness direction with an upper end portion on the main surface side as a starting point, and includes the peripheral edge portion inclined in the oblique direction with the upper end portion as the starting point.

4. The semiconductor device according to claim 3,
wherein the body region has a thickness of 0.5 μm or thicker, and
when the upper end portion of the peripheral edge portion is set as a reference position, the body region has a gradient in which a change amount of the peripheral edge portion in the horizontal direction at a thickness position of 0.5 μm is 0.05 μm or larger.

5. The semiconductor device according to claim 1,
wherein the body region has a concentration gradient that gradually decreases in the thickness direction.

6. The semiconductor device according to claim 1,
wherein the body region includes a high concentration region on an inner side and a low concentration region on a peripheral edge side in the horizontal direction, and has a concentration gradient that gradually decreases from the high concentration region toward the low concentration region.

7. The semiconductor device according to claim 6,
wherein the high concentration region includes a portion formed below an intermediate portion of the body region, and
the low concentration region includes a portion formed below the intermediate portion of the body region.

8. The semiconductor device according to claim 6,
wherein the high concentration region has a concentration gradient that gradually decreases in the thickness direction, and
the low concentration region has a concentration gradient that gradually decreases in the thickness direction.

9. The semiconductor device according to claim 1,
wherein the peripheral edge portion of the body region includes bulging portions protruding in the horizontal direction in multi-stages along the thickness direction.

10. The semiconductor device according to claim 1, further comprising:
the body regions that are formed at an interval in the surface layer portion of the drift region; and
a surface layer drift region of the first conductivity type that is defined in a region between the body regions such that a width in the horizontal direction increases in the thickness direction in the surface layer portion of the drift region, and forms a JFET structure with the body regions.

11. The semiconductor device according to claim 1, further comprising:
an impurity region of the first conductivity type that is formed in a surface layer portion of the body region, and has an impurity concentration higher than an impurity concentration of the drift region; and
a contact region of the second conductivity type that is formed in the surface layer portion of the body region, and has an impurity concentration higher than an impurity concentration of the body region.

12. The semiconductor device according to claim 1, further comprising:
a column region of the second conductivity type that is formed in a thickness range below the body regions in the drift region.

13. A semiconductor device comprising:
a chip that has a main surface;
a drift region of a first conductivity type that is formed in a surface layer portion of the main surface;
a body region of a second conductivity type that is formed in a surface layer portion of the drift region; and
a contact region of the second conductivity type that is formed in a surface layer portion of the body region, and has an impurity concentration higher than an impurity concentration of the body region;
wherein the body region includes a high concentration region formed in a thickness range below the contact region and a low concentration region formed in a region on a peripheral edge side with respect to the high concentration region in the thickness range.

14. The semiconductor device according to claim 13,
wherein the high concentration region has an impurity concentration lower than the impurity concentration of the contact region, and
the low concentration region has an impurity concentration lower than the impurity concentration of the high concentration region.

15. The semiconductor device according to claim 13,
wherein the body region includes a peripheral edge portion inclined in an oblique direction with respect to the main surface.

16. A manufacturing method for a semiconductor device comprising:
a step of preparing a wafer including a drift region of a first conductivity type in a surface layer portion of a main surface; and
a step of implanting impurities of a second conductivity type in a surface layer portion of the drift region such that an implantation range in a horizontal direction decreases in a thickness direction, and forming a body region of the second conductivity type that includes a peripheral edge portion inclined in an oblique direction with respect to the main surface.

17. The manufacturing method for the semiconductor device according to claim 16,
wherein the forming step of the body region includes a step of implanting the impurities into the surface layer portion of the drift region by an oblique ion implantation method.

18. The manufacturing method for the semiconductor device according to claim 17,
wherein the forming step of the body region includes a step of implanting the impurities to different depth positions in multi-stages in the surface layer portion of the drift region at different implantation angles.

19. The manufacturing method for the semiconductor device according to claim 16, further comprising:
a step of forming a mask having an opening on the main surface,
wherein the forming step of the body region includes a step of implanting the impurities into the surface layer portion of the drift region through the opening of the mask.

20. The manufacturing method for the semiconductor device according to claim 19,
wherein the forming step of the body region includes a step of implanting the impurities into a region immediately below the mask in the surface layer portion of the drift region.
